(19) United States
(12) Patent Application Publication
(10) Pub. No.: US 2023/0299560 A1
(43) Pub. Date: Sep. 21, 2023

(54) SEMICONDUCTOR-LASER ELEMENT

(71) Applicant: SONY GROUP CORPORATION, TOKYO (JP)

(72) Inventors: HIROSHI NAKAJIMA, TOKYO (JP); TATSUSHI HAMAGUCHI, TOKYO (JP); MASAYUKI TANAKA, TOKYO (JP); KENTARO HAYASHI, TOKYO (JP); RINTARO KODA, TOKYO (JP)

(21) Appl. No.: 18/005,151

(22) PCT Filed: Jun. 30, 2021
(86) PCT No.: PCT/JP2021/024690

§ 371 Date: Jan. 11, 2023

(30) Foreign Application Priority Data
Jul. 21, 2020 (JP) 2020-124411

(51) Int. Cl. H01S 5/183; H01S 5/343

(52) U.S. Cl. CPC H01S 5/18361; H01S 5/343

(57) ABSTRACT

A semiconductor laser element includes: a resonator structure including a stacked structure in which a first compound semiconductor layer, an active layer, and a second compound semiconductor layer are stacked; and a first light reflective layer and a second light reflective layer which are provided at both ends along a resonance direction of the resonator structure. When an oscillation wavelength is set to λ, each of the first light reflective layer and the second light reflective layer includes a refractive index periodic structure including, in a stacked manner, a plurality of thin films each having an optical film thickness of k0 (λ/4). A phase shift layer is provided inside at least one light reflective layer of the first light reflective layer or the second light reflective layer.

### TECHNICAL FIELD

The present disclosure relates to a semiconductor laser element.

### BACKGROUND ART

In a light-emitting element including a surface-emitting laser element (VCSEL), typically, laser light is resonated between two light reflective layers (Distributed Bragg Reflector layers, DBR layers) to thereby generate laser oscillation. In addition, in a surface-emitting laser element having a stacked structure in which an n-type compound semiconductor layer (a first compound semiconductor layer), an active layer (a light-emitting layer) including a compound semiconductor, and a p-type compound semiconductor layer (a second compound semiconductor layer) are stacked, typically, a second electrode including a transparent electrically-conductive material is formed on the p-type compound semiconductor layer, and a second light reflective layer including a stacked structure of an insulating material is formed on the second electrode. In addition, a first light reflective layer including a stacked structure of an insulating material, and a first electrode are formed on the n-type compound semiconductor layer (in a case where the n-type compound semiconductor layer is formed on an electrically-conductive substrate, on an exposed surface of the substrate).

A structure in which the first light reflective layer also functions as a concave mirror is disclosed in, for example, WO2018/083877A1. Here, in the technique disclosed in this International Publication, for example, an n-type compound semiconductor layer is provided with a convex part with respect to an active layer, and a first light reflective layer is formed on the convex part.

### CITATION LIST

### Patent Literature

PTL 1: WO2018/083877A1

### SUMMARY OF THE INVENTION

Incidentally, in a case where a resonator length is about 1 µm in a surface-emitting laser element, a longitudinal mode interval is 10 nm or more. Accordingly, an oscillation wavelength of the surface-emitting laser element having such a resonator length is stable with respect to an operating temperature or an operating current, and is also in a single longitudinal mode. In addition, in the surface-emitting laser element, as the resonator length becomes longer, the longitudinal mode interval becomes shorter. Accordingly, the oscillation wavelength of the surface-emitting laser element having a long resonator length becomes unstable with respect to the operating temperature or the operating current, and the longitudinal mode also tends to be a multimode. In addition, in general, the resonator length is about 1 mm in an edge light-emitting semiconductor laser element, and thus the longitudinal mode interval is on the order of 0.1 nm. Meanwhile, a gain of a typical semiconductor material has a band of about several nm, and a gain peak wavelength depends on a temperature. Therefore, for example, in an edge-emitting semiconductor laser element, the longitudinal mode is changed to hop by the operating temperature or the operating current.

It is therefore an object of the present disclosure to provide a semiconductor laser element having a configuration and a structure in which an oscillation wavelength is stable with respect to an operating temperature or an operating current.

A semiconductor laser element of the present disclosure for achieving the above object includes:
a resonator structure including a stacked structure in which a first compound semiconductor layer, an active layer, and a second compound semiconductor layer are stacked; and
a first light reflective layer and a second light reflective layer which are provided at both ends along a resonance direction of the resonator structure, in which, when an oscillation wavelength is set to λ0,
the first light reflective layer includes a first refractive index periodic structure with a period having an optical film thickness of k10 (λ 0/2) [where 0.9 ≤ k10 ≤ 1.1], the first refractive index periodic structure including, in a stacked manner, at least a plurality of first thin films each having an optical film thickness of k11 (λ 0/4) [where 0.7 ≤ k11 ≤ 1.3] and a plurality of second thin films each having an optical film thickness of k12 (λ 0/4) [where 0.7 ≤ k12 ≤ 1.3],
the second light reflective layer includes a second refractive index periodic structure with a period having an optical film thickness of k20 (λ 0/2) [where 0.9 ≤ k20 ≤ 1.1], the second refractive index periodic structure including, in a stacked manner, at least a plurality of first thin films each having an optical film thickness of k21 (λ 0/4) [where 0.7 ≤ k21 ≤ 1.3] and a plurality of second thin films each having an optical film thickness of k22 (λ 0/4) [where 0.7 ≤ k22 ≤ 1.3], and
a phase shift layer is provided inside at least one light reflective layer of the first light reflective layer or the second light reflective layer.

### BRIEF DESCRIPTION OF THE DRAWINGS

FIG. 1 is a schematic partial end view of a light-emitting element of Example 1.

FIG. 2 is a schematic partial end view of a modification example (Modification Example-1) of the light-emitting element of Example 1.

FIG. 3 is a schematic partial end view of a modification example (Modification Example-2) of the light-emitting element of Example 1.

FIG. 4 is a schematic partial end view of a light-emitting element array of Example 1.

FIG. 5 is a schematic partial end view of the light-emitting element array of Example 1.

FIG. 6 is a schematic partial end view of the light-emitting element array of Example 1.

FIG. 7 is a schematic plan view of an arrangement of a first portion and a second portion of a base part surface in the light-emitting element array of Example 1.

FIG. 8 is a schematic plan view of an arrangement of a first light reflective layer and a first electrode in the light-emitting element array of Example 1.

FIG. 9 is a schematic plan view of an arrangement of the first portion and the second portion of the base part surface in the light-emitting element array of Example 1.

FIG. 10 is a schematic plan view of an arrangement of the first light reflective layer and the first electrode in the light-emitting element array of Example 1.

FIGS. 11A and 11B are each a schematic partial end view of a stacked structure and the like for describing a method of manufacturing the light-emitting element of Example 1.

FIG. 12, subsequent to FIG. 11B, is a schematic partial end view of the stacked structure and the like for describing the method of manufacturing the light-emitting element of Example 1.

FIG. 13, subsequent to FIG. 12, is a schematic partial end view of the stacked structure and the like for describing the method of manufacturing the light-emitting element of Example 1.

FIGS. 14A and 14B, subsequent to FIG. 13, are each a schematic partial end view of a first compound semiconductor layer and the like for describing the method of manufacturing the light-emitting element of Example 1.

FIGS. 15A, 15B and 15C, subsequent to FIG. 14B, are each a schematic partial end view of the first compound semiconductor layer and the like for describing the method of manufacturing the light-emitting element of Example 1.

FIGS. 16A and 16B, subsequent to FIG. 15C, are each a schematic partial end view of the first compound semiconductor layer and the like for describing the method of manufacturing the light-emitting element of Example 1.

FIG. 17 is a schematic partial end view of a light-emitting element of Example 2.

FIG. 18 is a schematic partial end view of a light-emitting element array of Example 2.

FIG. 19 is a schematic plan view of an arrangement of a first portion and a second portion of a base part surface in the light-emitting element array of Example 2.

FIG. 20 is a schematic plan view of an arrangement of a first light reflective layer and a first electrode in the light-emitting element array of Example 2.

FIG. 21 is a schematic plan view of an arrangement of the first portion and the second portion of the base part surface in the light-emitting element array of Example 2.

FIG. 22 is a schematic plan view of an arrangement of the first light reflective layer and the first electrode in the light-emitting element array of Example 2.

FIGS. 23A and 23B are each a schematic partial end view of a first compound semiconductor layer and the like for describing a method of manufacturing the light-emitting element array of Example 2.

FIGS. 24A and 24B, subsequent to FIG. 23B, are each a schematic partial end view of the first compound semiconductor layer and the like for describing a method of manufacturing the light-emitting element of Example 2.

FIGS. 25A and 25B, subsequent to FIG. 24B, are each a schematic partial end view of the first compound semiconductor layer and the like for describing the method of manufacturing the light-emitting element of Example 2.

FIG. 26 is a schematic partial end view of a light-emitting element of Example 3.

FIG. 27 is a schematic partial end view of a light-emitting element of Example 4.

FIG. 28 is a schematic partial end view of a modification example of the light-emitting element of Example 4.

FIGS. 29A, 29B and 29C are each a schematic partial end view of a stacked structure and the like for describing a method of manufacturing a light-emitting element of Example 5.

FIG. 30 is a schematic partial cross-sectional view of a modification example of a light-emitting element of Example 6.

FIGS. 31A, 31B and 31C are each a schematic partial end view of a stacked structure and the like for describing a method of manufacturing a light-emitting element of Example 7.

FIG. 32 is a schematic partial cross-sectional view of a light-emitting element of Example 8.

FIG. 33 is a schematic cross-sectional view of an edge-emitting semiconductor laser element of Example 9.

FIG. 34 is a schematic cross-sectional view of the edge-emitting semiconductor laser element of Example 9.

FIG. 35 is a schematic partial end view of a modification example of the light-emitting element of Example 1 in which the second portion is flat.

FIG. 36A is a diagram illustrating an actually measured value and a calculated value of a light reflectance of a second light reflective layer including a phase shift layer in a semiconductor laser element of Example 1, FIG. 36B is an enlarged view of the actually measured value and the calculated value, at around a wavelength of 445 nm, of the light reflectance of the second light reflective layer including the phase shift layer illustrated in FIG. 36A, and FIG. 36C is a diagram illustrating an actually measured value and a calculated value of a light reflectance of a second light reflective layer in Comparative Example 1.

FIG. 37A is an enlarged view of the actually measured value and the calculated value, at around a wavelength of 445 nm, of the light reflectance of the second light reflective layer including the phase shift layer illustrated in FIG. 36A, FIG. 37B is a diagram illustrating changes in oscillation wavelengths at the time when a current is flowed between the first electrode and a second electrode, and FIG. 37C is a diagram illustrating changes in oscillation wavelengths at the time when a current is flowed between a first electrode and a second electrode in the semiconductor laser element of Comparative Example 1.

FIG. 38 is a diagram illustrating a current (operating current flowed between the first electrode and the second electrode as well as an amount of a change in the oscillation wavelength.

FIG. 39A is a diagram illustrating a relationship between a resonator length LOR and a longitudinal mode interval Δλ, and FIGS. 39B and 39C are each a conceptual diagram of a change in an active layer gain at the time when a current is flowed between the first electrode and the second electrode and a temperature of an active layer is raised.

FIGS. 40A and 40B are each a conceptual diagram illustrating a state in which, in the semiconductor laser element, a change in a temperature of the active layer causes a change in the active layer gain with respect to a wavelength.

FIG. 41A is a graph illustrating an actually measured value and a calculated value of a light reflectance of a second light reflective layer including a phase shift layer in a semiconductor laser element of Modification Example-3 of Example 1, and FIG. 41B is an enlarged view of the actually measured value and the calculated value, at around a wavelength of 430 nm to 460 nm, of the light reflectance of the second light reflective layer including the phase shift layer illustrated in FIG. 41A.

FIG. 42A is a graph illustrating an actually measured value and a calculated value of a light reflectance of a second light reflective layer including a phase shift layer in a semiconductor laser element of Modification Example-4 of Example 1, and FIG. 42B is an enlarged view of the actually measured value and the calculated value, at around a wavelength of 450 nm, of the light reflectance of the second light reflective layer including the phase shift layer illustrated in FIG. 42A.

FIG. 43A is a graph illustrating an actually measured value and a calculated value of a light reflectance of a second light reflective layer including a phase shift layer in a semiconductor laser element of Modification Example-6 of Example 1, and FIG. 43B is an enlarged view of the actually measured value and the calculated value, at around a wavelength of 450 nm, of the light reflectance of the second light reflective layer including the phase shift layer illustrated in FIG. 43A.

### MODES FOR CARRYING OUT THE INVENTION

Hereinafter, description is given of the present disclosure on the basis of Examples with reference to the drawings. However, the present disclosure is not limited to Examples, and various numerical values and materials in Examples are illustrative. It is to be noted that the description is given in the following order.
1. General Description of Semiconductor Laser Element of Present Disclosure
2. Example 1 (Semiconductor Laser Element and Surface-Emitting Laser Element of Present Disclosure, Light-Emitting Element of First Configuration, Light-Emitting Element of (1-A)th Configuration, Light-Emitting Element of Second Configuration)
3. Example 2 (Modification of Example 1, Light-Emitting Element) of (1-B)th Configuration
4. Example 3 (Modification of Examples 1 to 2, Light-Emitting Element of Third Configuration)
5. Example 4 (Modification of Examples 1 to 2, Light-Emitting Element of Fourth Configuration)
6. Example 5 (Modification of Example 4)
7. Example 6 (Modification of Examples 1 to 5)
8. Example 7 (Another Method of Manufacturing Light-Emitting Element of Present Disclosure)
9. Example 8 (Modification of Examples 1 to 6)
10. Example 9 (Semiconductor Laser Element and Edge-Emitting Semiconductor Laser Element of Present Disclosure)
11. Others

### General Description of Semiconductor Laser Element of Present Disclosure

In a semiconductor laser element of the present disclosure, a mode may be adopted in which the number of phase shift layers may be one or more and five or less. In addition, in a case where the number of the phase shift layers is two or more, a mode may be adopted in which a first thin film or a second thin film is disposed between a phase shift layer and a phase shift layer, or in which the first thin film and the second thin film are disposed therebetween.

In the semiconductor laser element of the present disclosure including various preferred modes described above, a mode may be adopted in which the phase shift layer is not provided at an edge part of a refractive index periodic structure.

Furthermore, in the semiconductor laser element of the present disclosure including the various preferred modes described above, a mode may be adopted in which an optical film thickness of the phase shift layer is 0.1 times or more and 50 times or less of λ0. In addition, in this case, a mode may be adopted in which a material configuring the phase shift layer is the same as a material configuring the first thin film, or is the same as a material configuring the second thin film. However, this is not limitative; a mode may also be adopted in which the material configuring the phase shift layer differs from the material configuring the first thin film and differs from the material configuring the second thin film.

The refractive index periodic structure may have a structure in which two kinds of thin films are stacked, or may have a structure in which three or more kinds of thin films are stacked.

The material configuring the first thin film differs from the material configuring the second thin film. In addition, a material configuring the first thin film in a first light reflective layer may be the same as or may be different from a material configuring the first thin film or the second thin film in a second light reflective layer. The material configuring the second thin film in the first light reflective layer may be the same as or may be different from the material configuring the first thin film or the second thin film in the second light reflective layer. That is, when the followings are set:
First light reflective layer
   Material configuring first thin film: MT1-1
   Material configuring second thin film: MT1-2
Second light reflective layer
   Material configuring first thin film: MT2-1
   Material configuring second thin film: MT2-2
Material configuring phase shift layer: MT3, it is given fact that
there is a relationship of:
$$\text{MT1-1} \neq \text{MT1-2 and MT2-1} \neq \text{MT2-2, and} \qquad \text{(A)}$$
as for MT1-1,
there are relationships of:

$$\text{MT1-1} = \text{MT2-1;} \qquad \text{(B-1)}$$

$$\text{MT1-1} \neq \text{MT2-1;} \qquad \text{(B-2)}$$

$$\text{MT1-1} = \text{MT2-2; or} \qquad \text{(B-3)}$$

$$\text{MT1-1} \neq \text{MT2-2, and} \qquad \text{(B-4)}$$
as for MT1-2,
there are relationships of:

$$\text{MT1-2} = \text{MT2-1;} \qquad \text{(C-1)}$$

$$\text{MT1-2} \neq \text{MT2-1;} \qquad \text{(C-2)}$$

$$\text{MT1-2} = \text{MT2-2; or} \qquad \text{(C-3)}$$

$$\text{MT1-2} \neq \text{MT2-2} \text{.} \qquad \text{(C-4)}$$

In addition, in a case where the phase shift layer is provided inside the first light reflective layer,
as for MT3,
there are relationships of:

$$\text{MT3} = \text{MT1-1;} \qquad \text{(D-1)}$$

$$\text{MT3} = \text{MT1-2; or} \qquad \text{(D-2)}$$

$$\text{MT3} \neq \text{MT1-1 and MT3} \neq \text{MT1-2, and} \qquad \text{(D-3)}$$
in a case where the phase shift layer is provided inside the second light reflective layer,
as for MT3,
there are relationships of:

$$\text{MT3} = \text{MT2-1;} \qquad \text{(E-1)}$$

$$\text{MT3} = \text{MT2-2; or} \qquad \text{(E-2)}$$

$$\text{MT3} \neq \text{MT2-1 and MT3} \neq \text{MT2-2} \text{.} \qquad \text{(E-3)}$$

Furthermore, in the semiconductor laser element of the present disclosure including the various preferred modes described above, a mode may be adopted in which the optical film thickness of the phase shift layer satisfies k3(λ0/4) (2r + 1) [where r is an integer of 100 or less, and 0.9 ≤ k3 ≤ 1.1]. However, this is not limitative, and a mode may also be broadly adopted in which the optical film thickness of the phase shift layer is an optical film thickness other than k3′(λ0/4) (2r′) [where r′ is an integer of 100 or less, and 0.9 ≤ k3′ ≤ 1.1].

As described above, the phase shift layer is a layer that disturbs (disturbs) a periodic structure in a refractive index periodic structure (distributed Bragg reflector condition, a film structure satisfying DBR condition) of the first light reflective layer or the second light reflective layer, and may be referred to as a “periodic structure disturbance layer” or may be referred to as a “non-periodic layer”.

Furthermore, in the semiconductor laser element of the present disclosure including the various preferred modes described above, a configuration may be adopted in which
the stacked structure includes, in a stacked manner,
   a first compound semiconductor layer having a first surface and a second surface opposed to the first surface,
   an active layer facing the second surface of the first compound semiconductor layer, and
   a second compound semiconductor layer having a first surface facing the active layer and a second surface opposed to the first surface,
the first light reflective layer is formed on a base part surface located on side of the first surface of the first compound semiconductor layer,
the second light reflective layer is formed on side of the second surface of the second compound semiconductor layer; and
the semiconductor laser element includes a surface-emitting laser element. It is to be noted that the semiconductor laser element having such a configuration may be referred to as a “surface-emitting laser element in the present disclosure” in some cases for the sake of convenience. In such cases, a configuration may be adopted in which the first light reflective layer functions as a concave mirror, and
the second light reflective layer has a flat shape, and in such a surface-emitting laser element in the present disclosure, a configuration may be adopted in which a resonator length LOR is 1 × 10⁻⁵ m or more. Examples of the upper limit of the resonator length LOR may include, but not limited to, 1 × 10⁻³ m.

Here, the “resonator length” is defined as a distance between a surface of the first light reflective layer facing the stacked structure and a surface of the second light reflective layer facing the stacked structure. In addition, a resonator structure, the first light reflective layer, and the second light reflective layer configure a resonator.

Alternatively, in the semiconductor laser element of the present disclosure including the various preferred modes described above, a configuration may be adopted in which
the stacked structure includes, in a stacked manner,
   a first compound semiconductor layer having a first surface and a second surface opposed to the first surface,
   an active layer facing the second surface of the first compound semiconductor layer, and
   a second compound semiconductor layer having a first surface facing the active layer and a second surface opposed to the first surface,
the stacked structure is provided with a first edge surface that outputs a portion of laser light generated in the active layer and reflects the remainder, and a second edge surface that is opposed to the first edge surface and reflects the laser light generated in the active layer,
the first edge surface is provided with the first light reflective layer, and
the second edge surface is provided with the second light reflective layer. It is to be noted that the semiconductor laser element having such a configuration may be referred to as an “edge-emitting semiconductor laser element in the present disclosure” in some cases for the sake of convenience. The resonator structure, the first light reflective layer, and the second light reflective layer configure the resonator.

In any of the semiconductor laser elements of the present disclosure including the various preferred modes and configurations described above (hereinafter, these may be collectively referred to as a “semiconductor laser element or the like of the present disclosure” in some cases), a mode may be adopted in which the light reflective layer provided with the phase shift layer has an etalon structure. Here, the etalon structure refers to an interference system having two reflective surfaces separated by a certain distance, and a wavelength spectrum of transmitted light exhibits a large light transmittance peak at or near a resonance wavelength.

The semiconductor laser element or the like of the present disclosure preferably oscillates in a single longitudinal mode; however, this is not limitative. When a ratio between intensity of laser light at an oscillation wavelength in a longitudinal mode and intensity of laser light at an oscillation wavelength in a proximity mode adjacent to the oscillation wavelength (intensity ratio, SMSR: Side Mode Suppression Ratio) is 30 dB or more, it is assumed that the oscillation is performed at the single longitudinal mode.

In addition, in the semiconductor laser element or the like of the present disclosure, a light reflectance Ref2 at a wavelength near the oscillation wavelength of the semiconductor laser element is lower than a light reflectance Ref1 at the oscillation wavelength of the semiconductor laser element. The difference between the oscillation wavelength of the semiconductor laser element and the wavelength near the oscillation wavelength of the semiconductor laser element is within ±5 nm. In addition, it is preferable to satisfy Ref2/Ref1 ≤ 0.999.

Furthermore, in the semiconductor laser element or the like of the present disclosure, the oscillation wavelength is hardly changed by the operating temperature. Here, the phrase “the oscillation wavelength is hardly changed” means that a wavelength change is ±1 nm or less. Examples of the lower limit and the upper limit of the operating temperature may include, but not limited to, 0° C. and 80° C.; when the wavelength change is ±1 nm or less within a range of the operating temperature, it is assumed that “the oscillation wavelength is hardly changed”.

In addition, in the semiconductor laser element or the like of the present disclosure, the oscillation wavelength is hardly changed by an operating current. Here, the phrase “the oscillation wavelength is hardly changed by the operating current” means that the wavelength change is ±1 nm or less. Examples of the lower limit and the upper limit of the operating current may include, but not limited to, 1 milliampere and 20 milliamperes; when the wavelength change is ±1 nm or less within a range of the operating current, it is assumed that “the oscillation wavelength is hardly changed by the operating current”.

Furthermore, in the semiconductor laser element or the like of the present disclosure, the oscillation wavelength is kept constant even when an active layer gain fluctuates with respect to the wavelength. Here, the phrase “the oscillation wavelength is kept constant even when the active layer gain fluctuates with respect to the wavelength” means that the wavelength change is ±1 nm or less.

When, in the semiconductor laser element or the like of the present disclosure, the first thin film and the second thin film that configure the refractive index periodic structure are referred to as “film A” and “film B”, respectively, for the sake of convenience, and the phase shift layer is referred to as “film C” for the sake of convenience, the refractive index periodic structure has a stacked structure such as film A, film B, film A, film B, film A, film B, ..., film A, film B, film A, and film B, whereas film C is inserted at any location except edge parts of such a stacked structure. That is, for example, a structure such as film A, film B, film A, film B, film C, film A, film B, ..., film A, film B, film A, and film B may be adopted; alternatively, a structure such as film A, film B, film A, film B, film A, film C, film B, ..., film A, film B, film A, and film B may be adopted. It is to be noted that a stacked unit of the first thin film (film A) and the second thin film (film B), or a stacked unit of the first thin film (film B) and the second thin film (film A) may be referred to as a “light reflective stacked film” in some cases for the sake of convenience.

In the surface-emitting laser element according to the present disclosure, a mode may be adopted in which a convex part is formed, with respect to the second surface of the first compound semiconductor layer, at a base part surface portion where the first light reflective layer is formed (which portion may be referred to as a “first portion” in some cases). In addition, in the surface-emitting laser element according to the present disclosure, a mode may be adopted in which a concave part is formed, with respect to the second surface of the first compound semiconductor layer, at a base part surface portion where the first light reflective layer is not formed (which portion may be referred to as a “second portion” in some cases, and surrounds the first portion). Such a mode is referred to as a “light-emitting element of a first configuration” for the sake of convenience. However, no limitation is made to such a mode, and a mode may also be adopted in which the second portion is flat. The second portion extends from the first portion; an extension part of the first light reflective layer may be formed in the second portion in some cases, or the extension part of the first light reflective layer may not be formed in the second portion in some cases.

In the light-emitting element of the first configuration, it is preferable that the base part surface be differentiable. That is, a mode may be adopted in which the base part surface is smooth. Here, “smooth” is an analytical term. For example, when a real variable function f(x) is differentiable in a < x < b and f′(x) is continuous, it can be said to be, in a keyword-like expression, continuously differentiable, or is also expressed as being smooth.

Here, when the base part surface is expressed by z = f(x, y), a differential value at the base part surface is obtainable by:

$$\partial \text{z} / \partial \text{x} = \left[\partial \text{f} \left(\text{x, y}\right) / \partial \text{x}\right] \text{y, and}$$

$$\partial \text{z} / \partial \text{y} = \left[\partial \text{f} \left(\text{x, y}\right) / \partial \text{y}\right] \text{x} \text{.}$$

In the light-emitting element of the first configuration, a boundary between the first portion and the second portion is definable as:
(1) in a case where the first light reflective layer does not extend to the second portion, an outer peripheral part of the first light reflective layer; or
(2) in a case where the first light reflective layer extends to the second portion, a portion in which an inflection point is present in the base part surface that lies astride the first portion and the second portion.

In the light-emitting element of the first configuration, as described above, a configuration may be adopted in which the second portion is a concave part with respect to the second surface of the first compound semiconductor layer (the second portion has a downwardly convex shape with respect to the second surface of the first compound semiconductor layer). The light-emitting element of the first configuration having such a configuration is referred to as a “light-emitting element of a (1-A)th configuration”. In addition, in the light-emitting element of the (1-A)th configuration, a configuration may be adopted in which a center part of the first portion is located on a vertex of a square lattice or on a vertex of an equilateral triangular lattice. In the former case, a configuration may be adopted in which a center part of the second portion is located on a vertex of a square lattice. In the latter case, a configuration may be adopted in which the center part of the second portion is located on a vertex of an equilateral triangular lattice. In the light-emitting element of the (1-A)th configuration, it is preferable that the base part surface be differentiable astride the first portion and the second portion.

In the light-emitting element of the (1-A)th configuration, examples of shapes of [the first portion/the second portion in a range from a peripheral part to a center part] include the following cases:
(A) [an upwardly convex shape/a downwardly convex shape];
(B) [an upwardly convex shape/a downwardly convex shape continuing to a line segment];
(C) [an upwardly convex shape/an upwardly convex shape continuing to a downwardly convex shape];
(D) [an upwardly convex shape/an upwardly convex shape continuing to a downwardly convex shape and to a line segment];
(E) [an upwardly convex shape/a line segment continuing to a downwardly convex shape]; and
(F) [an upwardly convex shape/a line segment continuing to a downwardly convex shape and to a line segment]. It is to be noted that in the light-emitting element, there are also cases where the base part surface terminates at the center part of the second portion.

Alternatively, a configuration may be adopted in which the second portion has a downwardly convex shape, and an upwardly convex shape extending from the downwardly convex shape, toward the center part of the second portion, with respect to the second surface of the first compound semiconductor layer. The light-emitting element of the first configuration having such a configuration is referred to as a “light-emitting element of a (1-B)th configuration”. In addition, in the light-emitting element of the (1-B)th configuration, a configuration may be adopted in which L2nd > L1 is satisfied, where L1 is a distance from the second surface of the first compound semiconductor layer to the center part of the first portion, and L2nd is a distance from the second surface of the first compound semiconductor layer to the center part of the second portion, or a configuration may be adopted in which

$$\text{R1} > \text{R2nd}$$

is satisfied, where R1 is a curvature radius of the center part of the first portion (i.e., a curvature radius of the first light reflective layer), and R2nd is a curvature radius of the center part of the second portion. It is to be noted that examples of a value of L2nd/L1 may include, but not limited to, 1 < L2nd/L1 ≤ 100; and examples of a value of R1/R2nd may include, but not limited to, 1 < R1/R2nd ≤ 100.

In the light-emitting element of the (1-B)th configuration including the preferred configurations described above, a configuration may be adopted in which the center part of the first portion is located on a vertex of a square lattice. In this case, a configuration may be adopted in which the center part of the second portion is located on a vertex of a square lattice. Alternatively, a configuration may be adopted in which the center part of the first portion is located on a vertex of an equilateral triangular lattice. In this case, a configuration may be adopted in which the center part of the second portion is located on a vertex of an equilateral triangular lattice.

In the light-emitting element of the (1-B)th configuration, examples of the shapes of [the first portion/the second portion in a range from a peripheral part to a center part] include the following cases:
(A) [an upwardly convex shape/a downwardly convex shape continuing to an upwardly convex shape];
(B) [an upwardly convex shape/an upwardly convex shape continuing to a downwardly convex shape, and to an upwardly convex shape]; and
(C) [an upwardly convex shape/a line segment continuing to a downwardly convex shape, and to an upwardly convex shape].

Alternatively, a configuration may be adopted in which the second portion has an annular convex shape surrounding the first portion and a downwardly convex shape extending from the annular convex shape toward the first portion, with respect to the second surface of the first compound semiconductor layer. The light-emitting element of the first configuration having such a configuration is referred to as a “light-emitting element of a (1-C)th configuration”.

In the light-emitting element of the (1-C)th configuration, a configuration may be adopted in which

$$\text{L2nd′} > \text{L1}$$

is satisfied, where L1 is a distance from the second surface of the first compound semiconductor layer to the center part of the first portion, and L2nd′ is a distance from the second surface of the first compound semiconductor layer to an apex part of the annular convex shape of the second portion, or a configuration may be adopted in which

$$\text{R1} > \text{R2nd′}$$

is satisfied, where R1 is a curvature radius of the center part of the first portion (i.e., a curvature radius of the first light reflective layer), and R2nd′ is a curvature radius of the apex part of the annular convex shape of the second portion. It is to be noted that examples of the value of L2nd′/L1 may include, but not limited to, 1 < L2nd′/L1 ≤ 100, and examples of the value of R1/R2nd′ may include, but not limited to, 1 < R1/R2nd′ ≤ 100. It is desirable that a curvature radius R2nd of the center part of the second portion be 1 × 10⁻⁶ m or more, preferably 3 × 10⁻⁶ m or more, and more preferably 5 × 10⁻⁶ m or more. It is desirable that a curvature radius R2nd′ of the apex part of the annular convex shape of the second portion be 1 × 10⁻⁶ m or more, preferably 3 × 10⁻⁶ m or more, and more preferably 5 × 10⁻⁶ m or more.

In the light-emitting element of the (1-C)th configuration, examples of shapes of [the first portion/the second portion in a range from a peripheral part to a center part] include the following cases:
(A) [an upwardly convex shape/a downwardly convex shape continuing to an upwardly convex shape, and to a downwardly convex shape];
(B) [an upwardly convex shape/a downwardly convex shape continuing to an upwardly convex shape, downwardly convex shape, and to a line segment];
(C) [an upwardly convex shape/an upwardly convex shape continuing to a downwardly convex shape, an upwardly convex shape, and to a downwardly convex shape];
(D) [an upwardly convex shape/an upwardly convex shape continuing to a downwardly convex shape, an upwardly convex shape, a downwardly convex shape, and to a line segment];
(E) [an upwardly convex shape/a line segment continuing to a downwardly convex shape, an upwardly convex shape, and to a downwardly convex shape]; and
(F) [an upwardly convex shape/a line segment continuing to a downwardly convex shape, an upwardly convex shape, a downwardly convex shape, and to a line segment]. It is to be noted that in the light-emitting element, there are also cases where the base part surface terminates at the center part of the second portion.

In the light-emitting element of the (1-B)th configuration or the light-emitting element of the (1-C)th configuration including the preferred configurations described above, a configuration may be adopted in which a bump is provided in a portion on the side of the second surface of the second compound semiconductor layer opposed to a convex-shaped portion in the second portion. Alternatively, in the light-emitting element of the (1-A)th configuration including the preferred configurations described above, a configuration may be adopted in which a bump is provided in a portion on the side of the second surface of the second compound semiconductor layer opposed to the center part of the first portion. Examples of the bump may include a gold (Au) bump, a solder bump, and an indium (In) bump. A method of providing the bump may be a known method. Specifically, the bump is provided on a second pad electrode (to be described later) provided on a second electrode, or on an extending part of the second pad electrode.

Alternatively, a brazing material may be used instead of the bump. Examples of the brazing material may include In (indium, melting point: 157° C.); an indium-gold-based low-melting-point alloy; a tin (Sn)-based high-temperature solder such as Sn₈₀Ag₂₀ (melting point: 220° C. to 370° C.) or Sn₉₅Cu₅ (melting point: 227° C. to 370° C.); a lead (Pb)-based high-temperature solder such as Pb_{97.5}Ag_{2.5} (melting point: 304° C.), Pb_{94.5}Ag_{5.5} (melting point: 304° C. to 365° C.), or Pb_{97.5}Ag_{1.5}Sn_{1.0} (melting point: 309° C.); a zinc (Zn)-based high-temperature solder such as Zn₉₅Al₅ (melting point: 380° C.); a tin-lead-based standard solder such as Sn₅Pb₉₅ (melting point: 300° C. to 314° C.) or Sn₂Pb₉₈ (melting point: 316° C. to 322° C.); or a brazing material such as Au₈₈Ga₁₂ (melting point: 381° C.) (all the subscripts represent atomic %).

Furthermore, in the surface-emitting laser element according to the present disclosure including the preferred modes and configurations described above, a mode may be adopted in which the first surface of the first compound semiconductor layer configures the base part surface. The light-emitting element having such a configuration is referred to as a “light-emitting element of a second configuration” for the sake of convenience. Alternatively, a configuration may be adopted in which a compound semiconductor substrate is provided between the first surface of the first compound semiconductor layer and the first light reflective layer, and the base part surface is configured by a surface of the compound semiconductor substrate. The light-emitting element having such a configuration is referred to as a “light-emitting element of a third configuration” for the sake of convenience. In this case, for example, a configuration may be adopted in which the compound semiconductor substrate includes a GaN substrate. As the GaN substrate, any of a polar substrate, a semipolar substrate, and a non-polar substrate may be used. A thickness of the compound semiconductor substrate may be, for example, 5 × 10⁻⁵ m to 1 × 10⁻⁴ m, but is not limited to such a value. Alternatively, a configuration may be adopted in which a base material is provided between the first surface of the first compound semiconductor layer and the first light reflective layer. Alternatively, a configuration may be adopted in which the compound semiconductor substrate and the base material are provided between the first surface of the first compound semiconductor layer and the first light reflective layer, and the base part surface is configured by a surface of the base material. The light-emitting element having such a configuration is referred to as a “light-emitting element of a fourth configuration” for the sake of convenience. Examples of a material configuring the base material may include a transparent dielectric material such as TiO₂, Ta₂O₅, or SiO₂, a silicone-based resin, and an epoxy-based resin. It is to be noted that the light-emitting element of the second configuration and the light-emitting element of the first configuration may be combined as appropriate, the light-emitting element of the third configuration and the light-emitting element of the first configuration may be combined as appropriate, or the light-emitting element of the fourth configuration and the light-emitting element of the first configuration may be combined as appropriate. Alternatively, a configuration may be adopted in which a structure in which a second substrate having a first surface and a second surface opposed to the first surface and a first substrate having a first surface and a second surface opposed to the first surface are attached together is provided between the first surface of the first compound semiconductor layer and the first light reflective layer, and the base part surface is configured by the first surface of the first substate. Here, the second surface of the first substrate and the first surface of the second substrate are attached together, the first light reflective layer is formed on the first surface of the first substrate, and a stacked structure is formed on the second surface of the second substrate. The light-emitting element having such a configuration is referred to as a “light-emitting element of a fifth configuration” for the sake of convenience. Examples of the second substrate may include an InP substrate and a GaAs substrate, and examples of the first substrate may include a Si substrate, a SiC substrate, an AlN substrate, and a GaN substrate.

In the surface-emitting laser element according to the present disclosure including the preferred modes and configurations described above, a configuration may be adopted in which a figure drawn by the first portion when the base part surface is cut along a virtual plane including a stacking direction of the stacked structure is a part of a circle, a part of a parabola, a part of a sine curve, a part of an ellipse, or a part of a catenary curve. The figure may not strictly be a part of a circle, may not strictly be a part of a parabola, may not strictly be a part of a sine curve, may not strictly be a part of an ellipse, or may not strictly be a part of a catenary curve. That is, a case where the figure is roughly a part of a circle, a case where the figure is roughly a part of a parabola, a case where the figure is roughly a part of a sine curve, a case where the figure is roughly a part of an ellipse, and a case where the figure is roughly a part of a catenary curve are also encompassed by the case where “the figure is a part of a circle, a part of a parabola, a part of a sine curve, roughly a part of an ellipse, or roughly a part of a catenary curve.” Portions of these curves may be replaced with line segments. That is, a configuration may also be adopted in which a figure drawn by an apex part of the first portion is a part of a circle, a part of a parabola, a part of a sine curve, a part of an ellipse, or a part of a catenary curve, while a figure drawn by a bottom portion of the first portion is a line segment. It is possible to determine the figure drawn by the base part surface by measuring the shape of the base part surface with a measuring instrument, and analyzing thus-obtained data by a least squares method.

Examples of a method of forming a sacrificial layer for forming the first portion and the second portion of the base part surface include: various kinds of printing methods including a screen printing method, an ink jet printing method, and a metal mask printing method; a spin coating method; a transfer method using a metal mold or the like; a nanoimprint method; a 3D printing technique (e.g., a 3D printing technique using a stereolithographic 3D printer or a two-photon absorption micro 3D printer); a physical vapor deposition method (a PVD method including, for example, vacuum deposition method such as an electron beam deposition method or a thermal filament deposition method, a sputtering method, an ion plating method, and a laser ablation method); various kinds of chemical vapor deposition methods (CVD methods); a lift-off method; and a micro processing technique or the like with a pulsed laser, and also combinations of any of these methods and an etching method.

Furthermore, in the surface-emitting laser element according to the present disclosure including the preferred modes and configurations described above, it is desirable that a curvature radius R1 of the center part of the first portion be 1 × 10⁻⁵ m or more, and preferably 3 × 10⁻⁵ m or more. Furthermore, the curvature radius R1 of the center part of the first portion may be 3 × 10⁻⁴ m or more. It is to be noted that, in any case, the value of R1 is a value equal to or greater than a value of the resonator length LOR. That is, R1 ≥ LOR holds true.

In the surface-emitting laser element according to the present disclosure including the preferred modes and configurations described above, or an edge-emitting semiconductor laser element according to the present disclosure, a configuration may be adopted in which the stacked structure includes at least one kind of material selected from the group consisting of a GaN-based compound semiconductor, an InP-based compound semiconductor, and a GaAs-based compound semiconductor. Specifically, the stacked structure may have any of the following configurations:
(a) a configuration including a GaN-based compound semiconductor;
(b) a configuration including an InP-based compound semiconductor;
(c) a configuration including a GaAs-based compound semiconductor;
(d) a configuration including a GaN-based compound semiconductor and an InP-based compound semiconductor;
(e) a configuration including a GaN-based compound semiconductor and a GaAs-based compound semiconductor;
(f) a configuration including an InP-based compound semiconductor and a GaAs-based compound semiconductor; and
(g) a configuration including a GaN-based compound semiconductor, an InP-based compound semiconductor, and a GaAs-based compound semiconductor. Alternatively, a group III-V compound semiconductor in which a group V element includes at least one kind of N (nitrogen), P (phosphorus), or As (arsenic) may be adopted.

Furthermore, in a case where the surface-emitting laser elements according to the present disclosure including the preferred modes and configurations described above are arranged in an array, it is desirable that a formation pitch of the light-emitting elements be 3 µm or more and 50 µm or less, preferably 5 µm or more and 30 µm or less, and more preferably 8 µm or more and 25 µm or less.

In the surface-emitting laser element according to the present disclosure including the preferred modes and configurations described above, a configuration may be adopted in which a value of a thermal conductivity of the stacked structure is higher than a value of a thermal conductivity of the first light reflective layer. The thermal conductivity of a dielectric material configuring the first light reflective layer typically has a value of about 10 watts/(m·K) or less. Meanwhile, the thermal conductivity of the GaN-based compound semiconductor included in the stacked structure has a value of about 50 watts/(m·K) to about 100 watts/(m·K).

In the surface-emitting laser element according to the present disclosure including the preferred modes and configurations described above, materials of various compound semiconductor layers (including the compound semiconductor substrate) located between the active layer and the first light reflective layer are preferably free from a modulation in a refractive index of 10% or more (free from a difference in refractive index of 10% or more with respect to an average refractive index of the stacked structure). This makes it possible to suppress the occurrence of disturbance of a light field in a resonator.

With the surface-emitting laser element according to the present disclosure including the preferred modes and configurations described above, it is possible to configure a surface-emitting laser element (vertical resonator laser, VCSEL) that emits laser light through the first light reflective layer, or a surface-emitting laser element that emits laser light through the second light reflective layer. In some cases, a semiconductor-laser-element manufacturing substrate (to be described later) may be removed.

In the surface-emitting laser element according to the present disclosure, a configuration may be adopted in which the stacked structure specifically includes, for example, an AlInGaN-based compound semiconductor, as described above. Here, more specific examples of the AlInGaN-based compound semiconductor may include GaN, AlGaN, InGaN, and AlInGaN. Furthermore, boron (B) atoms, thallium (Tl) atoms, arsenic (As) atoms, phosphorus (P) atoms, or antimony (Sb) atoms may be included in these compound semiconductors, as desired. The active layer desirably has a quantum well structure. Specifically, the active layer may have a single quantum well structure (SQW structure), or may have a multiquantum well structure (MQW structure). While the active layer having the quantum well structure has a structure in which at least one well layer and at least one barrier layer are stacked, examples of a combination of (a compound semiconductor included in the well layer, a compound semiconductor included in the barrier layer) may include (In_{y}Ga_{(1-y)}N, GaN), (In_{y}Ga_{(1-y)}N, In_{z}Ga_{(1-z)}N) [where y > z], and (In_{y}Ga_{(1-y)}N, AlGaN). The first compound semiconductor layer may include a compound semiconductor of a first electrical conductivity type (e.g., n-type), and the second compound semiconductor layer may include a compound semiconductor of a second electrical conductivity type (e.g., p-type) different from the first electrical conductivity type. The first compound semiconductor layer and the second compound semiconductor layer are also referred to as a first cladding layer and a second cladding layer. The first compound semiconductor layer and the second compound semiconductor layer may each be a layer of a single structure, a layer of a multilayer structure, or a layer of a superlattice structure. Furthermore, the first compound semiconductor layer and the second compound semiconductor layer may each include a composition gradient layer or a concentration gradient layer.

Alternatively, examples of group III atoms included in the stacked structure may include gallium (Ga), indium (In), and aluminum (Al). Examples of group V atoms included in the stacked structure may include arsenic (As), phosphorus (P), antimony (Sb), and nitrogen (N). Specific examples thereof may include AlAs, GaAs, AlGaAs, AlP, GaP, GaInP, AlInP, AlGaInP, AlAsP, GaAsP, AlGaAsP, AlInAsP, GaInAsP, AlInAs, GaInAs, AlGaInAs, AlAsSb, GaAsSb, AlGaAsSb, AlN, GaN, InN, AlGaN, GaNAs, and GaInNAs. Examples of the compound semiconductor included in the active layer may include GaAs, AlGaAs, GaInAs, GaInAsP, GaInP, GaSb, GaAsSb, GaN, InN, GaInN, GaInNAs, and GaInNAsSb.

Examples of the quantum well structure may include a two-dimensional quantum well structure, a one-dimensional quantum well structure (a quantum wire), and a zero-dimensional quantum well structure (a quantum dot). Examples of a material configuring a quantum well may include, but not limited to: Si; Se; chalcopyrite-based compounds including CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂; perovskite-based materials; group III-V compounds including GaAs, GaP, InP, AlGaAs, InGaP, AlGaInP, InGaAsP, GaN, InAs, InGaAs, GaInNAs, GaSb, and GaAsSb; CdSe, CdSeS, CdS, CdTe, In₂Se₃, In₂S₃, Bi₂Se₃, Bi₂S₃, ZnSe, ZnTe, ZnS, HgTe, HgS, PbSe, PbS, TiO₂, and the like.

The stacked structure is formed on a second surface of the semiconductor-laser-element manufacturing substrate, on a second surface of the compound semiconductor substrate, or on the second surface of the second substrate. It is to be noted that the second surface of the semiconductor-laser-element manufacturing substrate is opposed to the first surface of the first compound semiconductor layer, and a first surface of the semiconductor-laser-element manufacturing substrate is opposed to the second surface of the semiconductor-laser-element manufacturing substrate. In addition, the second surface of the compound semiconductor substrate is opposed to the first surface of the first compound semiconductor layer, and a first surface of the compound semiconductor substrate is opposed to the second surface of the compound semiconductor substrate. In addition, the second surface of the second substrate is opposed to the first surface of the first compound semiconductor layer, and a first surface of the second substrate is opposed to the second surface of the first substrate. Examples of the semiconductor-laser-element manufacturing substrate or the first substrate may include a GaN substrate, a sapphire substrate, a GaAs substrate, a SiC substrate, an alumina substrate, a ZnS substrate, a ZnO substrate, an AlN substrate, a LiMgO substrate, a LiGaO₂ substrate, a MgAl₂O₄ substrate, an InP substrate, a Si substrates, and these substrates with an underlying layer or a buffer layer formed on a surface (a principal surface) thereof, among which the GaN substrate is preferably used owing to its low deficiency density. In addition, examples of the compound semiconductor substrate or the second substrate may include a GaN substrate, an InP substrate, and a GaAs substrate. While the GaN substrate is known to vary in characteristic thereof among a polar characteristic, a nonpolar characteristic, and a semipolar characteristic depending on a growth surface, any principal surface (second surface) of the GaN substrate is usable for formation of the compound semiconductor layer. In addition, regarding the principal surface of the GaN substrate, crystal orientation planes that are generally called by such names as A plane, B plane, C plane, R plane, M plane, N plane, and S plane or planes provided by making these planes offset in a specific direction, and the like are also usable, depending on the crystal structure (e.g., a cubic type, a hexagonal type, or the like). Examples of a method of forming various compound semiconductor layers included in the light-emitting element may include, but not limited to, an organometallic chemical vapor deposition method (MOCVD method, Metal Organic-Chemical Vapor Deposition method, MOVPE method, Metal Organic-Vapor Phase Epitaxy method), a molecular beam epitaxy method (MBE method), a hydride vapor phase growth method (HVPE method) in which a halogen contributes to transportation or reaction, an atomic layer deposition method (ALD method, Atomic Layer Deposition method), a migration-enhanced epitaxy method (MEE method, Migration-Enhanced Epitaxy method), a plasma-assisted physical vapor deposition method (PPD method), and the like.

GaAs and InP materials are the same in that they are of a zincblende structure. Principal planes of the compound semiconductor substrate and the second substrate including these materials may include planes provided by making these planes offset in a specific direction, in addition to planes including a (100) plane, a (111)AB plane, a (211)AB plane, a (311)AB plane. It is to be noted that “AB” means that offset directions are different by 90°. Whether a principal material of the plane belongs to the group III or the group V depends on the offset direction. By controlling the crystal plane orientation and film formation conditions, unevenness in composition and dot shape are controllable. As a film formation method, one such as an MBE method, an MOCVD method, an MEE method, or an ALD method is typically used, as with the GaN-based compound materials; however, these methods are not limitative.

Here, examples of an organogallium source gas in the MOCVD method may include trimethylgallium (TMG) gas and triethylgallium (TEG) gas, and examples of a nitrogen source gas may include ammonium gas and hydrazine gas. In forming a GaN-based compound semiconductor layer having an n-type electrical conductivity, for example, it is sufficient if silicon (Si) is added as an n-type impurity (n-type dopant). In forming a GaN-based compound semiconductor layer having a p-type electrical conductivity, for example, it is sufficient if magnesium (Mg) is added as a p-type impurity (p-type dopant). In a case where aluminum (Al) or indium (In) is included as constituent atoms of the GaN-based compound semiconductor layer, it is sufficient if trimethylaluminum (TMA) gas is used as an Al source, and it is sufficient if trimethylindium (TMI) gas is used as an In source. Furthermore, it is sufficient if monosilane gas (SiH₄ gas) is used as a Si source, and it is sufficient if biscyclopentadienylmagnesium gas, methylcyclopentadienylmagnesium, or biscyclopentadienylmagnesium (Cp₂Mg) is used as a Mg source. It is to be noted that examples of the n-type impurity (n-type dopant) other than Si may include Ge, Se, Sn, C, Te, S, O, Pd, and Po, and examples of the p-type impurity (p-type dopant) other than Mg may include Zn, Cd, Be, Ca, Ba, C, Hg, and Sr.

In a case where an InP-based compound semiconductor or an GaAs-based compound semiconductor is included in the stacked structure, in regard to a group III raw material, TMGa, TEGa, TMIn, TMAl, or the like i.e., an organometallic raw material, is typically used. Further, in regard to a group V raw material, arsine gas (AsH₃ gas), phosphine gas (PH₃ gas), ammonia (NH₃), or the like is used. It is to be noted that in regard to the group V raw material, an organometallic raw material is used in some cases, and examples thereof may include tertiary butyl arsine (TBAs), tertiary butyl phosphine (TBP), dimethylhydrazine (DMHy), trimethylantimony (TMSb), and the like. These materials decompose at low temperatures, and are therefore effective in low temperature growth. As an n-type dopant, monosilane (SiH₄) is used as a Si source, and hydrogen selenide (H₂Se) or the like is used as a Se source. In addition, dimethylzinc (DMZn), biscyclopentadienylmagnesium (Cp₂Mg), or the like is used as a p-type dopant. Candidates for the dopant materials are materials similar to those in the case with the GaN-based compound semiconductor.

It is sufficient if a support substrate for fixing the second light reflective layer thereon includes, for example, any of the various substrates listed as examples of the semiconductor-laser-element manufacturing substrate, or the support substrate may include an insulating substrate including AlN or the like, a semiconductor substrate including Si, SiC, Ge or the like, a metallic substrate, or an alloy-based substrate. It is preferable to use an electrically-conductive substrate, or it is preferable to use a metallic substrate or an alloy-based substrate, from the viewpoints of mechanical property, elastic deformation or plastic deformation property, heat dissipation property, and the like. An example of the thickness of the support substrate may be 0.05 mm to 1 mm. As a method of fixing the second light reflective layer onto the support substrate, any of known methods including a solder bonding method, a normal temperature bonding method, a bonding method using an adhesive tape, a bonding method using wax bonding, a method using an adhesive, and the like is usable; however, from the viewpoint of securing electrical conductivity, it is desirable to employ the solder bonding method or the normal temperature bonding method. For example, in a case where a silicon semiconductor substrate, which is an electrically-conductive substrate, is used as the support substrate, it is desirable, for suppressing warping resulting from a difference in thermal expansion coefficient, to employ a bonding method that allows for bonding at a low temperature of 400° C. or below. In a case where a GaN substrate is used as the support substrate, the bonding temperature may be 400° C. or higher.

In manufacturing the surface-emitting laser element according to the present disclosure, the semiconductor-laser-element manufacturing substrate may be left unremoved, or may be removed after forming the active layer, the second compound semiconductor layer, the second electrode, and the second light reflective layer sequentially on the first compound semiconductor layer. Specifically, after the active layer, the second compound semiconductor layer, the second electrode, and the second light reflective layer are formed sequentially on the first compound semiconductor layer and subsequently the second light reflective layer is fixed to the support substrate, it is sufficient if the semiconductor-laser-element manufacturing substrate is removed to thereby expose the first compound semiconductor layer (the first surface of the first compound semiconductor layer). Removal of the semiconductor-laser-element manufacturing substrate may be performed by a wet etching method using an aqueous alkali solution such as an aqueous sodium hydroxide solution or an aqueous potassium hydroxide solution, an ammonium solution + an aqueous hydrogen peroxide solution, a sulfuric acid solution + an aqueous hydrogen peroxide solution, a hydrochloric acid solution + an aqueous hydrogen peroxide solution, a phosphoric acid solution + an aqueous hydrogen peroxide solution or the like, a chemical mechanical polishing method (CMP method), a mechanical polishing method, a dry etching method such as a reactive ion etching (RIE) method, a lift-off method using a laser, or the like. Alternatively, a combination of any of these methods may be used to perform removal of the semiconductor-laser-element manufacturing substrate. In a case where the semiconductor-laser-element manufacturing substrate is left unremoved, attaching the first substrate onto the semiconductor-laser-element manufacturing substrate makes it possible to obtain an attached structure, which includes the semiconductor-laser-element manufacturing substrate, of the second substrate and the first substrate.

In a case where the surface-emitting laser elements according to the present disclosure are arranged in an array, a mode may be adopted in which the first electrode electrically coupled to the first compound semiconductor layer is common among a plurality of surface-emitting laser elements, and the second electrode electrically coupled to the second compound semiconductor layer is common among the plurality of surface-emitting laser elements, or is provided individually in the plurality of surface-emitting laser elements, but this is not limitative.

In a case where the semiconductor-laser-element manufacturing substrate remains, it is sufficient if the first electrode is formed on the first surface of the semiconductor-laser-element manufacturing substrate opposed to the second surface thereof, or on the first surface of the compound semiconductor substrate opposed to the second surface thereof. Further, in a case where the semiconductor-laser-element manufacturing substrate does not remain, it is sufficient if the first electrode is formed on the first surface of the first compound semiconductor layer included in the stacked structure. It is to be noted that, in this case, because the first light reflective layer is formed on the first surface of the first compound semiconductor layer, it is sufficient if the first electrode is formed in such a manner as to surround the first light reflective layer, for example. The first electrode desirably has a single-layer configuration or a multilayer configuration including, for example, at least one kind of metal (including alloy) selected from the group consisting of gold (Au), silver (Ag), palladium (Pd), platinum (Pt), nickel (Ni), Ti (titanium), vanadium (V), tungsten (W), chromium (Cr), Al (aluminum), Cu (copper), Zn (zinc), tin (Sn), and indium (In). Specific examples thereof may include Ti/Au, Ti/Al, Ti/Al/Au, Ti/Pt/Au, Ni/Au, Ni/Au/Pt, Ni/Pt, Pd/Pt, and Ag/Pd. It is to be noted that a layer preceding “/” more in the multilayer configuration is located closer to the active layer. This similarly applies also to the description given below. The first electrode may be formed as a film by, for example, a PVD method such as a vacuum deposition method or a sputtering method.

In a case of forming the first electrode in such a manner as to surround the first light reflective layer, a configuration may be adopted in which the first light reflective layer and the first electrode are in contact with each other. Alternatively, a configuration may be adopted in which the first light reflective layer and the first electrode are spaced apart from each other. In some cases, a state where the first electrode is formed to extend to a position on an edge part of the first light reflective layer, or a state where the first light reflective layer is formed to extend to a position on an edge part of the first electrode may be provided, for example.

A configuration may be adopted in which the second electrode includes a transparent electrically-conductive material. Examples of the transparent electrically-conductive material configuring the second electrode may include indium-based transparent electrically-conductive materials [specifically, for example, indium tin oxide (ITO, Indium Tin Oxide, inclusive of Sn-doped In₂O₃, crystalline ITO, and amorphous ITO), indium zinc oxide (IZO, Indium Zinc Oxide), indium gallium oxide (IGO), indium-doped gallium zinc oxide (IGZO, In-GaZnO₄), IFO (F-doped In₂O₃), ITiO (Ti-doped In₂O₃), InSn, and InSnZnO], tin-based transparent electrically-conductive materials [specifically, for example, tin oxide (SnOₓ), ATO (Sb-doped SnO₂), and FTO (F-doped SnO₂)], zinc-based transparent electrically-conductive materials [specifically, for example, zinc oxide (ZnO, inclusive of Al-doped ZnO (AZO) and B-doped ZnO), gallium-doped zinc oxide (GZO), and AlMgZnO (aluminum oxide- and magnesium oxide-doped zinc oxide)], NiO, TiOₓ, and graphene. Alternatively, the second electrode may include a transparent electrically-conductive film including gallium oxide, titanium oxide, niobium oxide, antimony oxide, nickel oxide, or the like as a base layer, or a transparent electrically-conductive material such as a spinel-type oxide or an oxide having a YbFe₂O₄ structure. It is to be noted that although depending on a layout state of the second light reflective layer and the second electrode, the material configuring the second electrode is not limited to a transparent electrically-conductive material, and a metal such as palladium (Pd), platinum (Pt), nickel (Ni), gold (Au), cobalt (Co), or rhodium (Rh) may be used. It is sufficient if the second electrode includes at least one of these materials. The second electrode may be formed as a film by, for example, a PVD method such as a vacuum deposition method or a sputtering method. Alternatively, a low-resistance semiconductor layer is usable as a transparent electrode layer, and in this case, specifically, an n-type GaN-based compound semiconductor layer is usable. Furthermore, in a case where a layer adjacent to the n-type GaN-based compound semiconductor layer is of the p-type, joining both layers through a tunnel junction makes it possible to reduce an electrical resistance at an interface. With the second electrode including the transparent electrically-conductive material, it is possible to spread a current in a lateral direction (in-plane direction of the second compound semiconductor layer), and it is thus possible to supply the current efficiently to a current injection region (to be described later).

In order to establish electrical coupling to an external electrode or circuit (hereinafter, sometimes referred to as an “external circuit or the like”), a first pad electrode and a second pad electrode may be provided on the first electrode and the second electrode. The pad electrodes desirably have a single-layer configuration or a multilayer configuration including at least one kind of metal selected from the group consisting of Ti (titanium), aluminum (Al), Pt (platinum), Au (gold), Ni (nickel), and Pd (palladium). Alternatively, the pad electrodes may have a multilayer configuration, such as a multilayer configuration of Ti/Pt/Au, a multilayer configuration of Ti/Au, a multilayer configuration of Ti/Pd/Au, a multilayer configuration of Ti/Pd/Au, a multilayer configuration of Ti/Ni/Au, or a multilayer configuration of Ti/Ni/Au/Cr/Au. In a case where the first electrode includes an Ag layer or Ag/Pd layers, it is preferable to form a cover metal layer including, for example, Ni/TiW/Pd/TiW/Ni on a surface of the first electrode and to form the pad electrode having, for example, a multilayer configuration of Ti/Ni/Au or a multilayer configuration of Ti/Ni/Au/Cr/Au on the cover metal layer.

The refractive index periodic structure (distributed Bragg reflector structure, Distributed Bragg Reflector layer, DBR layer) included in each of the first light reflective layer and the second light reflective layer includes, for example, a semiconductor multilayer film or a dielectric multilayer film. Examples of the dielectric material may include oxides of Si, Mg, Al, Hf, Nb, Zr, Sc, Ta, Ga, Zn, Y, B, Ti, and the like, nitrides of these elements (e.g., SiN_{X}, AlN_{X}, AlGaN_{X}, GaN_{X}, BN_{X}, and the like), fluorides of these elements, and the like. Specific examples thereof may include SiO_{X}, TiO_{X}, NbO_{X}, ZrO_{X}, TaO_{X}, ZnO_{X}, AlO_{X}, HfO_{X}, SiN_{X}, AlN_{X}, and the like. In addition, it is possible to obtain the light reflective layer, in which a plurality of light reflective stacked films (each having a stacked structure of the first thin film and the second thin film) is stacked, by alternately stacking two or more kinds of dielectric films including dielectric materials having different refractive indices, among these dielectric materials. Examples of the light reflective stacked film may include a multilayer film of SiO_{X}/SiN_{Y}, SiO_{X}/TaO_{X}, SiO_{X}/NbO_{Y}, SiO_{X}/ZrO_{Y}, SiO_{X}/AlN_{Y}, and the like. In order to obtain a desired light reflectance, it is sufficient if the material configuring each dielectric film (the first thin film and the second thin film), the film thickness, the number of films to be stacked, etc. are selected as appropriate. The thickness of each dielectric film (the first thin film and the second thin film) is adjustable as appropriate by the material to be used or the like, and is determined by an oscillation wavelength (light emission wavelength) λ0 and a refractive index n at the oscillation wavelength λ0 of the material used. Specifically, the optical film thickness of each dielectric film is, for example, (λ0/4). For example, in a case of configuring the light reflective stacked film from SiO_{X}/NbO_{Y} in a surface-emitting laser element having an oscillation wavelength λ0 of 410 nm, the film thickness may be, for example, about 40 nm to about 70 nm. The number of the films to be stacked may be, for example, two or more, and preferably about five to about twenty. The thickness of the light reflective layer as a whole may be, for example, about 0.6 µm to about 1.7 µm. In addition, a light reflectance of the light reflective layer is desirably 99% or more. It is also sufficient if the material configuring the phase shift layer is selected as appropriate from the above-described materials, for example. It is to be noted that, as the difference between a refractive index of the material configuring the first thin film and a refractive index of the material configuring the second thin film becomes larger, the light reflectance becomes higher, which is desirable.

It is possible for the light reflective layer and the phase shift layer to be each formed by a known method. Specific examples of the method may include: PVD methods including a vacuum deposition method, a sputtering method, a reactive sputtering method, an ECR plasma sputtering method, a magnetron sputtering method, an ion beam assisted deposition method, an ion plating method, and a laser ablation method; various CVD methods; coating methods including a spraying method, a spin coating method, and a dipping method; a method combining two or more of these methods; and a method combining any of these methods with one or more of total or partial pretreatment, irradiation with an inert gas (Ar, He, Xe or the like) or plasma, irradiation with oxygen gas, ozone gas, or plasma, an oxidation treatment (heat treatment), and an exposure treatment.

The light reflective layer including the phase shift layer is not limited to a particular size or shape, insofar as the light reflective layer covers a current injection region or an element region (which are to be described later). Specific examples of a planar shape of the first light reflective layer may include, but not limited to, a circular shape, an elliptical shape, a rectangular shape, and a polygonal shape (triangular shape, tetragonal shape, hexagonal shape, etc.) including a regular polygonal shape. In addition, the planar shape of the first portion may be similar or approximate to the planar shape of the first light reflective layer. Specific examples of a shape of a boundary between the current injection region and a current non-injection and a planar shape of an opening provided in the element region and a current confinement region may include a circular shape, an elliptical shape, a rectangular shape, and a polygonal shape (triangular shape, tetragonal shape, hexagonal shape, etc.) including a regular polygonal shape. The shape of the boundary between the current injection region and the current non-injection is desirably a similar shape. Here, the “element region” refers to a region into which a confined current is injected, or a region in which light is confined due to a refractive index difference or the like, or a region which is within a region sandwiched between the first light reflective layer and the second light reflective layer and in which laser oscillation is generated, or a region which is within the region sandwiched between the first light reflective layer and the second light reflective layer and which actually contributes to laser oscillation.

Side surfaces and exposed surfaces of the stacked structure may be covered with a coating layer (insulating film). Formation of the coating layer (insulating film) is performable using a known method. The refractive index of a material configuring the coating layer (insulating film) is preferably lower than the refractive index of the material configuring the stacked structure. Examples of the material configuring the coating layer (insulating film) may include SiO_{X}-based materials including SiO₂, SiN_{X}-based materials, SiO_{Y}N_{Z}-based materials, TaO_{X}, ZrO_{X}, AlN_{X}, AlO_{X}, and GaO_{X}. Alternatively, examples of the material configuring the coating layer (insulating film) may include organic materials such as polyimide resin. Examples of a method of forming the coating layer (insulating film) may include PVD methods including a vacuum deposition method and a sputtering method, and CVD methods. Further, the coating layer (insulating film) may also be formed by a coating method.

### Example 1

Example 1 relates to the semiconductor laser element of the present disclosure, in particular, to the surface-emitting laser element according to the present disclosure, and further to the light-emitting elements of the first configuration and the (1-A)th configuration, and the light-emitting element of the second configuration. In the following description, unless otherwise specified, a semiconductor laser element including the surface-emitting laser element is referred to as a “light-emitting element”.

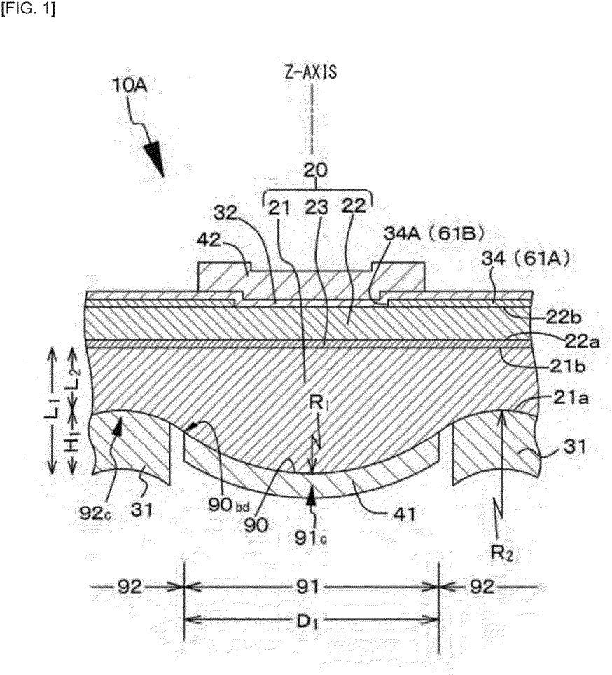

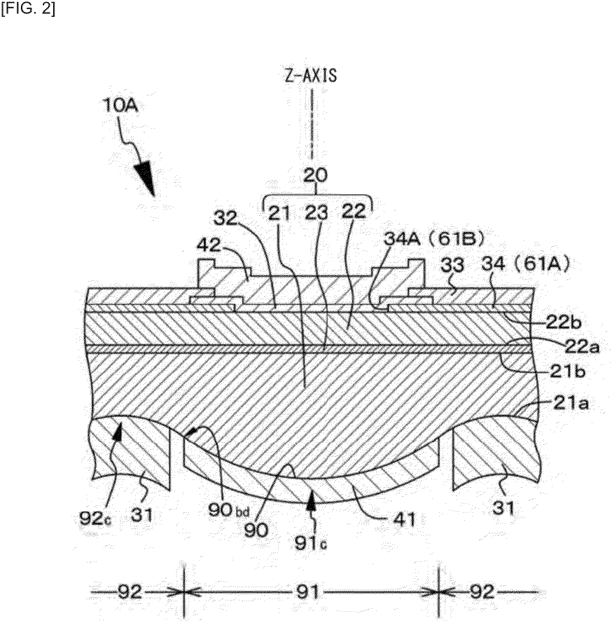

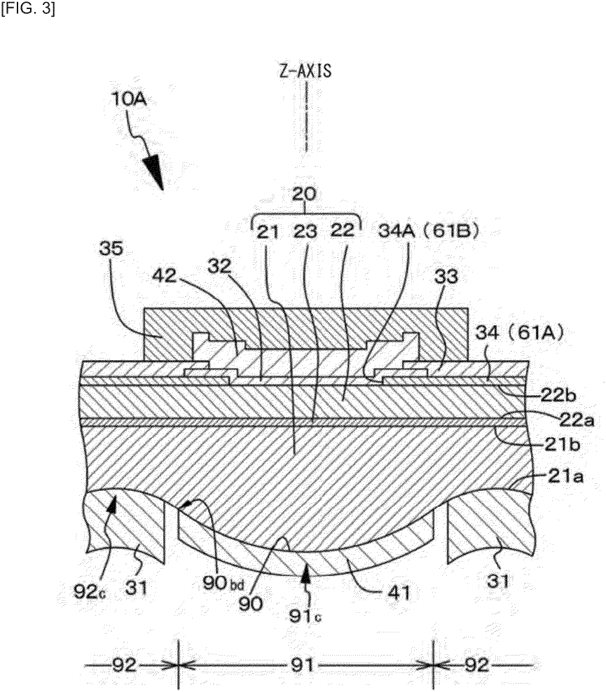

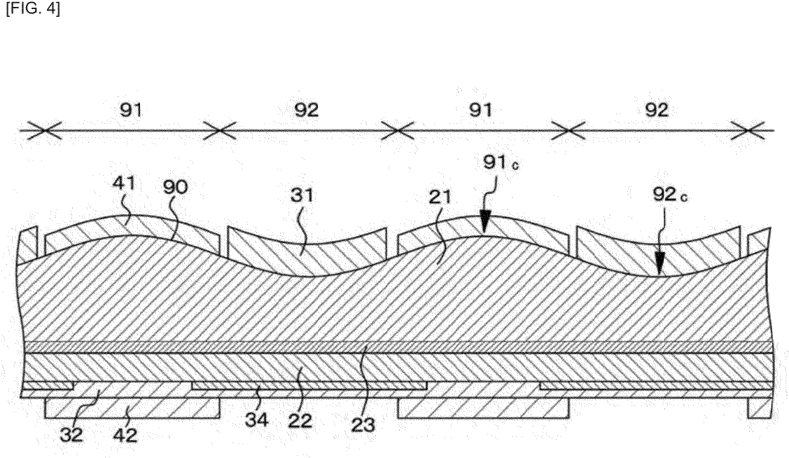

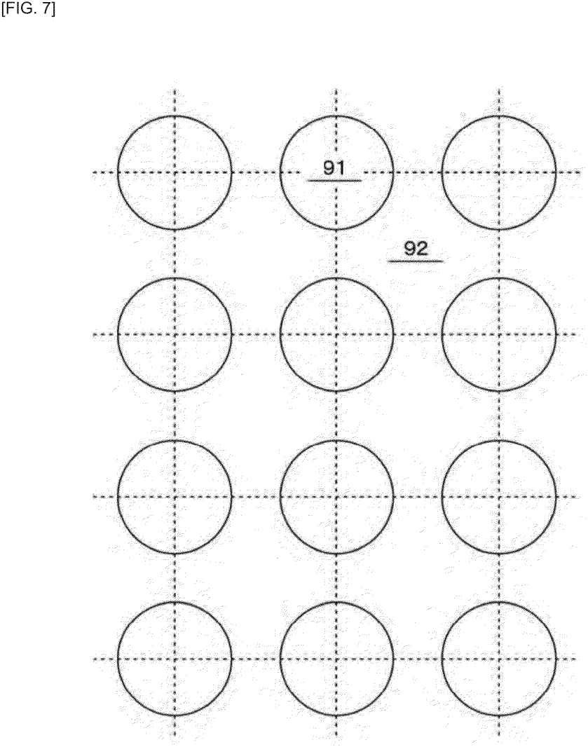

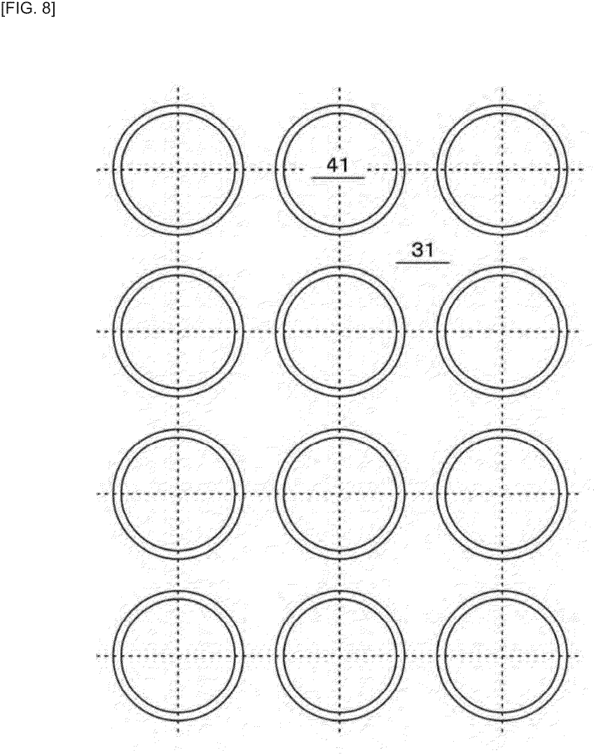

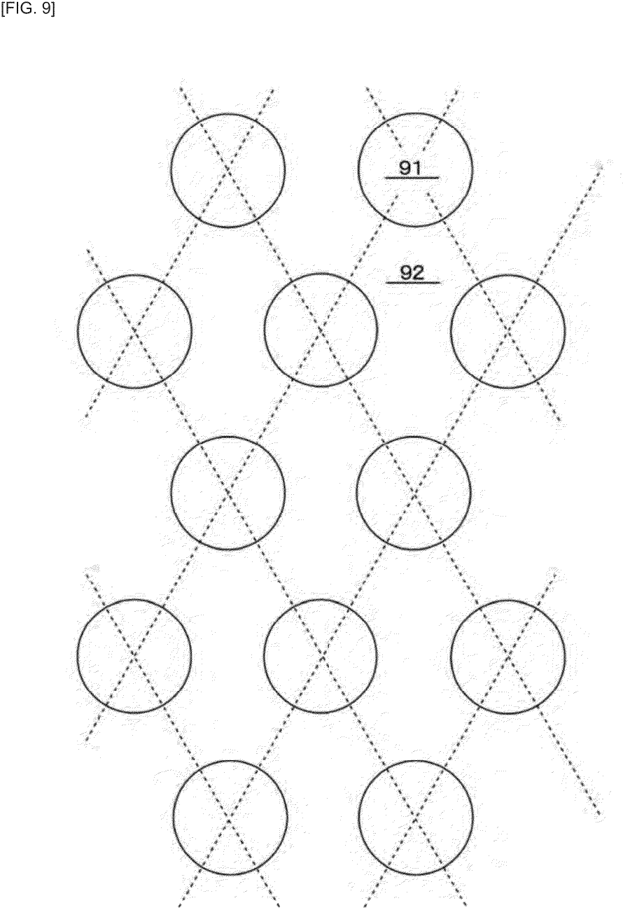

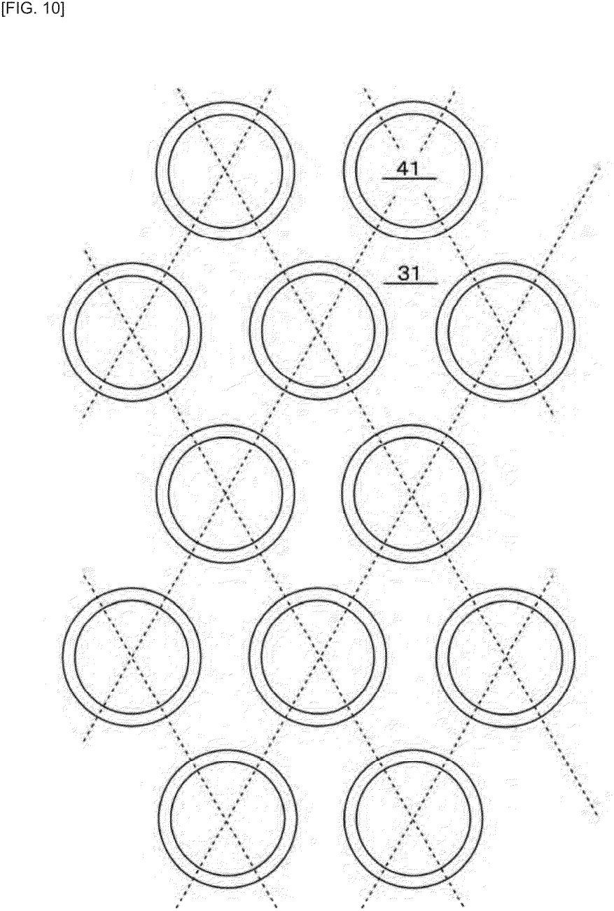

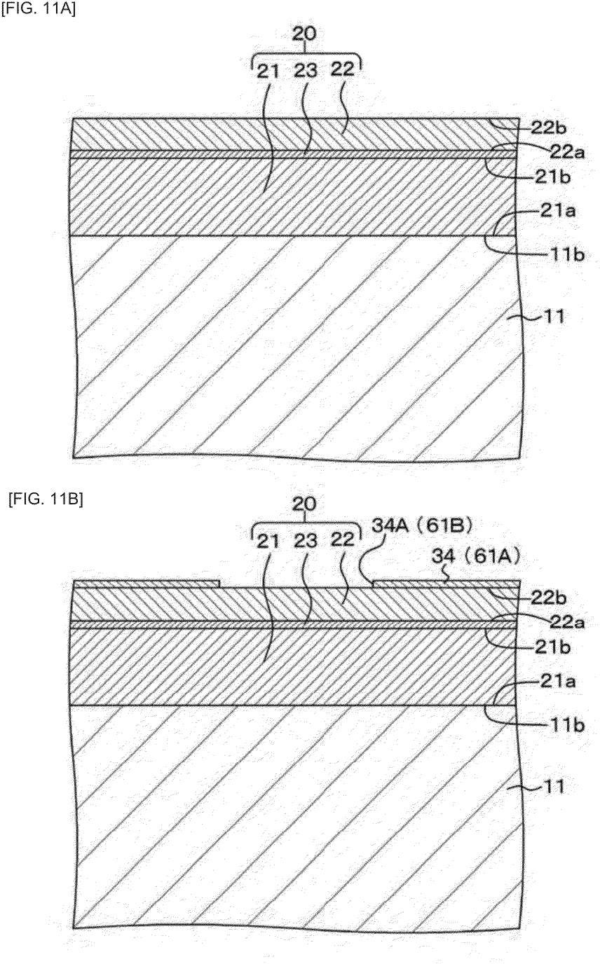

FIGS. 1 and 2 (Modification Example-1) and FIG. 3 (Modification Example-2) each illustrate a schematic partial end view of a light-emitting element 10A of Example 1. FIGS. 4, 5 and 6 each illustrate a schematic partial end view of a light-emitting element array in a case where the light-emitting element array includes a plurality of light-emitting elements of Example 1. FIGS. 7 and 9 each illustrate a schematic plan view of an arrangement of the first portion and the second portion of the base part surface in the light-emitting element array. FIGS. 8 and 10 each illustrate a schematic plan view of an arrangement of the first light reflective layer and the first electrode in the light-emitting element array. Furthermore, FIGS. 11A, 11B, 12, 13, 14A, 14B, 15A, 15B, 15C, 16A, and 16B each illustrate a schematic partial end view of the first compound semiconductor layer and the like for describing a method of manufacturing the light-emitting element of Example 1.

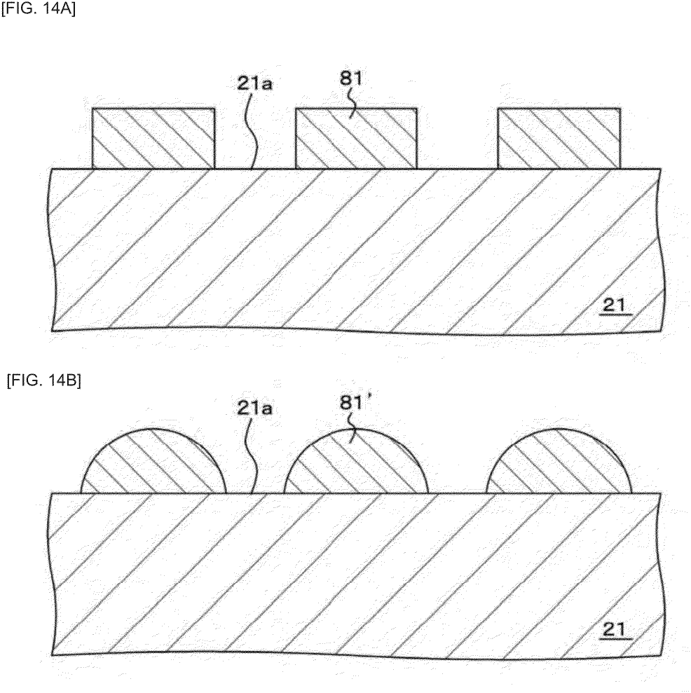

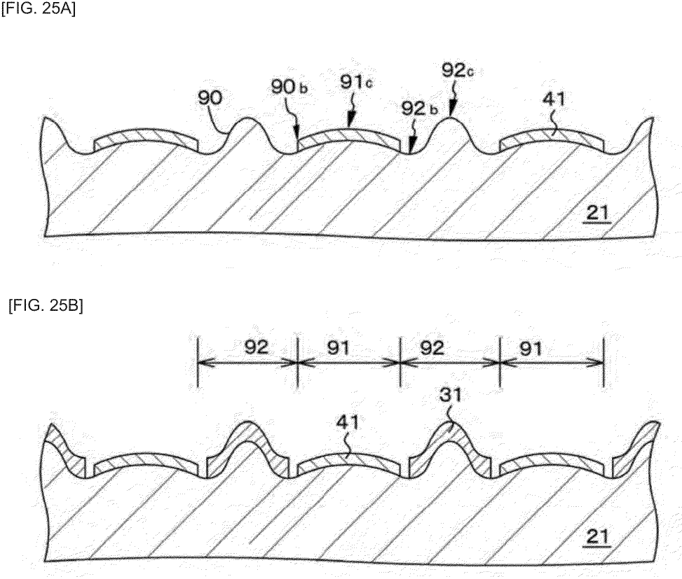

It is to be noted that FIGS. 14A, 14B, 15A, 15B, 15C, 16A, 16B, 23A, 23B, 24A, 24B, 25A, 25B, 31A, 31B, and 31C omit illustration of the active layer, the second compound semiconductor layer, the second light reflective layer, or the like. In addition, in FIGS. 7, 9, 19, and 21, the first portion of the base part surface is indicated by a solid circle for clarification, the center part of the second portion of the base part surface is indicated by a solid circle for clarification, and a portion of the apex part of the annular convex shape of the second portion of the base part surface is indicated by a solid ring for clarification.

The semiconductor laser element (surface-emitting laser element, light-emitting element 10A) of Example 1 includes:
the resonator structure including a stacked structure 20 in which a first compound semiconductor layer 21, an active layer 23, and a second compound semiconductor layer 22 are stacked; and
a first light reflective layer 41 and a second light reflective layer 42 provided at both ends along a resonance direction of the resonator structure. In addition, when the oscillation wavelength is set to λ0,
the first light reflective layer 41 includes a first refractive index periodic structure with a period having an optical film thickness of k10 (λ 0/2) [where 0.9 ≤ k10 ≤ 1.1] and in which at least a plurality of first thin films each having an optical film thickness of k11 (λ 0/4) [where 0.7 ≤ k11 ≤ 1.3] and a plurality of second thin films each having an optical film thickness of k12 (λ 0/4) [where 0.7 ≤ k12 ≤ 1.3] are stacked,
the second light reflective layer 42 includes a second refractive index periodic structure with a period having an optical film thickness of k20 (λ 0/2) [where 0.9 ≤ k20 ≤ 1.1] and in which at least a plurality of first thin films each having an optical film thickness of k21 (λ 0/4) [where 0.7 ≤ k21 ≤ 1.3] and a plurality of second thin films each having an optical film thickness of k22 (λ 0/4) [where 0.7 ≤ k22 ≤ 1.3] are stacked, and
the phase shift layer is provided inside at least one light reflective layer of the first light reflective layer 41 or the second light reflective layer 42.

Here, the resonator structure, the first light reflective layer 41, and the second light reflective layer 42 configure the resonator. In addition, the first light reflective layer 41 and the second light reflective layer 42 each have the distributed Bragg reflector structure.

Specifically, in Example 1, the phase shift layer is provided inside the second light reflective layer 42. The second light reflective layer 42 has the second refractive index periodic structure in which twelve layers of the light reflective stacked film are stacked. Here, when a first layer, a second layer, a third layer, ... of the light reflective stacked film are referred to from side of the stacked structure, the phase shift layer is provided between a sixth layer of the light reflective stacked film and a seventh layer of the light reflective stacked film. In this manner, the phase shift layer is not provided at an edge part of the second refractive index periodic structure.

In addition, the optical film thickness of the phase shift layer is 0.1 times or more and 50 times or less of λ0. It is to be noted that, in Example 1 or in Examples 2 to 9 to be described later, k10 = k11 = k12 = k20 = k21 = k22 = 1.0 and k3 = k3′ = 1.0 were set as design values.

In the second light reflective layer 42, the first thin film was configured by SiO₂, and the second thin film was configured by Ta₂O₅. Furthermore, SiO₂, which is the same material as that configuring the first thin film, was adopted as the material configuring the phase shift layer. In addition, the optical film thickness of the phase shift layer was set at 2.25 λ0. In the light reflective stacked film configuring the first light reflective layer 41, the first thin film was configured by SiO₂, and the second thin film was configured by Ta₂O₅, similarly to the second light reflective layer 42. In addition, the first light reflective layer 41 has the first refractive index periodic structure in which fourteen layers of the light reflective stacked film are stacked.

The stacked structure 20 configuring the surface-emitting laser element includes, in a stacked manner,
the first compound semiconductor layer 21 having a first surface 21a and a second surface 21b opposed to the first surface 21a,
the active layer (light-emitting layer) 23 facing the second surface 21b of the first compound semiconductor layer 21, and
the second compound semiconductor layer 22 having a first surface 22a facing the active layer 23 and a second surface 22b opposed to the first surface 22a,
the first light reflective layer 41 is formed on a base part surface 90 located on side of the first surface of the first compound semiconductor layer 21, and
the second light reflective layer 42 is formed on side of the second surface of the second compound semiconductor layer 22. Here, the first light reflective layer 41 functions as a concave mirror, and the second light reflective layer 42 has a flat shape. In addition, the resonator length LOR is 1 × 10⁻⁵ m or more.

In the light-emitting element of Example 1, a convex part is formed, with respect to the second surface 21b of the first compound semiconductor layer 21, in a first portion 91 which is a portion of the base part surface 90 where the first light reflective layer 41 is formed. In addition, a concave part is formed, with respect to the second surface 21b of the first compound semiconductor layer 21, in a second portion 92 which is a portion of the base part surface 90 where the first light reflective layer 41 is not formed. That is, the second portion 92 has a downwardly convex shape with respect to the second surface 21b of the first compound semiconductor layer 21. In a case where the light-emitting element array includes the plurality of light-emitting elements of Example 1, a center part 91c of the first portion 91 of the base part surface 90 is located on a vertex of a square lattice (see FIG. 7) or located on a vertex of an equilateral triangular lattice (see FIG. 9).

In addition, the base part surface 90 has a concavo-convex shape, and is differentiable. That is, the base part surface 90 is analytically smooth. The second portion 92 extends from the first portion 91; an extension part of the first light reflective layer 41 may be formed in the second portion 92 in some cases, or the extension part of the first light reflective layer 41 may not be formed in the second portion 92 in some cases. In the illustrated example, however, the extension part of the first light reflective layer 41 is not formed in the second portion 92. The first portion 91, the second portion 92, and a boundary (linking portion) 90bd between the first portion and the second portion 92 are also differentiable.

In Examples 1 to 9, the first compound semiconductor layer 21 has a first electrically-conductive type (specifically, n-type), and the second compound semiconductor layer 22 has a second electrically-conductive type (specifically, p-type) different from the first electrically-conductive type.

In the light-emitting element 10A of Example 1, the boundary 90bd between the first portion 91 and the second portion 92 is definable as:
(1) in a case where the first light reflective layer 41 does not extend to the second portion 92, an outer peripheral part of the first light reflective layer; or
(2) in a case where the first light reflective layer 41 extends to the second portion 92, a portion in which an inflection point is present in the base part surface 90 that lies astride the first portion 91 and the second portion 92. Here, the light-emitting element 10A of Example 1 specifically corresponds to the case (1).

In addition, in the light-emitting element 10A of Example 1, examples of shapes of [the first portion 91/the second portion 92 in a range from a peripheral part to a center part] include the following cases:
(A) [an upwardly convex shape/a downwardly convex shape];
(B) [an upwardly convex shape/a downwardly convex shape continuing to a line segment];
(C) [an upwardly convex shape/an upwardly convex shape continuing to a downwardly convex shape];
(D) [an upwardly convex shape/an upwardly convex shape continuing to a downwardly convex shape and to a line segment];
(E) [an upwardly convex shape/a line segment continuing to a downwardly convex shape]; and
(F) [an upwardly convex shape/a line segment continuing to a downwardly convex shape and to a line segment], and the light-emitting element 10A of Example 1 specifically corresponds to the case (A).

In the light-emitting element 10A of Example 1, the first surface 21a of the first compound semiconductor layer 21 configures the base part surface 90. A figure drawn by the first portion 91 of the base part surface 90 when the base part surface 90 is cut along a virtual plane including a stacking direction of the stacked structure 20 is differentiable, and more specifically, may be a part of a circle, a part of a parabola, a sine curve, a part of an ellipse, a part of a catenary curve, or a combination of these curves. Portions of these curves may be replaced with a line segment. A figure drawn by the second portion 92 is also differentiable, and more specifically, may also be a part of a circle, a part of a parabola, a part of a sine curve, a part of an ellipse, a part of a catenary curve, or a combination of any of these curves. Portions of these curves may be replaced with a line segment. That is, a configuration may also be adopted in which a figure drawn by an apex part of the first portion 91 of the base part surface 90 is a part of a circle, a part of a parabola, a part of a sine curve, a part of an ellipse, or a part of a catenary curve, and a figure drawn by a bottom portion of the first portion 91 of the base part surface 90 is a line segment. In addition, a configuration may also be adopted in which a figure drawn by a bottommost part of the second portion 92 of the base part surface 90 is a part of a circle, a part of a parabola, a part of a sine curve, a part of an ellipse, or a part of a catenary curve, and a figure drawn by a part above the bottommost part of the second portion 92 of the base part surface 90 is a line segment. Furthermore, the boundary 90bd between the first portion 91 and the second portion 92 of the base part surface 90 is also differentiable.

In a case where the light-emitting element array is configured by the plurality of light-emitting elements of Example 1, it is desirable, in the light-emitting element array, that a formation pitch of the light-emitting elements be 3 µm or more and 50 µm or less, preferably 5 µm or more and 30 µm or less, and more preferably 8 µm or more and 25 µm or less. In addition, the curvature radius R1 of the center part 91c of the first portion 91 of the base part surface 90 is desirably 1 × 10⁻⁵ m or more. The resonator length LOR preferably satisfies 1 × 10⁻⁵ m ≤ LOR. Parameters of the light-emitting element 10A are as exhibited in Table 1 below. It is to be noted that the diameter of the first light reflective layer 41 is denoted by D1, the height of the first portion 91 of the base part surface 90 is denoted by H1, and the curvature radius of a center part 92c of the second portion 92 of the base part surface 90 is denoted by R2. Here, the height H1 of the first portion 91 is expressed by:

$$\text{H1} = \text{L1} - \text{L2}$$

where L1 is a distance from the second surface 21b of the first compound semiconductor layer 21 to the center part 91c of the first portion 91 of the base part surface 90, and L2 is a distance from the second surface 21b of the first compound semiconductor layer 21 to the center part 92c of the second portion 92 of the base part surface 90.

A configuration may be adopted in which the stacked structure 20 includes at least one kind of material selected from the group consisting of a GaN-based compound semiconductor, an InP-based compound semiconductor, and a GaAs-based compound semiconductor. In Example 1, specifically, the stacked structure 20 includes a GaN-based compound semiconductor.

The first compound semiconductor layer 21 includes an n-GaN layer, the active layer 23 includes a three-tiered quantum well structure in which In_{0.04}Ga_{0.96}N layers (barrier layers) and In_{0.16}Ga_{0.84}N layers (well layers) are stacked, and the second compound semiconductor layer 22 includes a p-GaN layer. A first electrode 31 including Ti/Pt/Au is electrically coupled to an external circuit or the like through a first pad electrode (not illustrated) including, for example, Ti/Pt/Au or V/Pt/Au. Meanwhile, a second electrode 32 is formed on the second compound semiconductor layer 22, and the second light reflective layer 42 is formed on the second electrode 32. The second light reflective layer 42 on the second electrode 32 has a flat shape. The second electrode 32 includes a transparent electrically-conductive material, specifically, ITO. On an edge part of the second electrode 32, a second pad electrode 33 including, for example, Pd/Ti/Pt/Au, Ti/Pd/Au, or Ti/Ni/Au for establishing electrical coupling to the external circuit or the like may be formed or coupled (see FIGS. 2 and 3). The first light reflective layer 41 and the second light reflective layer 42 include, for example, a stacked structure of a Ta₂O₅ layer and a SiO₂ layer, or a stacked structure of a SiN layer and a SiO₂ layer. Although the first light reflective layer 41 and the second light reflective layer 42 have such a multilayer structure, they are illustrated as a single layer for simplification of the drawings. Respective planar shapes of the first electrode 31, the first light reflective layer 41, the second light reflective layer 42, and an opening 34A provided in an insulating layer (current confinement layer) 34 are circular.

As illustrated in FIG. 4, in a case where the light-emitting element array is configured by the plurality of light-emitting elements of Example 1, the second electrode 32 is common among the light-emitting elements 10A configuring the light-emitting element array. The second electrode is coupled to an external circuit or the like through the first pad electrode (not illustrated). The first electrode 31 is also common among the light-emitting elements 10A configuring the light-emitting element array, and is coupled to an external circuit or the like through the first pad electrode (not illustrated). In the light-emitting element 10A illustrated in FIGS. 1 and 4, light may be emitted to the outside through the first light reflective layer 41, or light may be emitted to the outside through the second light reflective layer 42. It is to be noted that, in a case where the light-emitting element array is not configured by the light-emitting elements 10A, it is sufficient if the first electrode 31 and the second electrode 32 are provided in the light-emitting element 10A. This also applies similarly to the following description.

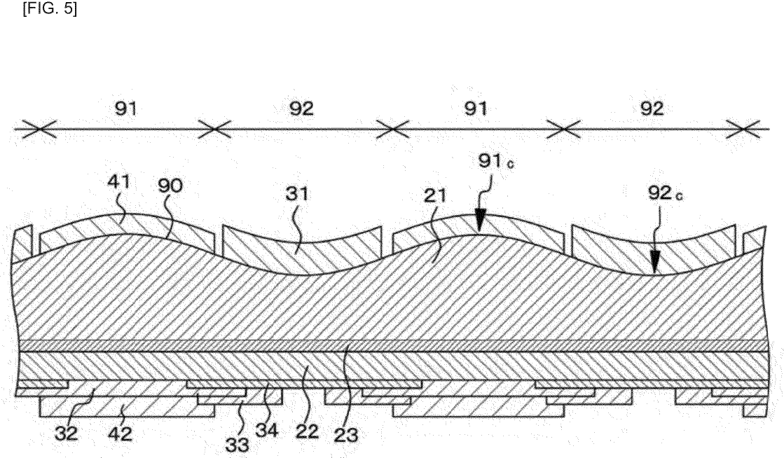

Alternatively, as illustrated in FIG. 5, in Modification Example-1 of Example 1, the second electrode 32 is individually formed in the light-emitting elements 10A configuring the light-emitting element array, and is coupled to an external circuit or the like through the second pad electrode 33. The first electrode 31 is common among the light-emitting elements 10A configuring the light-emitting element array, and is coupled to an external circuit or the like through the first pad electrode (not illustrated). In the light-emitting element 10A illustrated in FIGS. 2 and 5, light may be emitted to the outside through the first light reflective layer 41, or light may be emitted to the outside through the second light reflective layer 42.

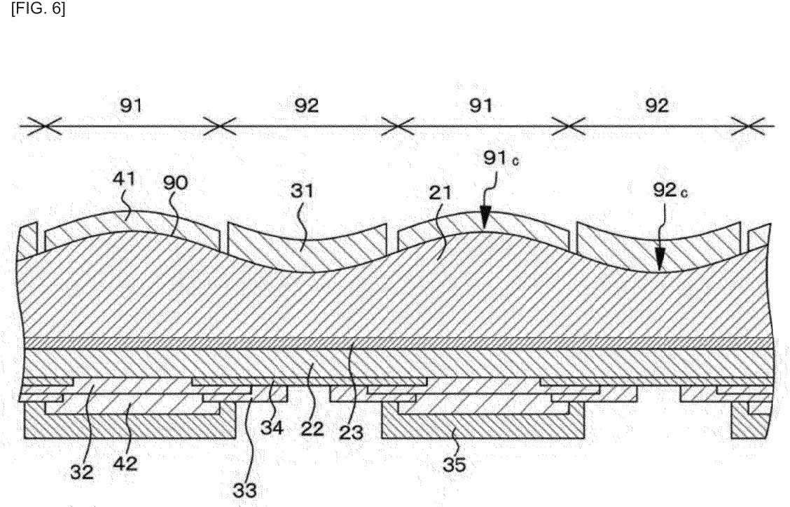

Alternatively, as illustrated in FIG. 6, in Modification Example-2 of Example 1, in the case of the light-emitting element array, the second electrode 32 is individually formed in the light-emitting elements 10A configuring the light-emitting element array. On the second pad electrode 33 formed on the second electrode 32, a bump 35 is formed and coupling to an external circuit or the like is established through the bump 35. The first electrode 31 is common among the light-emitting elements 10A configuring the light-emitting element array, and is coupled to an external circuit or the like through the first pad electrode (not illustrated). The bump 35 is provided in a portion on the side of the second surface of the second compound semiconductor layer 22 opposed to the center part 91c of the first portion 91 of the base part surface 90, and covers the second light reflective layer 42. Examples of the bump 35 may include a gold (Au) bump, a solder bump, and an indium (In) bump. A method of providing the bump 35 may be a known method. In the light-emitting element 10A illustrated in FIGS. 3 and 6, light is emitted to the outside through the first light reflective layer 41. It is to be noted that the bump 35 may be provided in the light-emitting element 10A illustrated in FIG. 1. Examples of the shape of the bump 35 may include a cylindrical shape, an annular shape, and a hemispherical shape.

A value of a thermal conductivity of the stacked structure 20 is higher than a value of a thermal conductivity of the first light reflective layer 41. The thermal conductivity of the dielectric material configuring the first light reflective layer 41 has a value of about 10 watts/(m·K) or less. Meanwhile, the thermal conductivity of the GaN-based compound semiconductor configuring the stacked structure 20 has a value of about 50 watts/(m·K) to about 100 watts/(m·K).

TABLE 1

| | |
|---|---|
| Curvature radius R1 | 100 µm |
| Diameter D1 | 20 µm |
| Height H1 | 2 µm |
| Curvature radius R2 | 2 µm |
| Second light reflective layer 42 | SiO₂/Ta₂O₅ (12 pairs) |
| Phase shift layer | SiO₂ (optical film thickness 2.25 λ0) |
| Second electrode 32 | ITO (thickness: 22 nm) |
| Second compound semiconductor layer 22 | p-GaN |
| Active layer 23 | InGaN (multiquantum well structure) |
| First compound semiconductor layer 21 | n-GaN |
| First light reflective layer 41 | SiO₂/Ta₂O₅ (14 pairs) |
| Resonator length LOR | 25 µm |
| Oscillation wavelength (emission wavelength) λ0 | 440.2 nm |
| Wavelength λ′ | 446.5 nm |

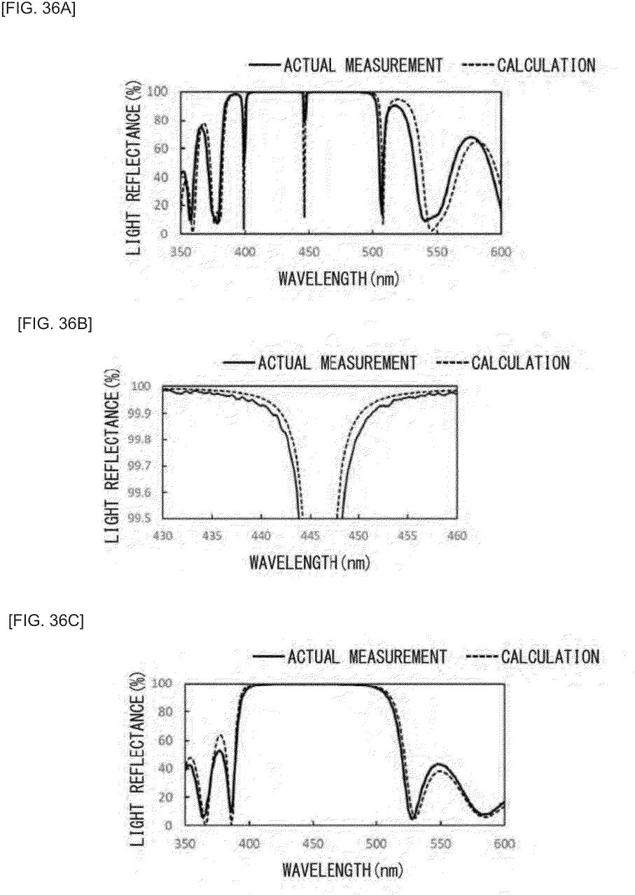

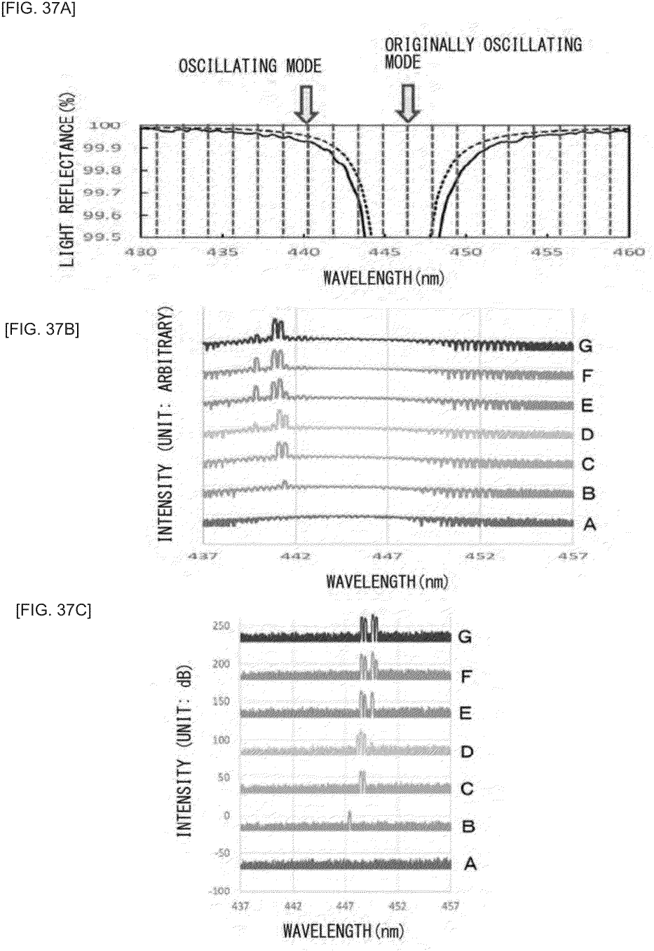

FIG. 36A illustrates an actually measured value (indicated by a solid line) and a calculated value (indicated by a dotted line) of a light reflectance of the second light reflective layer (the second light reflective layer of Example 1) including the phase shift layer. FIGS. 36B and 37A each illustrate an enlarged view thereof at around a wavelength of 445 nm. FIG. 36C illustrates, as Comparative Example 1, an actually measured value (indicated by a solid line) and a calculated value (indicated by a dotted line) of a light reflectance of a second light reflective layer not provided with the phase shift layer. As illustrated in FIGS. 36A and 36B, the second light reflective layer including the phase shift layer in the light-emitting element of Example 1 has the lowest light reflectance at the wavelength λ′ in the above Table 1. That is, the second light reflective layer 42 provided with the phase shift layer has an etalon structure. In addition, the value of Δλ, in the examples of FIGS. 36B and 37A is 1.6 nm.

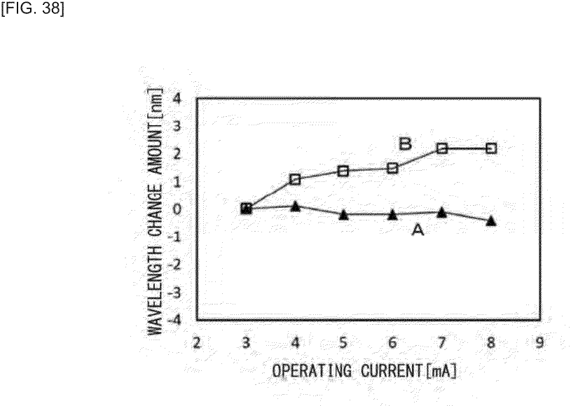

In addition, FIGS. 37B and 37C illustrate changes in the oscillation wavelengths when a current is flowed between the first electrode 31 and the second electrode 32 in Example 1 and Comparative Example 1, respectively. It is to be noted that the change in the oscillation wavelength when flowing a current of 2 milliamperes is indicated by “A” in FIGS. 37B and 37C. In addition, the change in the oscillation wavelength when flowing a current of 3 milliamperes is indicated by “B” in FIGS. 37B and 37C. Furthermore, the change in the oscillation wavelength when flowing a current of 4 milliamperes is illustrated by “C” in FIGS. 37B and 37C. In addition, the change in the oscillation wavelength when flowing a current of 5 milliamperes is indicated by “D” in FIGS. 37B and 37C. Furthermore, the change in the oscillation wavelength when flowing a current of 6 milliamperes is indicated by “E” in FIGS. 37B and 37C. In addition, the change in the oscillation wavelength when flowing a current of 7 milliamperes is indicated by “F” in FIGS. 37B and 37C. Furthermore, the change in the oscillation wavelength when flowing a current of 8 milliamperes is indicated by “G” in FIGS. 37B and 37C. In addition, FIG. 38 illustrates a current (an operating current, unit: milliampere) flowed between the first electrode 31 and the second electrode 32 as well as an amount of a change in the oscillation wavelength (unit: nm). It is to be noted that, in FIG. 38, “A” indicates data of Example 1, and “B” indicates data of Comparative Example 1.

In general, when a current is flowed to a light-emitting element, the light-emitting element generates heat, and a temperature of the active layer is raised; as a result, the emission wavelength is shifted toward side of longer wavelength. Such a phenomenon is remarkably observed in the light-emitting element of Comparative Example 1 illustrated in FIG. 37C because the phase shift layer is not provided. Meanwhile, as illustrated in FIG. 37B, such a phenomenon is not observed in Example 1 because the phase shift layer is provided. That is, in the light-emitting element of Example 1, as illustrated in FIG. 38, the oscillation wavelength is hardly changed by the operating temperature, and the oscillation wavelength is hardly changed by the operating current; the oscillation wavelength is kept constant even when the active layer gain fluctuates with respect to the wavelength. It is to be noted that the light-emitting element is temperature-controlled by a heat sink to allow an outer surface thereof to be kept at 50° C.

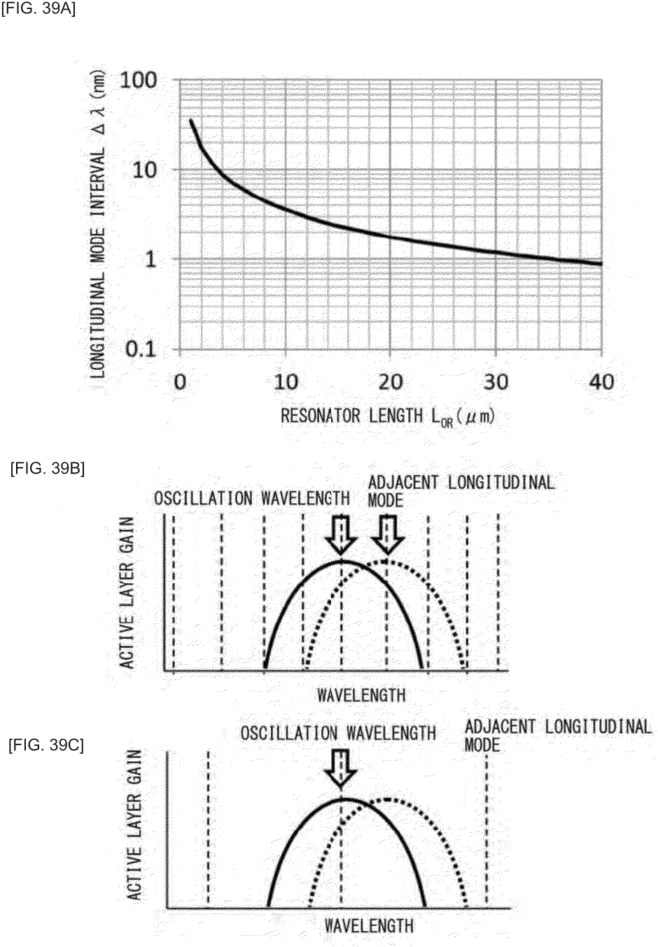

The longitudinal mode interval Δλ may satisfy:

$$\text{Δλ=} \left\{\text{λ} 02 / \left(2 \text{LOR} \times \text{nave}\right)\right\} \left[1 - \left(\text{λ} 0 / \text{nave}\right) \left(\text{dnave} / \text{d} \text{λ} \text{0}\right)\right] - 1$$

where nave is an average refractive index of a compound semiconductor layer configuring a resonator. FIG. 39A illustrates a relationship between the resonator length LOR (unit: µm) and the longitudinal mode interval (Δλ, unit: nm), when the GaN-based compound semiconductor (nave = 2.45) is used as a layer configuring the resonator and when (dnave/dλ0) = -0.01 and λ0 = 450 nm hold true. Under this condition,

$$\text{Δλ=} \text{41} \text{.1} / \text{LOR} \left(\text{nm}\right)$$

holds true. The value of Δλ in the examples of FIGS. 36B and 37A is 1.6 nm.

In addition, FIGS. 39B and 39C each illustrate a conceptual diagram of a change in the active layer gain when a current is flowed between the first electrode and the second electrode and the temperature of the active layer is raised. It is to be noted that FIG. 39B illustrates a case of LOR ≈ 30 µm, and FIG. 39C illustrates a case of LOR ≈ 2 µm. In the example illustrated in the FIG. 39B, Δλ ≈ 1 nm holds true, whereas, in the example illustrated in FIG. 39C, Δλ ≈ 20 nm holds true. That is, as the resonator length LOR becomes longer, the longitudinal mode interval Δλ becomes wider. In this manner, in a case where the resonator length LOR is short, the value of the longitudinal mode interval Δλ is large. Accordingly, the oscillation wavelength of the surface-emitting laser element is stable with respect to the operating temperature and the operating current, and is also in a single longitudinal mode. Meanwhile, as the resonator length LOR becomes longer, the longitudinal mode interval Δλ becomes narrower. In this manner, in a case where the resonator length LOR is long, the value of the longitudinal mode interval Δλ is small. Accordingly, the oscillation wavelength of the surface-emitting laser element becomes unstable with respect to the operating temperature and the operating current, and the longitudinal mode also tends to be a multimode.

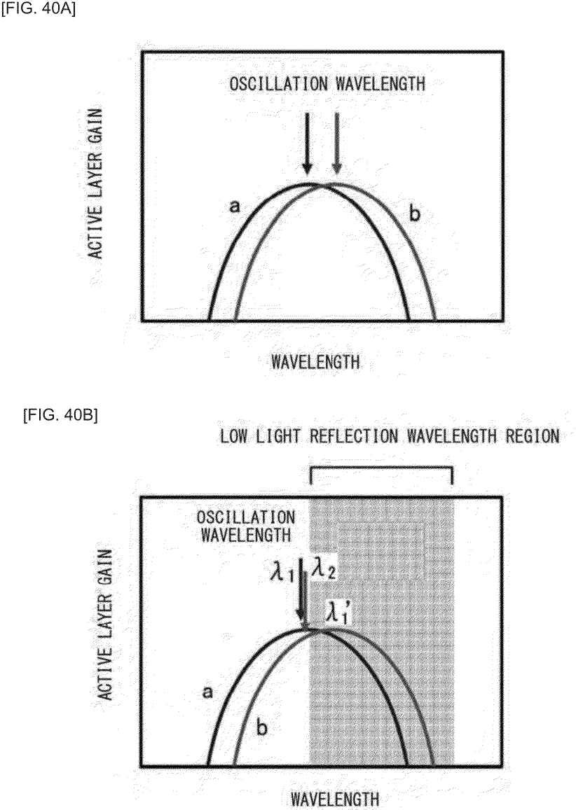

As illustrated in the conceptual diagram of FIG. 40A, the light-emitting element generally undergoes a change occurring in the active layer gain with respect to the wavelength by a change in the temperature of the active layer. Here, a wavelength at which the active layer gain is maximized is the oscillation wavelength of the light-emitting element. Accordingly, when the temperature of the active layer is raised, an active layer gain indicated by “a” is changed to an active layer gain indicated by “b”; as a result, a change also occurs in the oscillation wavelength.

Meanwhile, as illustrated in the conceptual diagram of FIG. 40B, in the light-emitting element of Example 1, when the temperature of the active layer is raised, the active layer gain indicated by “a” is changed to the active layer gain indicated by “b”. However, in the active layer gain in which the active layer gain is indicated by “b”, the phase shift layer is present, and a wavelength λ1′ shifted from the oscillation wavelength λ1 toward the side of the longer wavelength results in entering a low light reflection wavelength region in the second light reflective layer including the phase shift layer, thus causing the light-emitting element not to oscillate at the wavelength λ1′. Instead, the light-emitting element oscillates at an oscillation wavelength λ2, which is adjacent to the wavelength λ1′ and is located at side of a shorter wavelength than the wavelength λ1′. The value of the oscillation wavelength λ2 is a value close to or substantially equal to the value of the oscillation wavelength λ1.

As described above, in the light-emitting element (semiconductor laser element) of Example 1, the phase shift layer is provided inside the light reflective layer. Thus, the oscillation wavelength is stable with respect to the operating temperature and the operating current, and it is possible to obtain a single longitudinal mode. In addition, even when there is dispersion in a crystalline property of the compound semiconductor materials configuring the stacked structure in a virtual plane orthogonal to a thickness direction of the stacked structure, it is possible to obtain a uniform oscillation wavelength.

Hereinafter, description is given of various modification examples of Example 1.

Also in Modification Example-3 of Example 1, the phase shift layer is provided inside the second light reflective layer 42. The second light reflective layer 42 has the second refractive index periodic structure in which eight layers of the light reflective stacked film are stacked. In addition, the phase shift layer is provided between a second layer of the light reflective stacked film and a third layer of the light reflective stacked film. The phase shift layer is not provided at the edge part of the second refractive index periodic structure. Similarly to the light reflective stacked film of Example 1, the first thin film was configured by SiO₂, and the second thin film was configured by Ta₂O₅. Furthermore, SiO₂, which is the same material as that configuring the first thin film, was adopted as the material configuring the phase shift layer. In addition, the optical film thickness of the phase shift layer is 10 λ0. A configuration or structure of the first light reflective layer 41 was similar to the configuration or structure of the first light reflective layer 41 in Example 1.

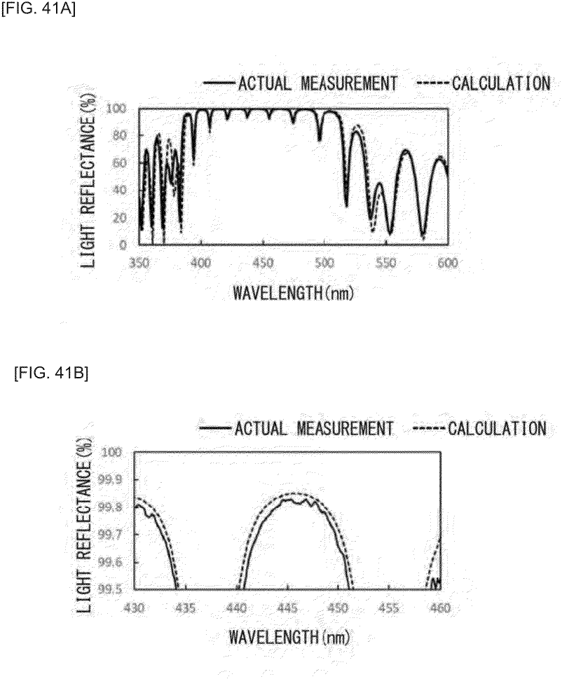

FIG. 41A illustrates a graph illustrating an actually measured value (indicated by a solid line) and a calculated value (indicated by a dotted line) of a light reflectance of the second light reflective layer including the phase shift layer in a semiconductor laser element of Modification Example-3 of Example 1. FIG. 41B illustrates an enlarged view of the actually measured value and the calculated value, at around a wavelength of 430 nm to 460 nm, of the light reflectance of the second light reflective layer including the phase shift layer illustrated in FIG. 41A. As illustrated in FIGS. 41A and 41B, the second light reflective layer including the phase shift layer in Modification Example-3 of the light-emitting element of Example 1 has a lower light reflectance in six wavelength regions.

In Modification Example-4 of Example 1, the phase shift layer is provided at two locations inside the second light reflective layer 42. The second light reflective layer 42 has the second refractive index periodic structure in which eighteen layers of the light reflective stacked film are stacked. In addition, a first phase shift layer is provided between a fourth layer of the light reflective stacked film and a fifth layer of the light reflective stacked film, and a second phase shift layer is provided between an eighth layer of the light reflective stacked film and a ninth layer of the light reflective stacked film. The first phase shift layer and the second phase shift layer are not provided at the edge part of the second refractive index periodic structure. Four layers of the light reflective stacked film are disposed between the phase shift layer and the phase shift layer. Similarly to the light reflective stacked film of Example 1, the first thin film was configured by SiO₂, and the second thin film was configured by Ta₂O₅. Furthermore, SiO₂, which is the same material as that configuring the first thin film, was adopted as the material configuring the phase shift layer. In addition, the optical film thickness of each of the first phase shift layer and the second phase shift layer is 2.25 λ0. A configuration or structure of the first light reflective layer 41 was similar to the configuration or structure of the first light reflective layer 41 in Example 1.

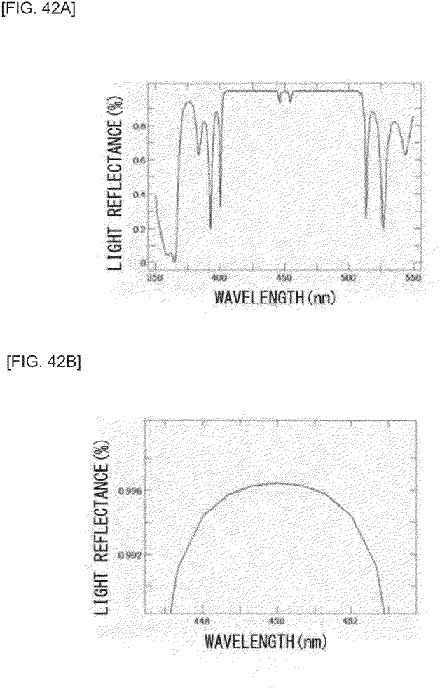

FIG. 42A illustrates a graph illustrating an actually measured value (indicated by a solid line) and a calculated value (indicated by a dotted line) of a light reflectance of the second light reflective layer including the phase shift layer in a semiconductor laser element of Modification Example-4 of Example 1. FIG. 42B illustrates an enlarged view of the actually measured value and the calculated value, at around a wavelength of 450 nm, of the light reflectance of the second light reflective layer including the phase shift layer illustrated in FIG. 42A. As illustrated in FIGS. 42A and 42B, the second light reflective layer including the phase shift layer in Modification Example-4 of the light-emitting element of Example 1 has a lower light reflectance in two wavelength regions.

In Modification Example-5 of Example 1, the phase shift layer is provided inside the first light reflective layer 41. The first light reflective layer 41 has the first refractive index periodic structure in which fourteen layers of the light reflective stacked film are stacked. In addition, a first phase shift layer is provided between a seventh layer of the light reflective stacked film and an eighth layer of the light reflective stacked film. The phase shift layer is not provided at the edge part of the first refractive index periodic structure. Similarly to the light reflective stacked film of Example 1, the first thin film was configured by SiO₂, and the first thin film was configured by Ta₂O₅. Furthermore, SiO₂, which is the same material as that configuring the first thin film, was adopted as the material configuring the phase shift layer. In addition, the optical film thickness of the phase shift layer is 2.25 λ0. The light reflective stacked film configuring the second light reflective layer 42 having a flat shape has a structure in which the first thin film (including SiO₂) and the second thin film (Ta₂O₅ similar to those of the first light reflective layer 41 are stacked. In addition, the second light reflective layer 42 has the second refractive index periodic structure in which nine layers of the light reflective stacked film are stacked.

In a semiconductor laser element of Modification Example-5 of Example 1, an actually measured value and a calculated value of the light reflectance of the first light reflective layer including the phase shift layer were similar to those in FIG. 36A.

In Modification Example-6 of Example 1, the first light reflective layer 41 has a configuration or structure similar to that of the first light reflective layer 41 of Modification Example-5 of Example 1. In addition, the second light reflective layer 42 has a configuration or structure similar to that of the second light reflective layer 42 of Example 1.

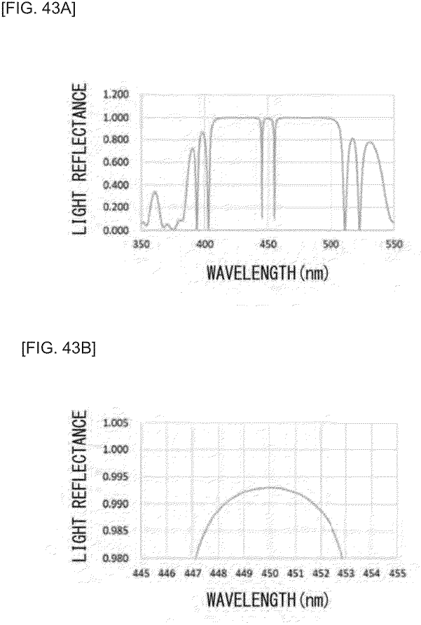

FIG. 43A illustrates a graph illustrating an actually measured value (indicated by a solid line) and a calculated value (indicated by a dotted line) of a light reflectance of the second light reflective layer including the phase shift layer in a semiconductor laser element of Modification Example-6 of Example 1. FIG. 43B illustrates an enlarged view of the actually measured value and the calculated value, at around a wavelength of 450 nm, of the light reflectance of the second light reflective layer including the phase shift layer illustrated in FIG. 43A. As illustrated in FIGS. 43A and 43B, the first light reflective layer and the second light reflective layer including the phase shift layer in Modification Example-6 of the light-emitting element of Example 1 have a lower light reflectance as a whole in two wavelength regions.

Incidentally, in Example 1, Modification Example-3 of Example 1, Modification Example-4 of Example 1, Modification Example-5 of Example 1, and Example 9 to be described later, the optical film thickness of the phase shift layer is 0.1 times or more and 50 times or less of λ0. In addition, in Example 1, Modification Example-4 of Example 1, Modification Example-5 of Example 1, and Example 9 to be described later, the optical film thickness of the phase shift layer satisfies k3(λ0/4) (2r + 1) [where r is an integer of 100 or less, and 0.9 ≤ k3 ≤ 1.1]. However, this is not limitative, and a mode may also be broadly adopted in which the optical film thickness of the phase shift layer is an optical film thickness other than k3′(λ,0/4) (2r′) [where r′ is an integer of 100 or less, and 0.9 ≤ k3′ ≤ 1.1].

Hereinafter, simulations were performed in which the arrangement order of the first thin film and the second thin film as well as the phase shift layer in the light reflective layer and materials configuring the first thin film, the second thin film, and the phase shift layer were changed in various manners, to study effects of the phase shift layer. It is assumed that that n1 is a refractive index of a material configuring the first thin film, n2 is a refractive index of a material configuring the second thin film, and n3 is a refractive index of a material configuring the phase shift layer.

In a structure such as film A, film B, film A, film B, film C, film A, film B, ..., film A, film B, film A, and film B (hereafter, referred to as a “first structure” for the sake of convenience), it is assumed that
Film A: a first thin film including a first material having a refractive index of n1
Film B: a second thin film including a second material having a refractive index of n2 (< n1).

In addition, in any case of the following cases:
Film C: a phase shift layer including the first material having a refractive index of n1
Film C: a phase shift layer including the second material having a refractive index of n2
Film C: a phase shift layer including a third material having a refractive index of n3 (where n3 < n2)
Film C: a phase shift layer including the third material having a refractive index of n3 (where n2 < n3 < n1)
Film C: a phase shift layer including the third material having a refractive index of n3 (where n1 < n3),
when the optical film thickness of the film C was set to (λ0/4), a simulation result was obtained which recognized the presence of a wavelength at which the light reflectance of the light reflective layer is lowered. Meanwhile, when the optical film thickness of the film C was set to (λ0/2), a simulation result was obtained which recognized no presence of a wavelength at which the light reflectance of the light reflective layer is lowered.

In addition, in a structure such as film A, film B, film A, film B, film A, film C, film B, ..., film A, film B, film A, and film B (hereafter, referred to as a “second structure” for the sake of convenience), it is assumed that
Film A: a first thin film including the first material having a refractive index of n1
Film B: a second thin film including the second material having a refractive index of n2 (< n1).

In addition, in any case of the following cases:
Film C: a phase shift layer including the first material having a refractive index of n1
Film C: a phase shift layer including the second material having a refractive index of n2
Film C: a phase shift layer including the third material having a refractive index of n3 (where n3 < n2)
Film C: a phase shift layer including the third material having a refractive index of n3 (where n2 < n3 < n1)
Film C: a phase shift layer including the third material having a refractive index of n3 (where n1 < n3),
when the optical film thickness of the film C was set to (λ0/4), a simulation result was obtained which recognized the presence of a wavelength at which the light reflectance of the light reflective layer is lowered. Meanwhile, when the optical film thickness of the film C was set to (λ0/2), a simulation result was obtained which recognized no presence of a wavelength at which the light reflectance of the light reflective layer is lowered.

Hereinafter, description is given of a method of manufacturing the light-emitting element of Example 1, with reference to FIGS. 11A, 11B, 12, 13, 14A, 14B, 15A, 15B, 15C, 16A, and 16B, which are each a schematic partial end view of the first compound semiconductor layer, and the like.

Here, a method of manufacturing the light-emitting element of Example 1 includes:
forming the stacked structure, and thereafter forming the second light reflective layer on the side of the second surface of the second compound semiconductor layer,
forming a first sacrificial layer on the first portion of the base part surface on which the first light reflective layer is to be formed, and thereafter making a surface of the first sacrificial layer into a convex shape,
forming a second sacrificial layer on the second portion of the base part surface exposed between the first sacrificial layers and on the first sacrificial layer to make a surface of the second sacrificial layer into a concavo-convex shape,
etching back the second sacrificial layer and the first sacrificial layer, and further etching back inwardly from the base part surface to form a convex part in the first portion of the base part surface with respect to the second surface of the first compound semiconductor layer and to form at least a concave part in the second portion of the base part surface, and
forming the first light reflective layer on the first portion of the base part surface.

First, after the stacked structure 20 is formed, the second light reflective layer 42 is formed on the side of the second surface of the second compound semiconductor layer 22.

### Step-100

Specifically, on a second surface 11b of a compound semiconductor substrate 11 having a thickness of about 0.4 mm, formed is the stacked structure 20 including a GaN-based compound semiconductor and including a stack of
the first compound semiconductor layer 21 having the first surface 21a and the second surface 21b opposed to the first surface 21a,
the active layer (light-emitting layer) 23 facing the second surface 21b of the first compound semiconductor layer 21, and
the second compound semiconductor layer 22 having the first surface 22a facing the active layer 23 and the second surface 22b opposed to the first surface 22a. More specifically, it is possible to obtain the stacked structure 20 (see FIG. 11A) by forming the first compound semiconductor layer 21, the active layer 23, and the second compound semiconductor layer 22 sequentially on the second surface 11b of the compound semiconductor substrate 11 by an epitaxial growth method using a known MOCVD method. It is to be noted that reference numeral 11a denotes a first surface of the compound semiconductor substrate 11 opposed to the second surface 11b of the compound semiconductor substrate 11.

### Step-110

Subsequently, an insulating layer (current confinement layer) 34 having the opening 34A and including SiO₂ is formed on the second surface 22b of the second compound semiconductor layer 22 by a combination of a film formation method, such as a CVD method, a sputtering method, or a vacuum deposition method, and a wet etching method or a dry etching method (see FIG. 11B). A current confinement region (a current injection region 61A and a current non-injection region 61B) is defined by the insulating layer 34 having the opening 34A. That is, the current injection region 61A is defined by the opening 34A.

In order to obtain the current confinement region, an insulating layer (current confinement layer) including an insulating material (e.g., SiOx, SiNx, or AlOx) may be formed between the second electrode 32 and the second compound semiconductor layer 22, or the second compound semiconductor layer 22 may be etched by an RIE method or the like to form a mesa structure. Alternatively, the current confinement region may be formed by partially oxidizing some layers of stacked second compound semiconductor layers 22 from a lateral direction, or a region with a reduced electrical conductivity may be formed by injecting impurities into the second compound semiconductor layer 22 by ion injection. Alternatively, any of them may be combined as appropriate. It is to be noted that it is necessary for the second electrode 32 to be electrically coupled to a portion of the second compound semiconductor layer 22 through which a current flows due to current confinement.

### Step-120

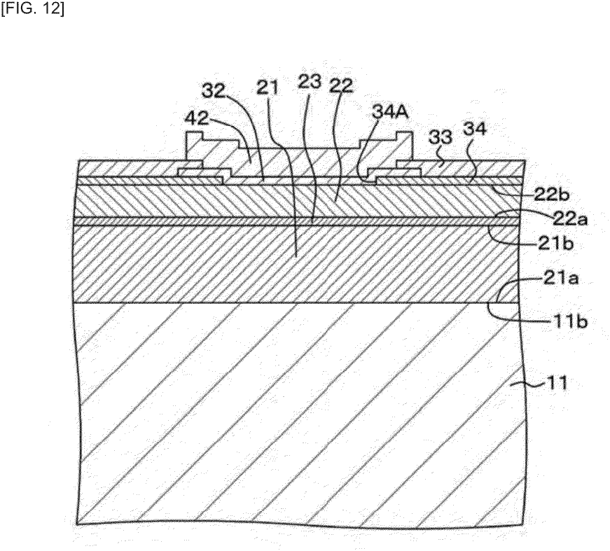

Thereafter, the second electrode 32 and the second light reflective layer 42 are formed on the second compound semiconductor layer 22. Specifically, the second electrode 32 is formed to extend from the second surface 22b of the second compound semiconductor layer 22 exposed at a bottom surface of the opening 34A (current injection region 61A) to a position on the insulating layer 34 by, for example, a lift-off method, and further, the second pad electrode 33 is formed by a combination of a film formation method such as a sputtering method or a vacuum deposition method and a patterning method such as a wet etching method or a dry etching method, as desired. Subsequently, the second light reflective layer 42 is formed to extend from a position on the second electrode 32 to a position on the second pad electrode 33 by a combination of a film formation method such as a sputtering method or a vacuum deposition method and a patterning method such as a wet etching method or a dry etching method. The second light reflective layer 42 on the second electrode 32 has a flat shape. In this manner, it is possible to obtain a structure illustrated in FIG. 12. Thereafter, as desired, the bump 35 may be provided in a portion on the side of the second surface of the second compound semiconductor layer 22 opposed to the center part 91c of the first portion 91 of the base part surface 90. Specifically, the bump 35 may be formed on the second pad electrode 33 (see FIGS. 2 and 3) formed on the second electrode 32 to cover the second light reflective layer 42. The second electrode 32 is coupled to an external circuit or the like through the bump 35.

### Step-130

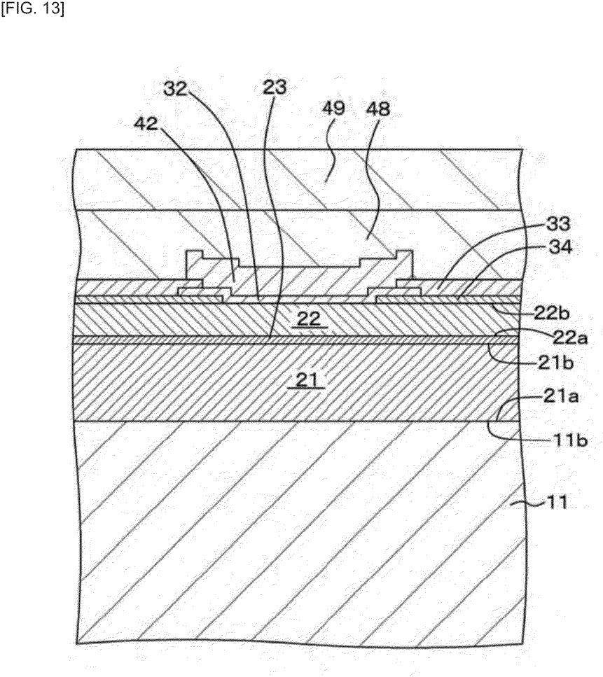

Subsequently, the second light reflective layer 42 is fixed to a support substrate 49 with a bonding layer 48 interposed therebetween (see FIG. 13). Specifically, the second light reflective layer 42 (or the bump 35) is fixed to the support substrate 49 including a sapphire substrate by using the bonding layer 48 including an adhesive.

### Step-140

Subsequently, the compound semiconductor substrate 11 is thinned by a mechanical polishing method or a CMP method, and further, etching is performed to remove the compound semiconductor substrate 11.

### Step-150

Thereafter, a first sacrificial layer 81 is formed on the first portion 91 of the base part surface 90 (specifically, the first surface 21a of the first compound semiconductor layer 21) on which the first light reflective layer 41 is to be formed, and thereafter, a surface of the first sacrificial layer is made into a convex shape. Specifically, the first sacrificial layer 81 illustrated in FIG. 14A is obtained by forming a first resist material layer on the first surface 21a of the first compound semiconductor layer 21 and patterning the first resist material layer to allow the first resist material layer to remain on the first portion 91, and thereafter, heat treatment is performed on the first sacrificial layer 81. It is thus possible to obtain a structure illustrated in FIG. 14B. Subsequently, a surface of a first sacrificial layer 81′ is subjected to an ashing processing (plasma irradiation processing) to modify the surface of the first sacrificial layer 81′. This prevents the first sacrificial layer 81′ from suffering damage, deformation, or the like when a second sacrificial layer 82 is formed in a next step.

### Step-160

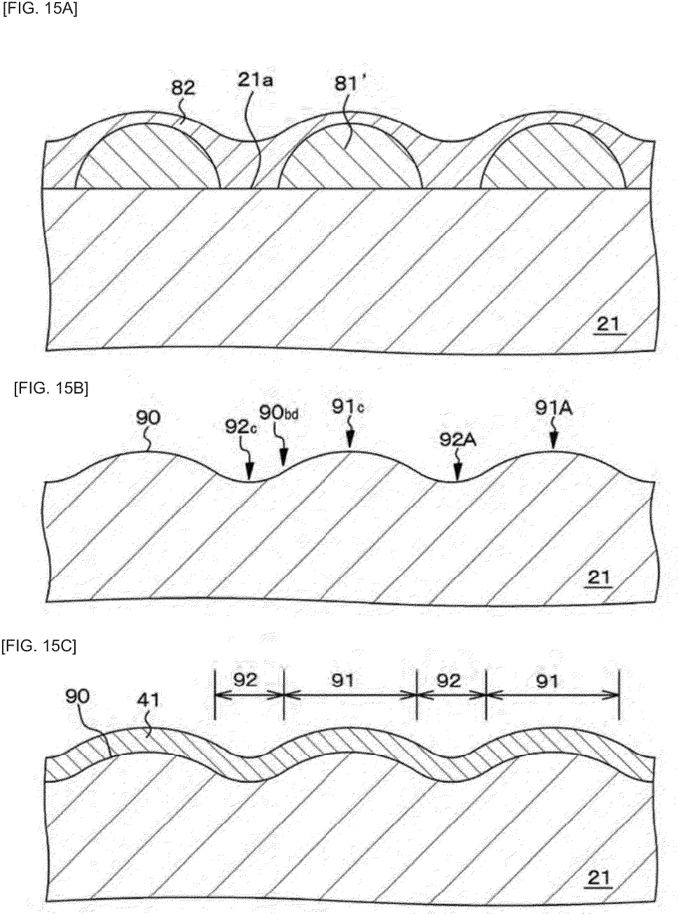

Subsequently, the second sacrificial layer 82 is formed on the second portion 92 of the base part surface 90 exposed between the first sacrificial layers 81′ and on the first sacrificial layers 81′ to make a surface of the second sacrificial layer 82 into a concavo-convex shape (see FIG. 15A). Specifically, the second sacrificial layer 82 including a second resist material layer having an appropriate thickness is formed across the entire surface. It is to be noted that in the example illustrated in FIG. 7, the second sacrificial layer 82 has an average film thickness of 2 µm, whereas in the example illustrated in FIG. 9, the second sacrificial layer 82 has an average film thickness of 5 µm.

In a case where it is necessary to further increase the curvature radius R1 of the first portion 91 of the base part surface 90, it is sufficient if [Step-150] and [Step-160] are repeated.

The materials configuring the first sacrificial layer 81 and the second sacrificial layer 82 are not limited to resist materials, and it is sufficient if a material appropriate in relation to the first compound semiconductor layer 21, such as an oxide material (e.g., SiO₂, SiN, TiO₂ or the like), a semiconductor material (e.g., Si, GaN, InP, GaAs, or the like), or a metal material (e.g., Ni, Au, Pt, Sn, Ga, In, Al, or the like) is selected. In addition, by using a resist material having an appropriate viscosity as the resist material configuring the first sacrificial layer 81 and the second sacrificial layer 82, and by appropriately setting and selecting the thickness of the first sacrificial layer 81, the thickness of the second sacrificial layer 82, the diameters of the first sacrificial layer 81′, etc., it is possible to set the value of the curvature radius of the base part surface 90 and the concavo-convex shape of the base part surface 90 (e.g., the diameter D1 and the height H1) to a desired value and a desired shape.

### Step-170

Thereafter, by etching back the second sacrificial layer 82 and the first sacrificial layer 81′ and further etching back inwardly from the base part surface 90 (i.e., from the first surface 21a of the first compound semiconductor layer 21 into the first compound semiconductor layer 21), a convex part 91A is formed in the first portion 91 of the base part surface 90, and at least a concave part (in Example 1, a concave part 92A) is formed in the second portion 92 of the base part surface 90, with respect to the second surface 21b of the first compound semiconductor layer 21. In this manner, it is possible to obtain a structure illustrated in FIG. 15B. The etching back may be performed by a dry etching method such as an RIE method, or by a wet etching method using hydrochloric acid, nitric acid, hydrofluoric acid, phosphoric acid, a mixture of any of these, or the like.

### Step-180

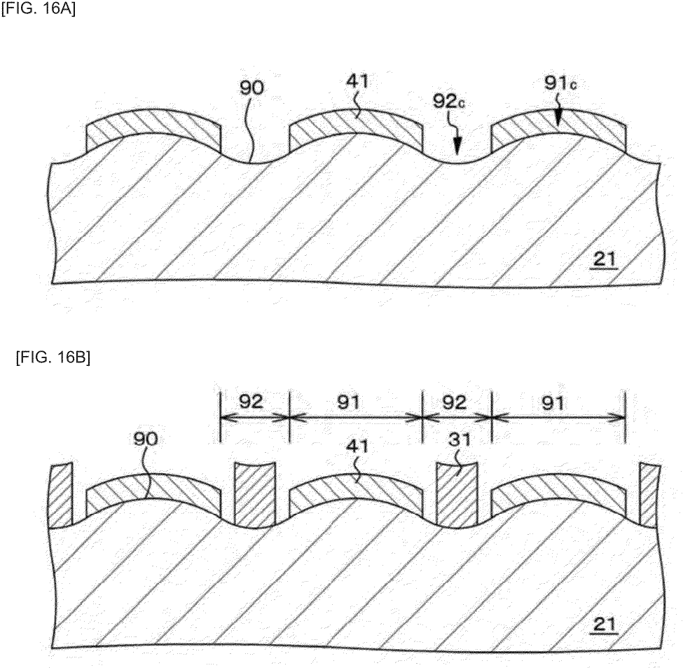

Next, the first light reflective layer 41 is formed on the first portion 91 of the base part surface 90. Specifically, the first light reflective layer 41 is formed across the entire surface of the base part surface 90 by a film formation method such as a sputtering method or a vacuum deposition method (see FIG. 15C), following which the first light reflective layer 41 is patterned. It is thus possible to obtain the first light reflective layer 41 on the first portion 91 of the base part surface 90 (see FIG. 16A). Thereafter, the first electrode 31 common among the light-emitting elements is formed on the second portion 92 of the base part surface 90 (see FIG. 16B). In the above-described manner, it is possible to obtain the light-emitting element 10A of Example 1. By making the first electrode 31 protrude relative to the first light reflective layer 41, it is possible to protect the first light reflective layer 41.

### Step-190

Thereafter, the support substrate 49 is removed, and the light-emitting elements are individually separated. Then, it is sufficient if electrical coupling to an external electrode or circuit (circuit for driving the light-emitting element) is established. Specifically, it is sufficient if the first compound semiconductor layer 21 is coupled to an external circuit or the like through the first electrode 31 and the unillustrated first pad electrode, and the second compound semiconductor layer 22 is coupled to an external circuit or the like through the second pad electrode 33 or the bump 35. Next, the semiconductor laser element (or light-emitting element array) of Example 1 is completed by performing packaging or sealing.

In addition, in the light-emitting element of Example 1, the base part surface has a concavo-convex shape, and is differentiable. Therefore, in a case where an external force is applied to the light-emitting element due to some cause, a possibility of stress concentrating on a rising portion of the convex part is avoidable with reliability, and thus there is no possible damage to the first compound semiconductor layer and the like. In particular, the light-emitting element is coupled or bonded to an external circuit or the like by using a bump; at the time of bonding, it is necessary to apply a high load (e.g., about 50 MPa) to the light-emitting element. With the light-emitting element of Example 1, there is no possible damage to the light-emitting element even when such a high load is applied. In addition, because the base part surface has a concavo-convex shape, generation of stray light is suppressed, and it is therefore possible to prevent the occurrence of light crosstalk between the light-emitting elements.

In a case of arranging light-emitting elements at narrow pitches in a light-emitting element array, it is not possible for the pitch to exceed the footprint diameter of the first sacrificial layer. Therefore, in order to reduce the pitch of the light-emitting element array, it is necessary to reduce the footprint diameter. Incidentally, the curvature radius R1 of the center part of the first portion of the base part surface has a positive correlation with the footprint diameter. That is, a decrease in footprint diameter with decreasing pitch results in a tendency of the curvature radius R1 to become smaller. For example, at a footprint diameter of 24 µm, a curvature radius R1 of about 30 µm has been reported. In addition, a radiation angle of light emitted from the light-emitting element has a negative correlation with the footprint diameter. That is, a decrease in footprint diameter with decreasing pitch results in a tendency of the curvature radius R1 to become smaller to enlarge a FFP (Far Field Pattern). A curvature radius R1 of less than 30 µm may result in a radiation angle of several degrees or more. Depending on the application field of the light-emitting element array, there may be cases where a narrow radiation angle of 2 to 3 degrees or less is demanded of light emitted from the light-emitting element.

According to Example 1, the first portion is formed in the base part surface with use of the first sacrificial layer and the second sacrificial layer. This makes it possible to obtain the first light reflective layer that is free from distortion and has a large curvature radius R1 even in a case where the light-emitting elements are arranged at narrow pitches. Accordingly, it is possible for light emitted from the light-emitting elements to be at a narrow radiation angle of 2 to 3 degrees or less, or a radiation angle as narrow as possible. This makes it possible to provide a light-emitting element with a narrow FFP, a light-emitting element with high orientability, and a light-emitting element with high beam quality. Furthermore, because a wide light emission region is obtainable, it is possible to achieve increased light output and improved light emission efficiency of the light-emitting element, and to achieve increased light output and improved efficiency of the light-emitting element.

Moreover, because it is possible to make the height (thickness) of the first portion lower (thinner), empty spaces (voids) are less likely to occur in the bump when the light-emitting element is coupled or bonded to an external circuit or the like by using the bump. This makes it possible to achieve improved thermal conductivity, and facilitates mounting.

Further, in the light-emitting element of Example 1, because the first light reflective layer serves also as a concave mirror, it is possible to cause light that spreads through diffraction with the active layer as a start point and enters the first light reflective layer to be reflected toward the active layer and condensed onto the active layer with reliability. It is thus possible to avoid an increase in diffraction loss and to perform laser oscillation with reliability. Owing to having a long resonator, it is also possible to avoid an issue of thermal saturation. Moreover, because it is possible to make the resonator length longer, allowance in the manufacturing process of the light-emitting element is enhanced, resulting in that improved yield is achievable. It is to be noted that “diffraction loss” refers to a phenomenon in which laser light reciprocating in a resonator is gradually dissipated to the outside of the resonator, because light generally tends to spread due to a diffraction effect. In addition, it is possible to suppress stray light, and to suppress light crosstalk between the light-emitting elements. Here, when light emitted from a certain light-emitting element comes into an adjacent light-emitting element and is absorbed by the active layer of the adjacent light-emitting element, or is coupled to a resonance mode, the light-emitting operation of the adjacent light-emitting element is affected, and noise is generated. Such a phenomenon is referred to as light crosstalk. Moreover, the apex part of the first portion is, for example, a spherical surface, and therefore exhibits the effect of confining light in a lateral direction with reliability.

In addition, although a GaN substrate is used in the manufacturing process of the light-emitting element except for Example 5 to be described later, no GaN-based compound semiconductor is formed by a method for lateral epitaxial growth, such as an ELO method. This makes it possible to use not only a polar GaN substrate but also a semipolar GaN substrate and a nonpolar GaN substrate, as the GaN substrate. While the use of the polar GaN substrate tends to lower the light emission efficiency due to a piezoelectric effect in the active layer, the use of the nonpolar GaN substrate or the semipolar GaN substrate makes it possible to solve or mitigate such an issue.

### Example 2

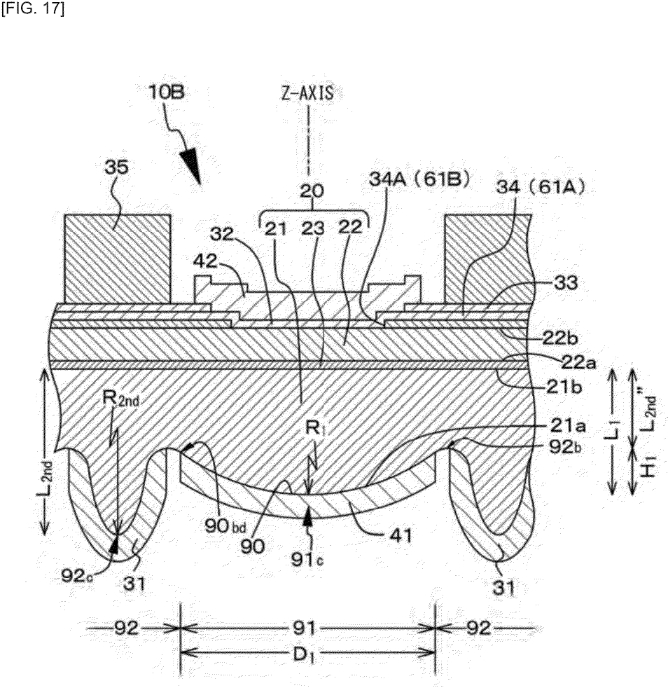

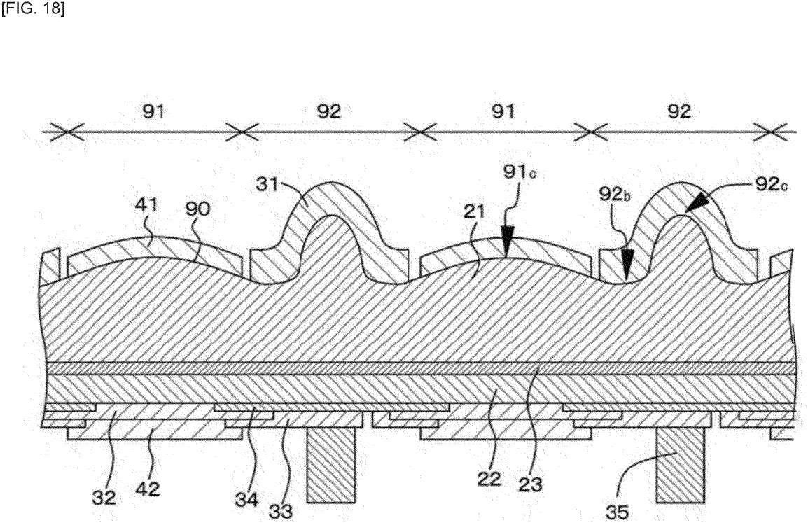

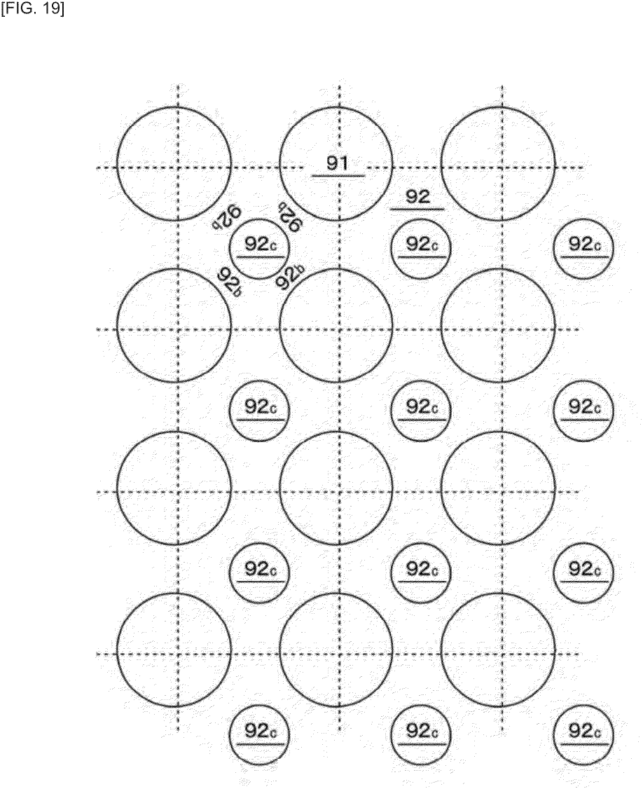

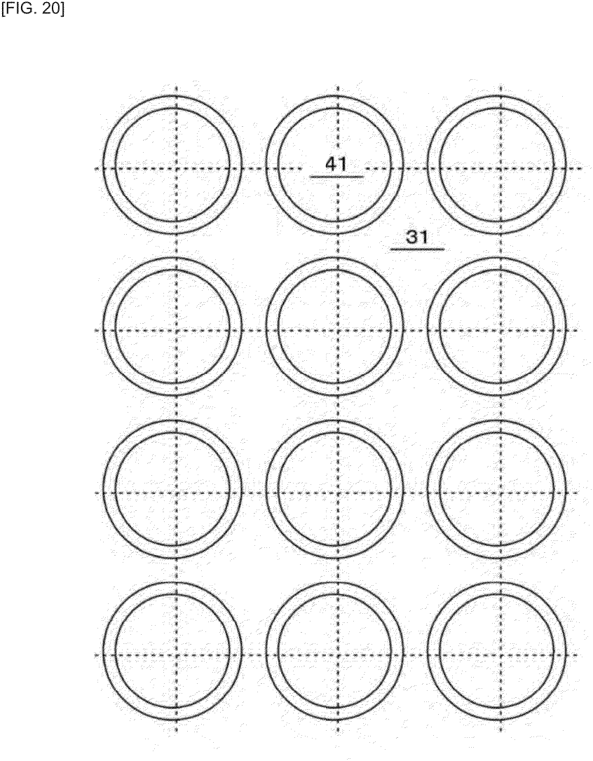

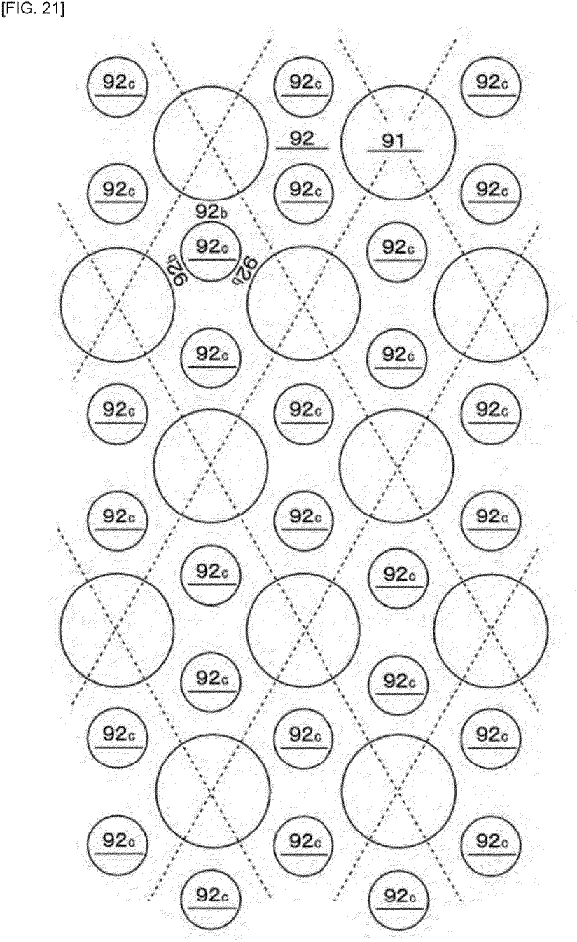

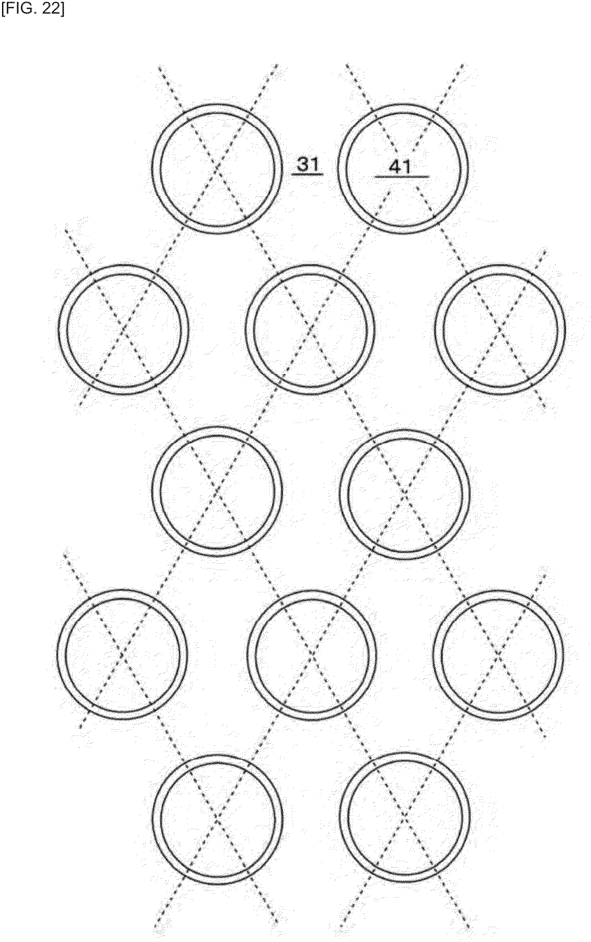

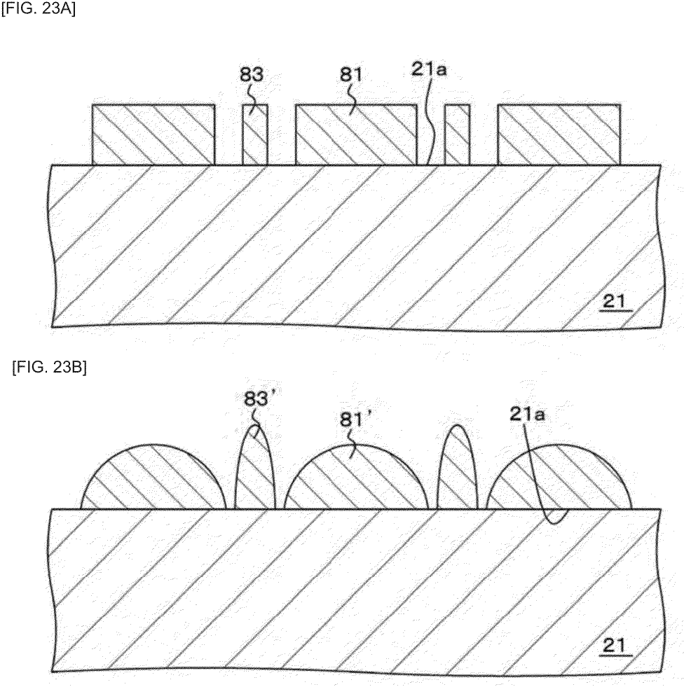

Example 2 is a modification of Example 1, and relates to a light-emitting element of the (1-B)th configuration. FIG. 17 illustrates a schematic partial end view of a light-emitting element 10B of Example 2. FIG. 18 illustrates a schematic partial end view of the light-emitting element array of Example 2. In addition, FIGS. 19 and 21 each illustrate a schematic plan view of an arrangement of a first portion and a second portion of a base part surface of the light-emitting element array of Example 2. FIGS. 20 and 22 each illustrate a schematic plan view of an arrangement of a first light reflective layer and a first electrode in the light-emitting element array of Example 2. Furthermore, FIGS. 23A, 23B, 24A, 24B, 25A, and 25B each illustrate a schematic partial end view of a first compound semiconductor layer and the like for describing a method of manufacturing the light-emitting element of Example 2.

In the light-emitting element 10B of Example 2, the second portion 92 of the base part surface 90 has a downwardly convex shape, and an upwardly convex shape extending from the downwardly convex shape, toward the center part of the second portion 92, with respect to the second surface 21b of the first compound semiconductor layer 21. In addition,

$$\text{L2nd} > \text{L1}$$

is satisfied, where L1 is a distance from the second surface 21b of the first compound semiconductor layer 21 to the center part 91c of the first portion 91 of the base part surface 90, and L2nd is a distance from the second surface 21b of the first compound semiconductor layer 21 to the center part 92c of the second portion 92.

Alternatively,

$$\text{R1} > \text{R2nd}$$

is satisfied, where R1 is a curvature radius of the center part 91c of the first portion 91 (i.e., a curvature radius of the first light reflective layer 41), and R2nd is a curvature radius of the center part 92c of the second portion 92. It is to be noted that examples of a value of L2nd/L1 may include, but not limited to, 1 < L2nd/L1 ≤ 100; and examples of a value of R1/R2nd may include, but not limited to, 1 < R1/R2nd ≤ 100.

Specifically, for example,

$$\text{L2nd} / \text{L1} = 1.05 , \text{and}$$

$$\text{R1} / \text{R2nd} = 10$$

hold true.

In the light-emitting element 10B of Example 2, the center part 91c of the first portion 91 is located on a vertex of a square lattice (see FIG. 19), and in this case, the center part 92c (represented by a circular shape in FIG. 19) of the second portion 92 is located on a vertex of a square lattice. Alternatively, the center part 91c of the first portion 91 is located on a vertex of an equilateral triangular lattice (see FIG. 21), and in this case, the center part 92c (represented by a circular shape in FIG. 21) of the second portion 92 is located on a vertex of an equilateral triangular lattice. In addition, the second portion 92 has a downwardly convex shape toward the center part of the second region 92. Such a region is denoted by reference numeral 92b in FIGS. 19 and 21.

In the light-emitting element 10B of Example 2, examples of the shapes of [the first portion 91/the second portion 92 in a range from a peripheral part to a center part] include the following cases:
(A) [an upwardly convex shape/a downwardly convex shape continuing to an upwardly convex shape];
(B) [an upwardly convex shape/an upwardly convex shape continuing to a downwardly convex shape, and to an upwardly convex shape]; and
(C) [an upwardly convex shape/a line segment continuing to a downwardly convex shape, and to an upwardly convex shape], and the light-emitting element 10B of Example 2 specifically corresponds to the case (A).

In the light-emitting element 10B of Example 2, the bump 35 is provided in a portion on the side of the second surface of the second compound semiconductor layer 22 opposed to a convex-shaped portion in the second portion 92.

In a case where the light-emitting element array is configured by a plurality of light-emitting elements of Example 2 as illustrated in FIG. 17, the second electrode 32 is common among the light-emitting elements 10B configuring the light-emitting element array, or as illustrated in FIG. 18, the second electrode 32 is individually formed, and is electrically coupled to an external circuit or the like through the bump 35. The first electrode 31 is common among the light-emitting elements 10B configuring the light-emitting element array, and is coupled to an external circuit or the like through the first pad electrode (not illustrated). The bump 35 is formed in a portion on the side of the second surface of the second compound semiconductor layer 22 opposed to a convex-shaped portion 92c in the second portion 92. In the light-emitting element 10B illustrated in FIGS. 17 and 18, light may be emitted to the outside through the first light reflective layer 41 or may be emitted to the outside through the second light reflective layer 42. Examples of the shape of the bump 35 may include a cylindrical shape, an annular shape, and a hemispherical shape.

In addition, it is desirable that the curvature radius R2nd of the center part 92c of the second portion 92 be 1 × 10⁻⁶ m or more, preferably 3 × 10⁻⁶ m or more, and more preferably 5 × 10⁻⁶ m or more, and specifically,

$$\text{the curvature radius R2nd = 3} \text{μ} \text{} \text{m}$$

holds true.

Parameters of the light-emitting element 10B are as exhibited in Table 2 below, and specifications of the light-emitting element 10B of Example 2 excluding the phase shift layer are exhibited in Table 3 below. Here, the height H1 of the first portion 91 is expressed by

$$\text{H1} = \text{L1} - \text{L2nd″, and}$$

a height H2 of the center part 92c of the second portion 92 is expressed by

$$\text{H2} = \text{L2nd} - \text{L2nd″,}$$

where L1 is a distance from the second surface 21b of the first compound semiconductor layer 21 to the center part 91c of the first portion 91, and L2nd″ is a distance from the second surface 21b of the first compound semiconductor layer 21 to a deepest concave portion 92b in the second portion 92. It is to be noted that the first light reflective layer 41, the second light reflective layer 42, and the phase shift layer may be similar to those of Example 1 or the various modification examples of Example 1. This applies similarly to the following Examples.

TABLE 2

| | |
|---|---|
| Formation pitch | 25 µm |
| Curvature radius R1 | 150 µm |
| Diameter D1 | 20 µm |
| Height H1 | 2 µm |
| Curvature radius R2nd | 2 µm |
| Height H2 | 2.5 µm |

TABLE 3

| | |
|---|---|
| Second light reflective layer 42 | SiO₂/Ta₂O₅ |
| Second electrode 32 | ITO (thickness: 30 nm) |
| Second compound semiconductor layer 22 | p-GaN |
| Active layer 23 | InGaN (multiquantum well structure) |
| First compound semiconductor layer 21 | n-GaN |
| First light reflective layer 41 | SiO₂/Ta₂O₅ |
| Resonator length LOR | 25 µm |
| Oscillation wavelength (light emission wavelength) λ0 | 445 nm |

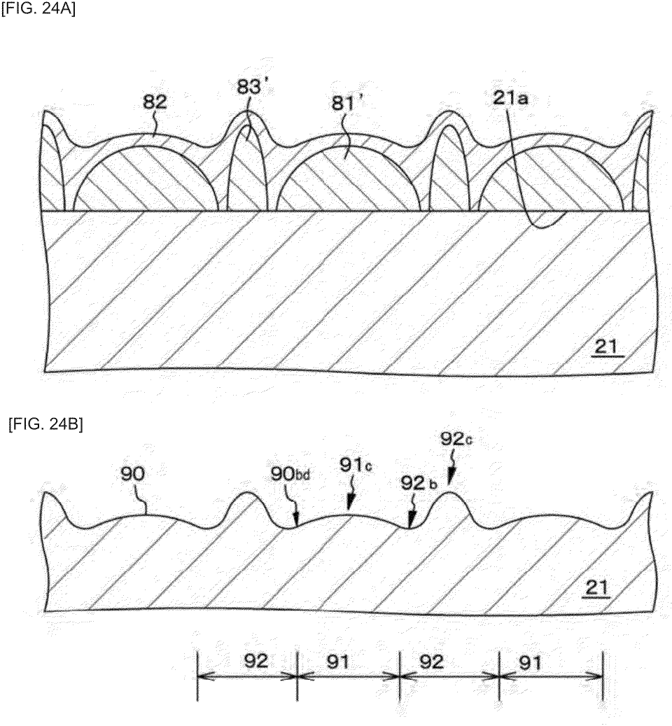

FIGS. 23A, 23B, 24A, 24B, 25A, and 25B each illustrate a schematic partial end view of the first compound semiconductor layer and the like for describing a method of manufacturing the light-emitting element of Example 2. It is possible for the method of manufacturing the light-emitting element of Example 2 to be substantially similar to the method of manufacturing the light-emitting element of Example 1, and detailed description thereof is therefore omitted. It is to be noted that reference numeral 83 in FIG. 23A and reference numeral 83′ in FIGS. 23B and 24A represent portions of the first sacrificial layer for forming the center part 92c of the second portion 92. It is to be noted that as the size (diameter) of the first sacrificial layer decreases, the height of the first sacrificial layer having been subjected to heat treatment increases.

Even in the light-emitting element of Example 2, it is necessary, in the case of coupling or bonding to an external circuit or the like by using the bump 35, to apply a high load (e.g., about 50 MPa) to the light-emitting element at the time of bonding. In the light-emitting element of Example 2, the bump 35 and the convex-shaped portion 92c in the second portion 92 are arranged in alignment in a vertical direction. It is therefore possible to prevent, with reliability, the light-emitting element from being damaged even when such a high load is applied.

### Example 3

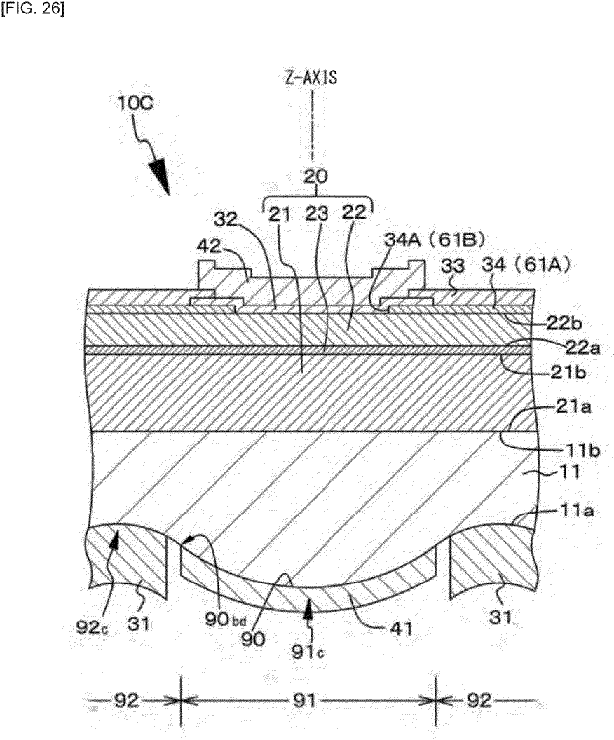

Example 3 is a modification of Examples 1 to 2, and relates to the light-emitting element of the third configuration. In a light-emitting element 10C of Example 3, a schematic partial end view of which is illustrated in FIG. 26, the compound semiconductor substrate 11 is provided (left unremoved) between the first surface 21a of the first compound semiconductor layer 21 and the first light reflective layer 41. The base part surface 90 is configured by a surface (first surface 11a) of the compound semiconductor substrate 11.

For the light-emitting element 10C of Example 3, the compound semiconductor substrate 11 is thinned, and subjected to mirror finishing in a step similar to [Step-140] of Example 1. A surface roughness Ra of the first surface 11a of the compound semiconductor substrate 11 preferably has a value of 10 nm or less. The surface roughness Ra is defined in JIS B-610: 2001, and specifically is measurable on the basis of observations with an AFM or a section TEM. Thereafter, it is sufficient if the first sacrificial layer 81 in [Step-150] of Example 1 is formed on the exposed surface (first surface 11a) of the compound semiconductor substrate 11, and steps similar to [Step-150] and subsequent steps of Example 1 are executed to provide the base part surface 90 including the first portion 91 and the second portion 92 in the compound semiconductor substrate 11, in place of the first compound semiconductor layer 21 of Example 1, to thereby complete the light-emitting element or the light-emitting element array.

Except for the above points, it is possible for a configuration or structure of the light-emitting element of Example 3 to be similar to the configurations or structures of the light-emitting elements of Examples 1 to 2, and therefore detailed descriptions thereof are omitted.

### Example 4

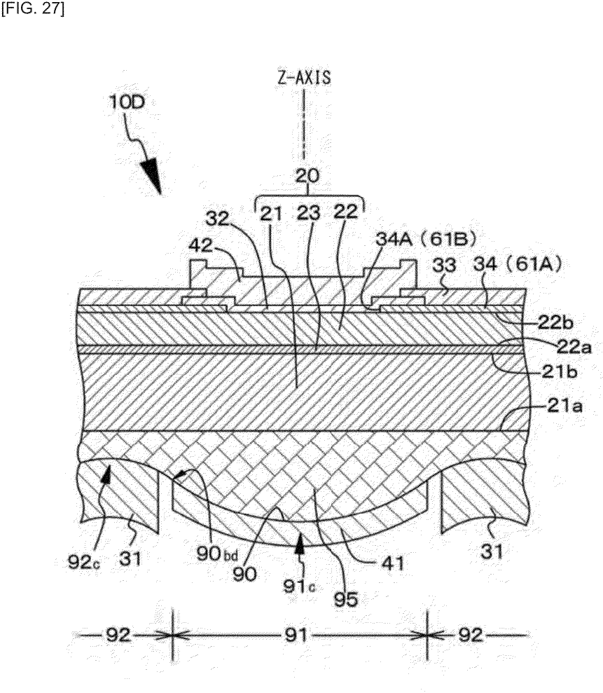

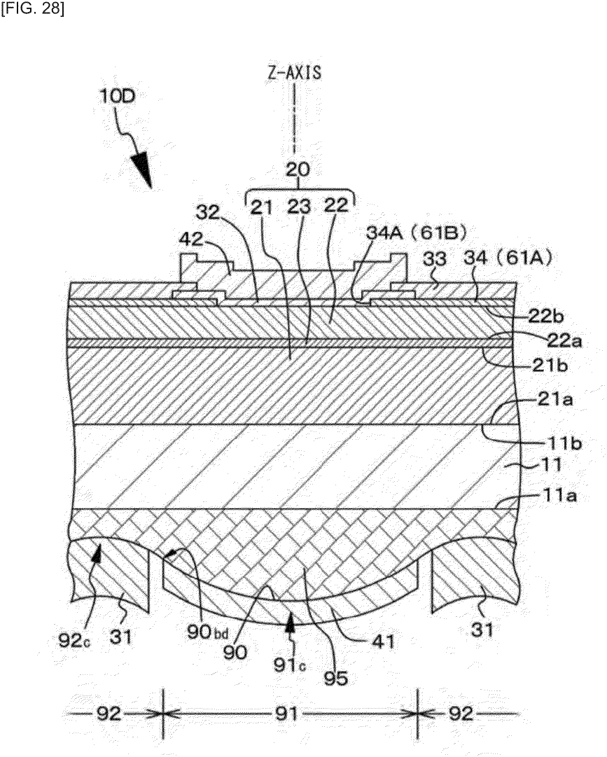

Example 4 is also a modification of Examples 1 to 2, and relates to the light-emitting element of the fourth configuration. In a light-emitting element 10D of Example 4, a schematic partial end view of which is illustrated in FIG. 27, a base material 95 is provided between the first surface 21a of the first compound semiconductor layer 21 and the first light reflective layer 41, and the base part surface 90 is configured by a surface of the base material 95. Alternatively, in a modification example of the light-emitting element 10D of Example 4, a schematic partial end view of which is illustrated in FIG. 28, the compound semiconductor substrate 11 and the base material 95 are provided between the first surface 21a of the first compound semiconductor layer 21 and the first light reflective layer 41, and the base part surface 90 is configured by the surface of the base material 95. Examples of the material configuring the base material 95 may include a transparent dielectric material such as TiO₂, Ta₂O₅, or SiO₂, a silicone-based resin, and an epoxy-based resin.

For the light-emitting element 10D of Example 4 illustrated in FIG. 27, in a step similar to [Step-140] of Example 1, the compound semiconductor substrate 11 is removed, and the base material 95 having the base part surface 90 is formed on the first surface 21a of the first compound semiconductor layer 21. Specifically, for example, a TiO₂ layer or a Ta₂O₅ layer is formed on the first surface 21a of the first compound semiconductor layer 21, following which a patterned resist layer is formed on the TiO₂ layer or the Ta₂O₅ layer in which the first portion 91 is to be formed, and the resist layer is heated to cause the resist layer to reflow to thereby obtain a resist pattern. The resist pattern is given a shape the same as (or a shape similar to) the shape of the first portion. Then, by etching back the resist pattern and the TiO₂ layer or the Ta₂O₅ layer, it is possible to obtain the base material 95 provided with the first portion 91 and the second portion 92 on the first surface 21a of the first compound semiconductor layer 21. Subsequently, it is sufficient if the first light reflective layer 41 is formed on a desired region of the base material 95 by a well-known method.

Alternatively, for the light-emitting element 10D of Example 4 illustrated in FIG. 28, after the compound semiconductor substrate 11 is thinned and subjected to mirror finishing in a step similar to [Step 140] of Example 1, the base material 95 having the base part surface 90 is formed on the exposed surface (first surface 11a) of the compound semiconductor substrate 11. Specifically, for example, a TiO₂ layer or a Ta₂O₅ layer is formed on the exposed surface (first surface 11a) of the compound semiconductor substrate 11, following which a patterned resist layer is formed on the TiO₂ layer or the Ta₂O₅ layer in which the first portion 91 is to be formed, and the resist layer is heated to cause the resist layer to reflow to thereby obtain a resist pattern. The resist pattern is given a shape the same as (or a shape similar to) the shape of the first portion. Then, by etching back the resist pattern and the TiO₂ layer or the Ta₂O₅ layer, it is possible to obtain the base material 95 provided with the first portion 91 and the second portion 92 on the exposed surface (first surface 11a) of the compound semiconductor substrate 11. Subsequently, it is sufficient if the first light reflective layer 41 is formed on a desired region of the base material 95 by a well-known method.

Except for the above points, it is possible for a configuration or structure of the light-emitting element of Example 4 to be similar to the configurations or structures of the light-emitting elements of Examples 1 to 2, and therefore detailed descriptions thereof are omitted.

### Example 5

Example 5 is a modification of Example 4. A schematic partial end view of a light-emitting element of Example 5 is substantially similar to FIG. 28, and it is possible for a configuration or structure of the light-emitting element of Example 5 to be substantially similar to the configuration or structure of the light-emitting element of Example 4. Detailed descriptions thereof are thus omitted.

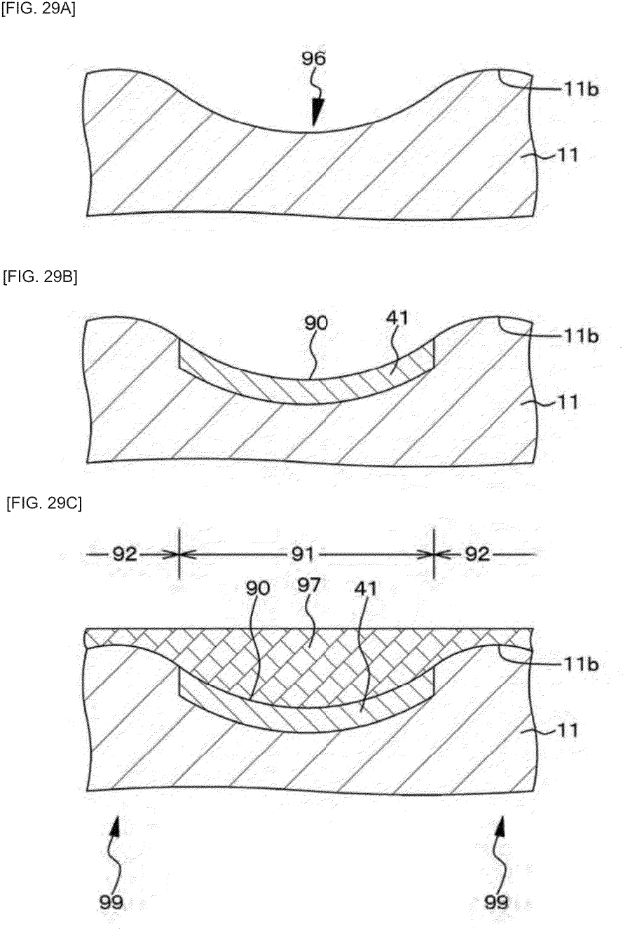

In Example 5, first, a convexo-concave part 96 for forming the base part surface 90 is formed on the second surface 11b of the semiconductor-laser-element manufacturing substrate 11 (see FIG. 29A). Then, the first light reflective layer 41 including a multilayered film is formed on the second surface 11b of the semiconductor-laser-element manufacturing substrate 11 (see FIG. 29B), following which a planarization film 97 is formed on the first light reflective layer 41 and the second surface 11b, and the planarization film 97 is subjected to a planarization processing (see FIG. 29C).

Next, on the planarization film 97 of the semiconductor-laser-element manufacturing substrate 11 including the first light reflective layer 41, the stacked structure 20 is formed by lateral growth using a method for lateral epitaxial growth such as an ELO method. Thereafter, [Step-110] and [Step-120] of Example 1 are executed. Then, the semiconductor-laser-element manufacturing substrate 11 is removed, and the first electrode 31 is formed on the planarization film 97 exposed. Alternatively, the first electrode 31 is formed on the first surface 11a of the semiconductor-laser-element manufacturing substrate 11 without removing the semiconductor-laser-element manufacturing substrate 11.

### Example 6

Example 6 is a modification of Examples 1 to 5. In Examples 1 to 5, the stacked structure 20 includes a GaN-based compound semiconductor. In contrast, in Example 6, the stacked structure 20 includes an InP-based compound semiconductor or a GaAs-based compound semiconductor. It is to be noted that, in this case, for example, it is sufficient if an InP substrate or a GaAs substrate is used as the compound semiconductor substrate, but this is not limitative.

Parameters of a light-emitting element in a light emitting element of Example 6 having a configuration or structure similar to that illustrated in FIG. 1 (except that the stacked structure 20 includes an InP-based compound semiconductor) are as exhibited in Table 4 below, and specifications of the light-emitting element are exhibited in Table 5 below.

TABLE 4

| | |
|---|---|
| Formation pitch | 25 µm |
| Curvature radius R1 | 100 µm |
| Diameter D1 | 20 µm |
| Height H1 | 2 µm |
| Curvature radius R2 | 4 µm |

TABLE 5

| | |
|---|---|
| Second light reflective layer 42 | SiO₂/Ta₂O₅ |
| Second electrode 32 | ITO (thickness: 22 nm) |
| Second compound semiconductor layer 22 | p-InP |
| Active layer 23 | InGaAs (multiquantum well structure), AlInGaAsP (multiquantum well structure), or InAs quantum dot |
| First compound semiconductor layer 21 | n-InP |
| First light reflective layer 41 | SiO₂/Ta₂O₅ |
| Resonator length LOR | 25 µm |
| Oscillation wavelength (light emission wavelength) λ0 | 1.6 µm |

Further, parameters of the light-emitting element in the light-emitting element of Example 6 having a configuration or structure similar to that of FIG. 1 (except that the stacked structure 20 includes a GaAs-based compound semiconductor) are as exhibited in Table 6 below, and specifications of the light-emitting element are exhibited in Table 7 below.

TABLE 6

| | |
|---|---|
| Formation pitch | 25 µm |
| Curvature radius R1 | 100 µm |
| Diameter D1 | 20 µm |
| Height H1 | 2 µm |
| Curvature radius R2 | 5 µm |

TABLE 7

| | |
|---|---|
| Second light reflective layer 42 | SiO₂/Ta₂O₅ |
| Second electrode 32 | ITO (thickness: 22 nm) |
| Second compound semiconductor layer 22 | p-GaAs |
| Active layer 23 | InGaAs (multiquantum well structure), GaInNAs (multiquantum well structure), or InAs quantum dot |
| First compound semiconductor layer 21 | n-GaAs |
| First light reflective layer 41 | SiO₂/Ta₂O₅ |
| Resonator length LOR | 25 µm |
| Oscillation wavelength (light emission wavelength) λ0 | 0.94 µm |

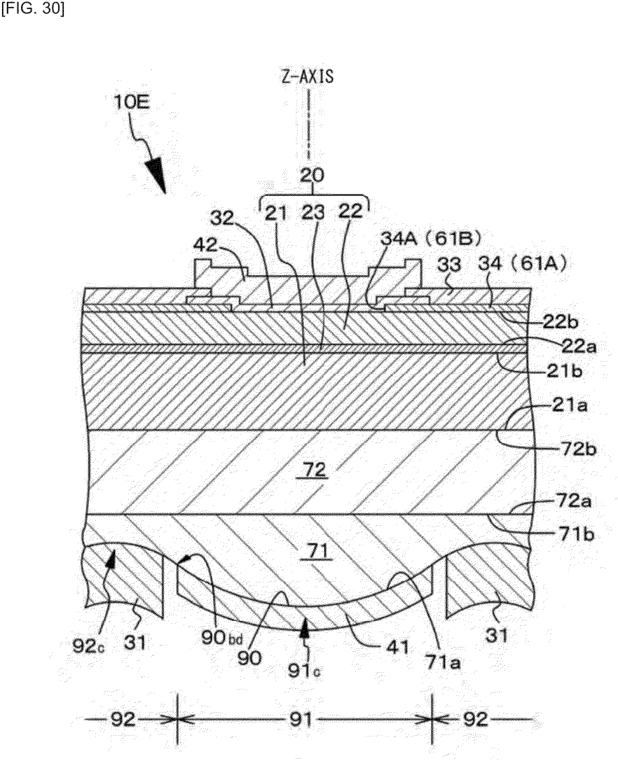

FIG. 30 illustrates a schematic partial cross-sectional view of a modification example of the light-emitting element of Example 6 (the light-emitting element of the fifth configuration). In the modification example of the light-emitting element 10E of Example 6, a structure in which a second substrate 72 having a first surface 72a and a second surface 72b opposed to the first surface 72a, and a first substrate 71 having a first surface 71a and a second surface 71b opposed to the first surface 71a are attached together is provided between the first surface 21a of the first compound semiconductor layer 21 and the first light reflective layer 41. In addition, the base part surface 90 is formed on the first surface 71a of the first substrate 71. The second surface 71b of the first substrate 71 and the first surface 72a of the second substrate 72 are attached together. The first light reflective layer 41 is formed on the first surface 71a of the first substrate 71. The stacked structure 20 is formed on the second surface 72b of the second substrate 72. Examples of the second substrate 72 may include an InP substrate and a GaAs substrate, and examples of the first substrate 71 may include a Si substrate, a SiC substrate, an A1N substrate, and a GaN substrate. The stacked structure 20 includes, for example, an InP-based compound semiconductor or a GaAs-based compound semiconductor.

In manufacturing of the modification example of the light-emitting element 10E of Example 6, the compound semiconductor substrate 11 is thinned, and subjected to mirror finishing in a step similar to [Step-140] of Example 1. The compound semiconductor substrate 11 corresponds to the second substrate 72. Next, the first substrate 71 and the second substrate 72 are bonded with use of a bonding method such as surface activated bonding, dehydration condensation bonding, or thermal diffusion bonding. Next, steps similar to [Step-150] to [Step-170] of Example 1 are executed on the first surface 71a of the first substrate 71, which makes it possible to form a concavo-convex part (the first portion 91 and the second portion 92) on the first surface 71a of the first substrate 71 serving as the base part surface 90. Thereafter, it is sufficient if steps similar to [Step-180] to [Step-190] of Example 1 are executed.

### Example 7

Example 7 relates to another method of manufacturing the light-emitting element. The method of manufacturing the light-emitting element of Example 7 includes
forming the stacked structure, and thereafter forming the second light reflective layer on the side of the second surface of the second compound semiconductor layer,
forming the first sacrificial layer on the first portion of the base part surface on which the first light reflective layer is to be formed, and thereafter making a surface of the first sacrificial layer into a convex shape,
etching back the first sacrificial layer, and further etching back inwardly from the base part surface to form a convex part in the first portion of the base part surface with respect to the second surface of the first compound semiconductor layer,
forming the second sacrificial layer on the base part surface, thereafter etching back the second sacrificial layer, and further etching back inwardly from the base part surface to form a convex part in the first portion of the base part surface with respect to the second surface of the first compound semiconductor layer and to form at least a concave part in the second portion of the base part surface, and
forming the first light reflective layer on the first portion of the base part surface.

### [Step

In the method of manufacturing the light emitting element of Example 7, after the stacked structure 20 is formed, the second light reflective layer 42 is formed on the side of the second surface of the second compound semiconductor layer 22. Specifically, first, steps similar to [Step-100] to [Step-140] of Example 1 are executed.

### [Step

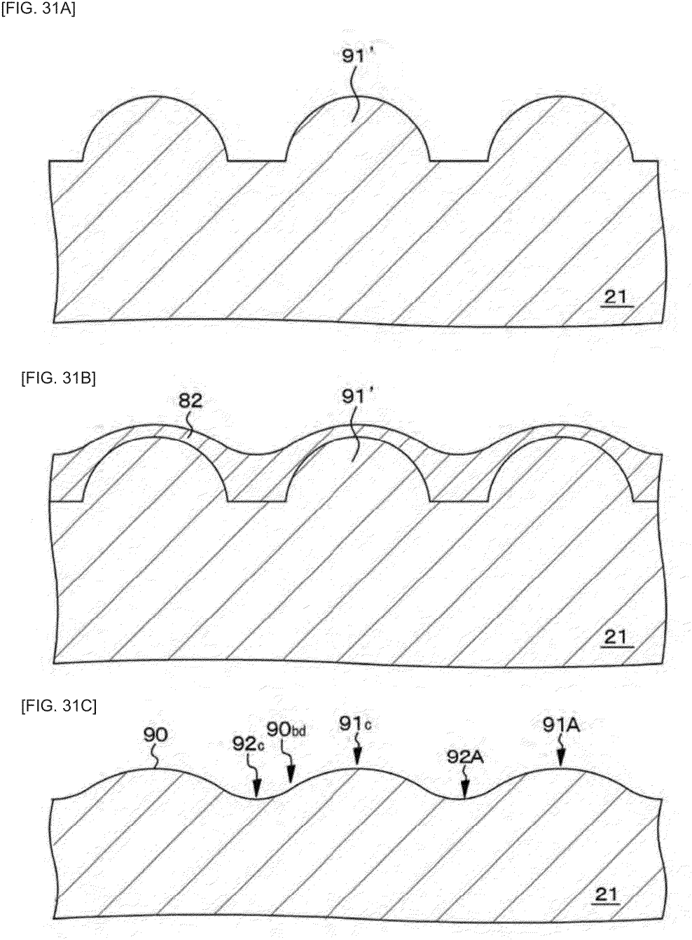

Subsequently, after the first sacrificial layer 81 is formed on the first surface 21a of the first compound semiconductor layer 21, the surface of the first sacrificial layer 81 is made into a convex shape (see FIGS. 14A and 14B). Thereafter, by etching back the first sacrificial layer 81′ and further etching back the first compound semiconductor layer 21 inwardly from the first surface 21a, a convex part 91′ is formed with respect to the second surface 21b of the first compound semiconductor layer 21. In this manner, it is possible to obtain the structure illustrated in FIG. 31A.

### [Step

Thereafter, after the second sacrificial layer 82 is formed across the entire surface (see FIG. 31B), the second sacrificial layer 82 is etched back, and further the first compound semiconductor layer 21 is etched back inwardly, whereby a convex part is formed in the first portion 91 and at least a concave part is formed in the second portion 92 (see FIG. 31C), with respect to the second surface 21b of the first compound semiconductor layer 21.

In a case where it is necessary to further increase the curvature radius R1 of the first portion 91, it is sufficient if [Step-720] is repeated.

### [Step

Thereafter, it is sufficient if steps similar to [Step-180] to [Step-190] of Example 1 are executed.

### Example 8

Example 8 is a modification of Examples 1 to 6. A light-emitting element of Example 8 includes, more specifically, a surface-emitting laser element (vertical resonator laser, VCSEL) that emits laser light from a top surface of the first compound semiconductor layer 21 through the first light reflective layer 41.

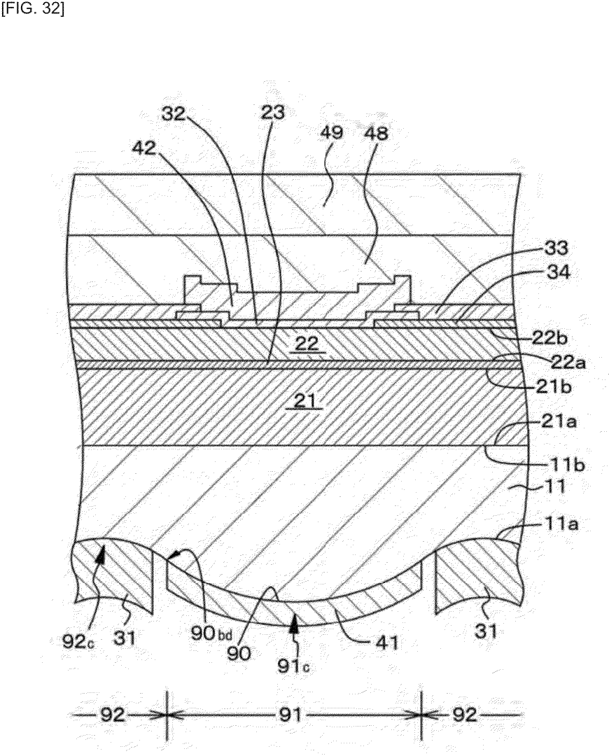

In the light-emitting element of Example 8, as illustrated in a schematic partial cross-sectional view in FIG. 32, the second light reflective layer 42 is fixed, by a solder bonding method, to the support substrate 49 including a silicon semiconductor substrate with the bonding layer 48 interposed therebetween. The bonding layer 48 includes a gold (Au) layer or a solder layer including tin (Sn).

It is possible for the light-emitting element of Example 8 to be manufactured by a method similar to that of the light-emitting element of Example 1 except that the support substrate 49 is not removed.

### Example 9

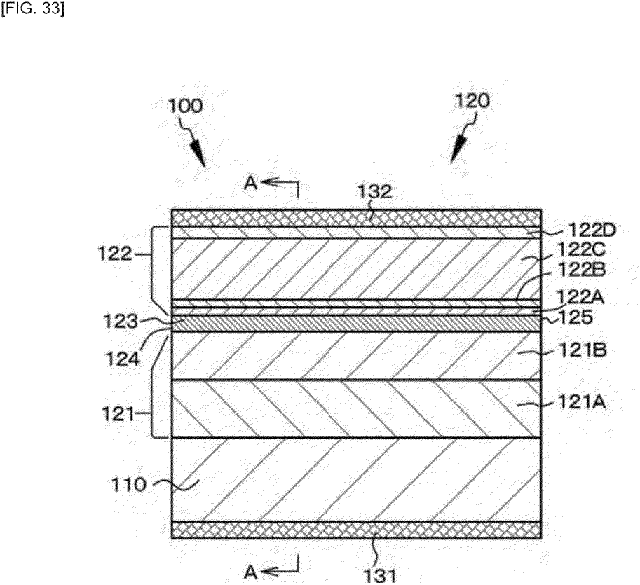

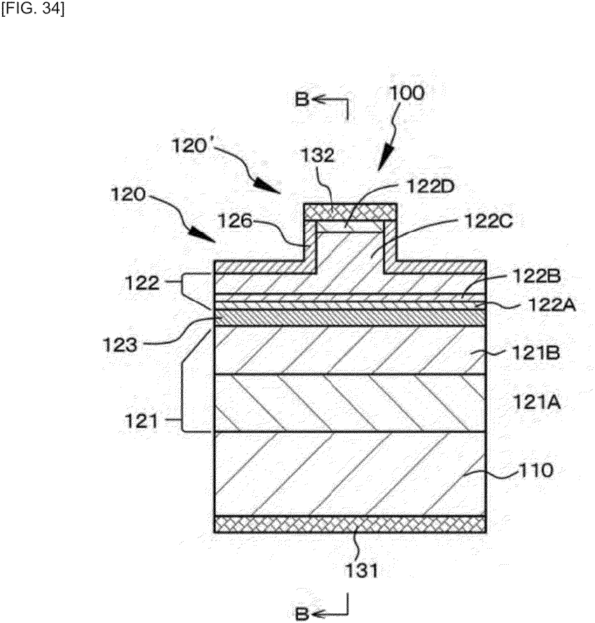

Example 9 relates to an edge-emitting semiconductor laser element (Edge Emitting Laser, EEL). FIGS. 33 and 34 each illustrate a schematic cross-sectional view of the edge-emitting semiconductor laser element of Example 9. It is to be noted that FIG. 33 is a schematic partial cross-sectional view along an arrow B-B of FIG. 34, and FIG. 34 is a schematic partial cross-sectional view along an arrow A-A of FIG. 33.

An edge-emitting semiconductor laser element 100 of Example 9 includes a stacked structure 120, in which a first compound semiconductor layer 121 having a first surface and a second surface opposed to the first surface and having a first electrically-conductive type (specifically, n-type in Example 9), a third compound semiconductor layer (active layer) 123 facing the second surface of the first compound semiconductor layer and including a compound semiconductor, and a second compound semiconductor layer 122 having a first surface facing the active layer and a second surface opposed to the first surface and having a second electrically-conductive type (specifically, p-type in Example 9) different from the first electrically-conductive type are stacked in order. In addition, a second electrode 132 is formed on the second compound semiconductor layer 122, and a first electrode 131 is electrically coupled to the first compound semiconductor layer 121.

In addition, the stacked structure 120 includes a light reflective edge surface (first edge surface) 124 that outputs a portion of laser light generated in the active layer and reflects the remainder, and a light output edge surface (second edge surface) 125 that is opposed to the first edge surface and the first edge surface and reflects the laser light generated in the active layer. The stacked structure 120 includes a ridge stripe structure 120′. That is, the edge-emitting semiconductor laser element of Example 9 has a ridge-stripe-type separate confinement heterostructure (SCH structure).

A first light reflective layer [low-reflective coat layer (LR)] is formed on the light reflective edge surface (first edge surface) 124 of the edge-emitting semiconductor laser element 100, and a second light reflective layer [high-reflective coat layer (HR)] is formed on the light output edge surface (second edge surface) 125 thereof. The light reflective edge surface (first edge surface) 124 and the light output edge surface (second edge surface) 125 are provided at both ends along a resonance direction of the resonator structure, and the light reflective edge surface (first edge surface) 124 and the light output edge surface (second edge surface) 125 are disposed to be opposed to each other. The stacked structure 120, the first edge surface 124, and the second edge surface 125 configure a resonator. The second light reflective layer includes, for example, twelve stacked layers of the light reflective stacked film of SiO₂ and Ta₂O₅. In addition, the phase shift layer is provided between a sixth layer of the light reflective stacked film and a seventh layer of the light reflective stacked film. The optical film thickness of the phase shift layer including SiO₂ was set to 2.25 λ0. In addition, the first light reflective layer includes, for example, three stacked layers of the light reflective stacked film of SiO₂ and Ta₂O₅. It is to be noted that illustration of these high-reflective coat layer and low-reflective coat layer is omitted. A light reflectance of the second edge surface 125 at which a light beam (light pulse) is reflected is, for example, 99% or more (specifically, e.g., 99.9%), and a light reflectance of the first edge surface 124 from which a light beam (light pulse) is outputted is 5% to 90% (specifically, e.g., 10%). It is needless to say that the values of the various parameters mentioned above are merely exemplary and may be modified as appropriate. In addition, the phase shift layer may be provided at the light output edge surface (first edge surface) 124 that functions as a low-reflective coat layer (AR) or a non-reflective coat layer (AR); alternatively, the phase shift layer may be provided at both of the light reflective edge surface (first edge surface) 124 and the light output edge surface (second edge surface) 125.

In the edge-emitting semiconductor laser element 100 of Example 9, specifically, a base 110 includes an n-type GaN substrate, and the stacked structure 120 is provided on (0001) plane of the n-type GaN substrate. The (0001) plane of the n-type GaN substrate is also referred to as a “C plane”, and is a crystal plane having a polarity. In addition, the stacked structure 120 configured by the first compound semiconductor layer 121, the third compound semiconductor layer (active layer) 123, and the second compound semiconductor layer 122 includes a GaN-based compound semiconductor, specifically, an AlGaInN-based compound semiconductor, and more specifically has a layer configuration illustrated in Table 8 below. Here, in Table 8, a compound semiconductor layer listed at lower side indicates a layer closer to the base 110. A band gap of a compound semiconductor configuring a well layer in the third compound semiconductor layer (active layer) 123 is 3.06 eV. The active layer 123 has a quantum well structure provided with a well layer and a barrier layer, and a doping concentration of impurities (specifically, silicon, Si) of the barrier layer is 2 × 10¹⁷ cm⁻³ or more and 1 × 10²⁰ cm⁻³ or less. In addition, a stacked insulating film 126 including SiO₂/SiN is formed on both sides of the ridge stripe structure 120′. The SiO₂ layer is the lower layer and the Si layer is the upper layer. In addition, the second electrode (p-side ohmic electrode) 132 is formed on a p-type GaN contact layer 122D corresponding to a top surface of the ridge stripe structure 120′. Meanwhile, the first electrode (n-side ohmic electrode) 131 including Ti/Pt/Au is formed on a back surface of the base 110. In Example 9, the second electrode 32 was configured by a Pd-monolayer having a thickness of 0.1 µm. A p-type AlGaN electron barrier layer 122A has a thickness of 10 nm. A second light guide layer (p-type AlGaN layer) 122B has a thickness of 100 nm. A second cladding layer (p-type AlGaN layer) 122C has a thickness of 0.5 µm. The p-type GaN contact layer 122D has a thickness of 100 nm. Furthermore, the p-type electron barrier layer 122A, the second light guide layer 122B, the second cladding layer 122C, and the p-type contact layer 122D configuring the second compound semiconductor layer 122 are each doped with Mg of 1 × 10¹⁹ cm⁻³ or more (specifically, 2 × 10¹⁹ cm⁻³. Meanwhile, a first cladding layer (n-type AlGaN layer) 121A has a thickness of 2.5 µm. A first light guide layer (n-type GaN layer) 121B has a thickness of 1.25 µm, and the thickness (1.25 µm) of the first light guide layer 121B is larger than the thickness (100 nm) of the second light guide layer 122B. In addition, although the first light guide layer 121B is configured by GaN, the first light guide layer 121B may be alternatively configured by a compound semiconductor having a wider band gap than that of the active layer 23 and having a narrower band gap than that of the first cladding layer 121A.

TABLE 8

Second compound semiconductor layer 122
p-type GaN contact layer (Mg-doped) 122D
Second cladding layer (p-type Al 0.05 Ga 0.95 N layer (Mg-doped)) 122C
Second light guide layer (p-type Al 0.01 Ga 0.99 N layer (Mg-doped)) 122B
p-type Al 0.20 Ga 0.80 N electron barrier layer (Mg-doped) 122A
Third compound semiconductor layer (active layer) 123
GaInN quantum well active layer
(Well layer: Ga 0.92 In 0.08 N/barrier layer: Ga 0.98 In 002 N)
First compound semiconductor layer 121
First light guide layer (n-type GaN layer) 121B
First cladding layer (n-type Al 0.03 Ga 0.97 N layer) 121A

where
Well layer (2 layers): 10 nm [non-doped]
Barrier layer (3 layers): 12 nm [Doping concentration (Si): 2 × 10¹⁸ cm⁻³]

Although the present disclosure has been described above on the basis of preferred Examples, the present disclosure is not limited to these Examples. The configurations and structures of the semiconductor laser elements described in Examples are illustrative, and may be modified as appropriate. The methods of manufacturing the semiconductor laser elements may also be modified as appropriate. In some cases, by appropriately selecting the bonding layer and the support substrate, it is possible to provide a surface-emitting laser element that emits light from the top surface of the second compound semiconductor layer through the second light reflective layer. In some cases, a through-hole reaching the first compound semiconductor layer may be formed in a region of each of the second compound semiconductor layer and the active layer that does not affect light emission, and a first electrode insulated from the second compound semiconductor layer and the active layer may also be formed in the through-hole. The first light reflective layer may extend to the second portion of the base part surface. That is, the first light reflective layer on the base part surface may include a so-called solid film. In addition, in this case, it is sufficient if a through-hole is formed in the first light reflective layer extending to the second portion of the base part surface, and the first electrode coupled to the first compound semiconductor layer is formed in the through-hole. In addition, it is also possible to form the base part surface by providing a sacrificial layer by a nanoimprint method.

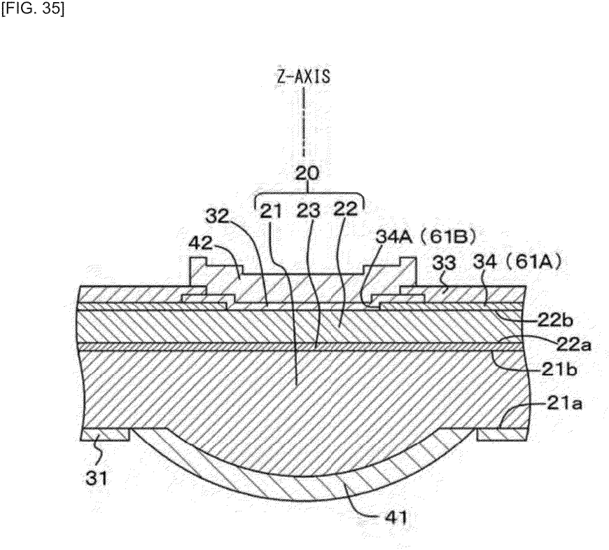

In the light-emitting elements of Examples 1 to 8, the second portion is made into a concavo-convex shape; however, the second portion may also be made into a flat shape as illustrated in FIG. 35.

In the light-emitting elements of Examples 1 to 8, the base part surface may be configured by surfaces of the first sacrificial layer and the second sacrificial layer. In addition, in this case, it is sufficient if the first light reflective layer is formed on the first sacrificial layer or on a portion of the first sacrificial layer.

A mode may be adopted in which a wavelength conversion material layer (color conversion material layer) is provided in a light emitting region of the light-emitting element. In addition, in this case, a mode may be adopted in which white light is emitted through the wavelength conversion material layer (color conversion material layer). Specifically, in a case where light produced by the active layer is to be outputted to the outside through the first light reflective layer, it is sufficient if the wavelength conversion material layer (color conversion material layer) is formed on light output side of the first light reflective layer, or in a case where the light produced by the active layer is to be outputted to the outside through the second light reflective layer, it is sufficient if the wavelength conversion material layer (color conversion material layer) is formed on light output side of the second light reflective layer.

In a case where blue light is to be emitted from a light-emitting layer, adopting any of the following modes makes it possible for white light to be outputted through the wavelength conversion material layer.

[A] By using a wavelength conversion material layer that converts blue light emitted from the light-emitting layer into yellow light, white light with which blue and yellow are mixed is obtained as light outputted from the wavelength conversion material layer.

[B] By using a wavelength conversion material layer that converts blue light emitted from the light-emitting layer into orange light, white light with which blue and orange are mixed is obtained as light outputted from the wavelength conversion material layer.

[C] By using a wavelength conversion material layer that converts blue light emitted from the light-emitting layer into green light and a wavelength conversion material layer that converts the blue light into red light, white light with which blue, green, and red are mixed is obtained as light outputted from the wavelength conversion material layer.

Alternatively, in a case where ultraviolet light is to be emitted from the light-emitting layer, adopting any of the following modes makes it possible for white light to be outputted through the wavelength conversion material layer.

[D] By using a wavelength conversion material layer that converts ultraviolet light emitted from the light-emitting layer into blue light and a wavelength conversion material layer that converts the ultraviolet light into yellow light, white light with which blue and yellow are mixed is obtained as light outputted from the wavelength conversion material layer.

[E] By using a wavelength conversion material layer that converts ultraviolet light emitted from the light-emitting layer into blue light and a wavelength conversion material layer that converts the ultraviolet light into orange light, white light with which blue and orange are mixed is obtained as light outputted from the wavelength conversion material layer.

[F] By using a wavelength conversion material layer that converts ultraviolet light emitted from the light-emitting layer into blue light, a wavelength conversion material layer that converts the ultraviolet light into green light, and a wavelength conversion material layer that converts the ultraviolet light into red light, white light with which blue, green, and red are mixed is obtained as light outputted from the wavelength conversion material layer.

Examples of thereof may include a red light-emitting phosphor particle, more specifically, (ME:Eu)S [where “ME” represents at least one kind of atom selected from the group consisting of Ca, Sr, and Ba, and the same applies hereinafter], (M:Sm)ₓ(Si,Al)₁₂(O,N)₁₆ [where “M” represents at least one kind of atom selected from the group consisting of Li, Mg, and Ca, and the same applies hereinafter], ME₂Si₅N₈:Eu, (Ca:Eu)SiN₂, and (Ca:Eu)AlSiN₃. In addition, specific examples of a wavelength conversion material that is excited by blue light and outputs green light may include a green light-emitting phosphor particle, more specifically, (ME:Eu)Ga₂S₄, (M:RE)ₓ(Si,Al)₁₂(O,N)₁₆ [where “RE” represents Tb and Yb], (M:Tb)ₓ(Si,Al)₁₂(O,N)₁₆, (M:Yb)ₓ(Si,Al)₁₂(O,N)₁₆, and Si_{6-z}Al_{z}O_{z}N_{8-z}:Eu. Further, specific examples of a wavelength conversion material that is excited by blue light and outputs yellow light may include a yellow light-emitting phosphor particle, more specifically, a YAG (yttrium-aluminum-garnet)-based phosphor particle. It is to be noted that a single kind of wavelength conversion material may be used, or two or more kinds of wavelength conversion materials may be used as a mixture. Furthermore, by using two or more kinds of wavelength conversion materials as a mixture, it is possible to achieve a configuration in which emission light of a color other than yellow, green, and red is to be outputted from a wavelength conversion material mixture product. Specifically, for example, a configuration in which a cyan color is to be outputted may be adopted, and in this case, it is sufficient if the green light-emitting phosphor particle (e.g., LaPO₄Ce, Tb, BaMgAl₁₀O₁₇:Eu, Mn, Zn₂SiO₄:Mn, MgAl₁₁O₁₉:Ce, Tb, Y₂SiO₅:Ce,Tb, or MgAl₁₁O₁₉:CE, Tb, Mn) and the blue light-emitting phosphor particle (e.g., BaMgAl₁₀O₁₇:Eu, BaMg₂Al₁₆O₂₇:Eu, Sr₂P₂O₇:Eu, Sr₅(PO₄)₃Cl:Eu, (Sr, Ca, Ba, Mg)₅(PO₄)₃Cl:Eu, CaWO₄, or CaWO₄:Pb) are used as a mixture.

Further, specific examples of a wavelength conversion material that is excited by ultraviolet light and outputs red light may include a red light-emitting phosphor particle, more specifically, Y₂O₃:Eu, YVO₄:Eu, Y(P,V)O₄:Eu, 3.5MgO·0.5MgF₂·Ge₂:Mn, CaSiO₃:Pb,Mn, Mg₆AsO₁₁:Mn, (Sr,Mg)₃(PO₄)₃:Sn, La₂O₂S:Eu, and Y₂O₂S:Eu. In addition, specific examples of a wavelength conversion material that is excited by ultraviolet light and outputs green light may include a green light emitting phosphor particle, more specifically, LaPO₄:Ce, Tb, BaMgAl₁₀O₁₇:Eu, Mn, Zn₂SiO₄:Mn, MgAl₁₁O₁₉:Ce, Tb, Y₂SiO₅:Ce, Tb, MgAl₁₁O₁₉:CE, Tb, Mn, and Si₆₋_{Z}Al_{Z}O_{Z}N_{8-Z}:Eu. Further, specific examples of a wavelength conversion material that is excited by ultraviolet light and outputs blue light may include a blue light-emitting phosphor particle, more specifically, BaMgAl₁₀O₁₇:Eu, BaMg₂Al₁₆O₂₇:Eu, Sr₂P₂O₇:Eu, Sr₅(PO₄)₃Cl:Eu, (Sr,Ca,Ba,Mg)₅(PO₄)₃Cl:Eu, CaWO₄, and CaWO₄:Pb. Further, specific examples of a wavelength conversion material that is excited by ultraviolet light and outputs yellow light may include a yellow light-emitting phosphor particle, more specifically, a YAG-based phosphor particle. It is to be noted that a single kind of wavelength conversion material may be used, or two or more kinds of wavelength conversion materials may be used as a mixture. Further, by using two or more kinds of wavelength conversion materials as a mixture, it is possible to achieve a configuration in which emission light of a color other than yellow, green, and red is to be outputted from a wavelength conversion material mixture product. Specifically, a configuration in which a cyan color is to be outputted may be adopted, and in this case, it is sufficient if the green light-emitting phosphor particle and the blue light-emitting phosphor particle described above are used as a mixture.

However, the wavelength conversion material (color conversion material) is not limited to the phosphor particles. Other examples of the wavelength conversion material may include a light-emitting particle of an indirect transition-type silicon-based material having a quantum well structure, such as a two-dimensional quantum well structure, a one-dimensional quantum well structure (quantum wire), or a zero-dimensional quantum well structure (quantum dot), in which a carrier wave function is localized in order to cause carriers to be efficiently converted into light as in a direct transition-type material, thus utilizing a quantum effect. It has also been known that rare earth atoms added to a semiconductor material sharply emit light by means of an intra-shell transition, and a light-emitting particle to which such a technique is applied is also usable.

As described above, examples of the wavelength conversion material may include a quantum dot. As the size (diameter) of the quantum dot becomes smaller, the band gap energy becomes higher, and the wavelength of light emitted from the quantum dot becomes shorter. That is, as the size of the quantum dot is smaller, light having a shorter wavelength (light on blue light side) is emitted, and as the size of the quantum dot is larger, light having a longer wavelength (light on red light side) is emitted. Therefore, employing the same material configuring a quantum dot and adjusting the size of the quantum dot make it possible to obtain a quantum dot that emits light having a desired wavelength (performing color conversion into a desired color). Specifically, the quantum dot preferably has a core-shell structure. Examples of the material configuring the quantum dot may include, but not limited to: Si; Se; chalcopyrite-based compounds including CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂; perovskite-based materials; group III-V compounds including GaAs, GaP, InP, InAs, InGaAs, AlGaAs, InGaP, AlGaInP, InGaAsP, and GaN; CdSe, CdSeS, CdS, CdTe, In₂Se₃, In₂S₃, Bi₂Se₃, Bi₂S₃, ZnSe, ZnTe, ZnS, HgTe, HgS, PbSe, PbS, TiO₂, and the like.

It is to be noted that the present disclosure may also have the following configurations.

### A01 Semiconductor Laser Element

A semiconductor laser element including:
a resonator structure including a stacked structure in which a first compound semiconductor layer, an active layer, and a second compound semiconductor layer are stacked; and
a first light reflective layer and a second light reflective layer which are provided at both ends along a resonance direction of the resonator structure, in which, when an oscillation wavelength is set to λ0,
the first light reflective layer includes a first refractive index periodic structure with a period having an optical film thickness of k10 (λ 0/2) [where 0.9 ≤ k10 ≤ 1.1], the first refractive index periodic structure including, in a stacked manner, at least a plurality of first thin films each having an optical film thickness of k11 (λ 0/4) [where 0.7 ≤ k1 1 ≤ 1.3] and a plurality of second thin films each having an optical film thickness of k12 (λ 0/4) [where 0.7 ≤ k12 ≤ 1.3],
the second light reflective layer includes a second refractive index periodic structure with a period having an optical film thickness of k20 (λ 0/2) [where 0.9 ≤ k20 ≤ 1.1], the second refractive index periodic structure including, in a stacked manner, at least a plurality of first thin films each having an optical film thickness of k21 (λ 0/4) [where 0.7 ≤ k21 ≤ 1.3] and a plurality of second thin films each having an optical film thickness of k22 (λ 0/4) [where 0.7 ≤ k22 ≤ 1.3], and
a phase shift layer is provided inside at least one light reflective layer of the first light reflective layer or the second light reflective layer.

### A02

The semiconductor laser element according to [A01], in which the number of the phase shift layer is one or more and five or less.

### A03

The semiconductor laser element according to [A02], in which the first thin film, the second thin film, or the first thin film and the second thin film are disposed between the phase shift layer and the phase shift layer.

### A04

The semiconductor laser element according to any one of [A01] to [A03], in which the phase shift layer is not provided at an edge part of the refractive index periodic structure.

### A05

The semiconductor laser element according to any one of [A01] to [A04], in which an optical film thickness of the phase shift layer is 0.1 times or more and 50 times or less of λ0.

### A06

The semiconductor laser element according to [A05], in which a material configuring the phase shift layer is same as a material configuring the first thin film, or is same as a material configuring the second thin film.

### A07

The semiconductor laser element according to any one of [A01] to [A06], in which the optical film thickness of the phase shift layer satisfies k3(λ0/4) (2r + 1) [where r is an integer of 100 or less, and 0.9 ≤ k3 ≤ 1.1].

### A08 Surface-Emitting Laser Element

The semiconductor laser element according to any one of [A01] to [A07], in which
the stacked structure includes, in a stacked manner,
   the first compound semiconductor layer having a first surface and a second surface opposed to the first surface,
   the active layer facing the second surface of the first compound semiconductor layer, and
   the second compound semiconductor layer having a first surface facing the active layer and a second surface opposed to the first surface,
the first light reflective layer is formed on a base part surface located on side of the first surface of the first compound semiconductor layer,
the second light reflective layer is formed on side of the second surface of the second compound semiconductor layer, and
the semiconductor laser element includes a surface-emitting laser element.

### A09

The semiconductor laser element according to [A08], in which
the first light reflective layer functions as a concave mirror, and
the second light reflective layer has a flat shape.

### A10

The semiconductor laser element according to [A08] or [A09], in which a resonator length LOR is 1 × 10⁻⁵ m or more.

### A11 Edge-Emitting Semiconductor Laser Element

The semiconductor laser element according to any one of [A01] to [A07], in which
the stacked structure includes, in a stacked manner,
   the first compound semiconductor layer having a first surface and a second surface opposed to the first surface,
   the active layer facing the second surface of the first compound semiconductor layer, and
   the second compound semiconductor layer having a first surface facing the active layer and a second surface opposed to the first surface,
the stacked structure is provided with a first edge surface that outputs a portion of laser light generated in the active layer and reflects a remainder, and a second edge surface that is opposed to the first edge surface and reflects the laser light generated in the active layer,
the first edge surface is provided with the first light reflective layer, and
the second edge surface is provided with the second light reflective layer.

### B01

The semiconductor laser element according to any one of [A08] to [A10], in which the base part surface has a concavo-convex shape and is differentiable.

### B02

The semiconductor laser element according to [B01], in which the base part surface is smooth.

### B03 Light-Emitting Element of First Configuration

The semiconductor laser element according to [B01] or [B02], in which a first portion of the base part surface on which the first light reflective layer is formed has an upwardly convex shape with respect to the second surface of the first compound semiconductor layer.

### B04 Light-Emitting Element of (1-A)th Configuration

The semiconductor laser element according to [B03], in which a second portion surrounding the first portion of the base part surface has a downwardly convex shape with respect to the second surface of the first compound semiconductor layer.

### B05

The semiconductor laser element according to [B04], in which a center part of the first portion of the base part surface is located on a vertex of a square lattice.

### B06

The semiconductor laser element according to [B04], in which a center part of the first portion of the base part surface is located on a vertex of an equilateral triangular lattice.

### B07 Light-Emitting Element of (1-B)th Configuration

The semiconductor element according to [B03], in which a second portion surrounding the first portion of the base part surface has a downwardly convex shape, and an upwardly convex shape extending from the downwardly convex shape, toward a center part of the second portion, with respect to the second surface of the first compound semiconductor layer.

### B08

The semiconductor laser element according to [B07], in which

$$\text{L2nd} > \text{L1}$$

is satisfied, where L1 is a distance from the second surface of the first compound semiconductor layer to a center part of the first portion of the base part surface, and L2nd is a distance from the second surface of the first compound semiconductor layer to the center part of the second portion of the base part surface.

### B09

The semiconductor laser element according to [B07] or [B08], in which

$$\text{R1} > \text{R2nd}$$

is satisfied, where R1 is a curvature radius of the center part of the first portion of the base part surface (i.e., a curvature radius of the first light reflective layer), and R2nd is a curvature radius of the center part of the second portion of the base part surface.

### B10

The semiconductor laser element according to any one of [B07] to [B09], in which the center part of the first portion of the base part surface is located on a vertex of a square lattice.

### B11

The semiconductor laser element according to [B10], in which the center part of the second portion of the base part surface is located on the vertex of the square lattice.

### B12

The semiconductor laser element according to any one of [B07] to [B09], in which the center part of the first portion of the base part surface is located on a vertex of an equilateral triangular lattice.

### B13

The semiconductor laser element according to [B12], in which the center part of the second portion of the base part surface is located on the vertex of the equilateral triangular lattice.

### B14

The semiconductor laser element according to any one of [B07] to [B13], in which the curvature radius R2nd of the center part of the second portion of the base part surface is 1 × 10⁻⁶ m or more, preferably 3 × 10⁻⁶ m or more, and more preferably 5 × 10⁻⁶ m or more.

### B15 Light-Emitting Element of (1-C)th Configuration

The semiconductor laser element according to [B03], in which a second portion surrounding the first portion of the base part surface has an annular convex shape surrounding the first portion of the base part surface and a downwardly convex shape extending from the annular convex shape toward the first portion of the base part surface, with respect to the second surface of the first compound semiconductor layer.

### B16

The semiconductor laser element according to [B15], in which

$$\text{L2nd′} > \text{L1}$$

is satisfied, where L1 is a distance from the second surface of the first compound semiconductor layer to a center part of the first portion of the base part surface, and L2nd′ is a distance from the second surface of the first compound semiconductor layer to an apex part of the annular convex shape of the second portion of the base part surface.

### B17

The semiconductor laser element according to [B 15] or [B16], in which

$$\text{R1} > \text{R2nd′}$$

is satisfied, where R1 is a curvature radius of the center part of the first portion of the base part surface (i.e., a curvature radius of the first light reflective layer), and R2nd′ isa curvature radius of the apex part of the annular convex shape of the second portion of the base part surface.

### B18

The semiconductor laser element according to any one of [B15] to [B17], in which the curvature radius R2nd′ of the apex part of the annular convex shape of the second portion of the base part surface is 1 × 10⁻⁶ m or more, preferably 3 × 10⁻⁶ m or more, and more preferably 5 × 10⁻⁶ m or more.

### B19

The semiconductor laser element according to any one of [B07] to [B18], in which a bump is provided in a portion on side of the second surface of the second compound semiconductor layer opposed to a convex-shaped portion in the second portion of the base part surface.

### B20

The semiconductor laser element according to any one of [B04] to [B06], in which a bump is provided in a portion on side of the second surface of the second compound semiconductor layer opposed to the center part of the first portion of the base part surface.

### B21

The semiconductor laser element according to any one of [B01] to [B20], in which the curvature radius R1 of the center part of the first portion of the base part surface (i.e., the curvature radius of the first light reflective layer) is 1 × 10⁻⁵ m or more, and preferably 3 × 10⁻⁵ m or more.

### B22

The semiconductor laser element according to any one of [B01] to [B21], in which the stacked structure includes at least one kind of material selected from the group consisting of a GaN-based compound semiconductor, an InP-based compound semiconductor, and a GaAs-based compound semiconductor.

### B23

The semiconductor laser element according to any one of [B01] to [B22], in which a figure drawn by the first portion of the base part surface when the base part surface is cut along a virtual plane including a stacking direction of the stacked structure is a part of a circle or a part of a parabola.

### B24 Light-Emitting Element of Second Configuration

The semiconductor laser element according to any one of [B01] to [B23], in which the first surface of the first compound semiconductor layer configures the base part surface.

### B25 Light-Emitting Element of Third Configuration

The semiconductor laser element according to any one of [B01] to [B23], in which a compound semiconductor substrate is provided between the first surface of the first compound semiconductor layer and the first light reflective layer, and the base part surface is configured by a surface of the compound semiconductor substrate.

### B26 Light-Emitting Element of Fourth Configuration

The semiconductor laser element according to any one of [B01] to [B23], in which a base material is provided between the first surface of the first compound semiconductor layer and the first light reflective layer, or a compound semiconductor substrate and the base material are provided between the first surface of the first compound semiconductor layer and the first light reflective layer, and the base part surface is configured by a surface of the base material.

### B27

The semiconductor laser element according to [B26], in which a material configuring the base material includes at least one kind of material selected from the group consisting of transparent dielectric materials such as TiO₂, Ta₂O₅, and SiO₂, a silicone-based resin, and an epoxy-based resin.

### B28 Light-Emitting Element of Fifth Configuration

The semiconductor laser element according to any one of [B01] to [B23], in which a structure in which a second substrate having a first surface and a second surface opposed to the first surface and a first substrate having a first surface and a second surface opposed to the first surface are attached together is provided between the first surface of the first compound semiconductor layer and the first light reflective layer, and the base part surface is configured by the first surface of the first substate.

### B29

The semiconductor laser element according to [B28], in which the second surface of the first substrate and the first surface of the second substrate are attached together, the first light reflective layer is formed on the first surface of the first substrate, and the stacked structure is formed on the second surface of the second substrate.

### B30

The semiconductor laser element according to [B28] or [B29], in which the first substrate includes a Si substrate, a SiC substrate, an AlN substrate, or a GaN substrate, and the second substrate includes an InP substrate or a GaAs substrate

### B31

The semiconductor laser element according to any one of [B01] to [B30], in which the first light reflective layer is formed on the base part surface.

### B32

The semiconductor laser element according to any one of [B01] to [B31], in which a value of a thermal conductivity of the stacked structure is higher than a value of a thermal conductivity of the first light reflective layer.

### C01 Method of Manufacturing Semiconductor Laser Element: First Aspect

A method of manufacturing a semiconductor laser element including
a stacked structure including, in a stacked manner,
   a first compound semiconductor layer having a first surface and a second surface opposed to the first surface,
   an active layer facing the second surface of the first compound semiconductor layer, and
   a second compound semiconductor layer having a first surface facing the active layer and a second surface opposed to the first surface,
a first light reflective layer formed on a base part surface located on side of the first surface of the first compound semiconductor layer, and
a second light reflective layer formed on side of the second surface of the second compound semiconductor layer and having a flat shape,
the base part surface having a first portion and a second portion surrounding the first portion,
the base part surface having a concavo-convex shape and being differentiable,
the method including:
   forming the stacked structure, and thereafter forming the second light reflective layer on the side of the second surface of the second compound semiconductor layer,
   forming a first sacrificial layer on the first portion of the base part surface on which the first light reflective layer is to be formed, and thereafter making a surface of the first sacrificial layer into a convex shape;
   forming a second sacrificial layer on the second portion of the base part surface exposed between the first sacrificial layer and the first sacrificial layer and on the first sacrificial layer to make a surface of the second sacrificial layer into a concavo-convex shape;
   etching back the second sacrificial layer and the first sacrificial layer, and further etching back inwardly from the base part surface to form a convex part in the first portion of the base part surface with respect to the second surface of the first compound semiconductor layer and to form at least a concave part in the second portion of the base part surface; and
   forming the first light reflective layer on the first portion of the base part surface.

### C02 Method of Manufacturing Semiconductor Laser Element: Second Aspect

A method of manufacturing a semiconductor laser element including
a stacked structure including, in a stacked manner,
   a first compound semiconductor layer having a first surface and a second surface opposed to the first surface,
   an active layer facing the second surface of the first compound semiconductor layer, and
   a second compound semiconductor layer having a first surface facing the active layer and a second surface opposed to the first surface,
a first light reflective layer formed on a base part surface located on side of the first surface of the first compound semiconductor layer, and
a second light reflective layer formed on side of the second surface of the second compound semiconductor layer and having a flat shape,
the base part surface having a first portion and a second portion surrounding the first portion,
the base part surface having a concavo-convex shape and being differentiable,
the method including:
   forming the stacked structure, and thereafter forming the second light reflective layer on the side of the second surface of the second compound semiconductor layer,
   forming a first sacrificial layer on the first portion of the base part surface on which the first light reflective layer is to be formed, and thereafter making a surface of the first sacrificial layer into a convex shape;
   etching back the first sacrificial layer, and further etching back inwardly from the base part surface to form a convex part in the first portion of the base part surface with respect to the second surface of the first compound semiconductor layer;
   forming a second sacrificial layer on the base part surface, thereafter etching back the second sacrificial layer, and further etching back inwardly from the base part surface to form a convex part in the first portion of the base part surface with respect to the second surface of the first compound semiconductor layer and to form at least a concave part in the second portion of the base part surface; and
   forming the first light reflective layer on the first portion of the base part surface.

### C03 Method of Manufacturing Semiconductor Laser Element: Nanoimprint Method

A method of manufacturing a semiconductor laser element including
a stacked structure including, in a stacked manner,
   a first compound semiconductor layer having a first surface and a second surface opposed to the first surface,
   an active layer facing the second surface of the first compound semiconductor layer, and
   a second compound semiconductor layer having a first surface facing the active layer and a second surface opposed to the first surface,
a first light reflective layer formed on a base part surface located on side of the first surface of the first compound semiconductor layer, and
a second light reflective layer formed on side of the second surface of the second compound semiconductor layer and having a flat shape,
the base part surface having a first portion and a second portion surrounding the first portion,
the base part surface having a concavo-convex shape and being differentiable,
the method including:
   preparing a mold having a surface complementary to the base part surface;
   forming the stacked structure, and thereafter forming the second light reflective layer on the side of the second surface of the second compound semiconductor layer;
   forming a sacrificial layer on the base part surface on which the first light reflective layer is to be formed, and thereafter transferring a shape of the surface of the mold complementary to the base part surface onto the sacrificial layer to form a concavo-convex part in the sacrificial layer;
   etching back the sacrificial layer, and further etching back inwardly from the base part surface to form a convex part in the first portion of the base part surface with respect to the second surface of the first compound semiconductor layer and to form at least a concave part in the second portion of the base part surface; and
   forming the first light reflective layer on the first portion of the base part surface.

This application claims the benefit of Japanese Priority Patent Application JP2020-124411 filed with Japan Patent Office on Jul. 21, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor laser element comprising:
a resonator structure including a stacked structure in which a first compound semiconductor layer, an active layer, and a second compound semiconductor layer are stacked; and
a first light reflective layer and a second light reflective layer which are provided at both ends along a resonance direction of the resonator structure, wherein, when an oscillation wavelength is set to λ0,
the first light reflective layer includes a first refractive index periodic structure with a period having an optical film thickness of k10 (λ0/2) [where 0.9 ≤ k10 ≤ 1.1], the first refractive index periodic structure including, in a stacked manner, at least a plurality of first thin films each having an optical film thickness of k11 (λ0/4) [where 0.7 ≤ k11 ≤ 1.3] and a plurality of second thin films each having an optical film thickness of k12 (λ0/4) [where 0.7 ≤ k12 ≤ 1.3],
the second light reflective layer includes a second refractive index periodic structure with a period having an optical film thickness of k20 (λ0/2) [where 0.9 ≤ k20 ≤ 1.1], the second refractive index periodic structure including, in a stacked manner, at least a plurality of first thin films each having an optical film thickness of k21 (λ0/4) [where 0.7 ≤ k21 ≤ 1.3] and a plurality of second thin films each having an optical film thickness of k22 (λ0/4) [where 0.7 ≤ k22 ≤ 1.3], and
a phase shift layer is provided inside at least one light reflective layer of the first light reflective layer or the second light reflective layer.

2. The semiconductor laser element according to claim 1, wherein the number of the phase shift layer is one or more and five or less.

3. The semiconductor laser element according to claim 2, wherein the first thin film, the second thin film, or the first thin film and the second thin film are disposed between the phase shift layer and the phase shift layer.

4. The semiconductor laser element according to claim 1, wherein the phase shift layer is not provided at an edge part of the refractive index periodic structure.

5. The semiconductor laser element according to claim 1, wherein an optical film thickness of the phase shift layer is 0.1 times or more and 50 times or less of λ0.

6. The semiconductor laser element according to claim 5, wherein a material configuring the phase shift layer is same as a material configuring the first thin film, or is same as a material configuring the second thin film.

7. The semiconductor laser element according to claim 1, wherein an optical film thickness of the phase shift layer satisfies k3(λ0/4) (2r + 1) [where r is an integer of 100 or less, and 0.9 ≤ k3 ≤ 1.1].

8. The semiconductor laser element according to claim 1, wherein
the stacked structure includes, in a stacked manner,
the first compound semiconductor layer having a first surface and a second surface opposed to the first surface,
the active layer facing the second surface of the first compound semiconductor layer, and
the second compound semiconductor layer having a first surface facing the active layer and a second surface opposed to the first surface,
the first light reflective layer is formed on a base part surface located on side of the first surface of the first compound semiconductor layer,
the second light reflective layer is formed on side of the second surface of the second compound semiconductor layer, and
the semiconductor laser element includes a surface-emitting laser element.

9. The semiconductor laser element according to claim 8, wherein
the first light reflective layer functions as a concave mirror, and
the second light reflective layer has a flat shape.

10. The semiconductor laser element according to claim 8, wherein a resonator length is 1 × 10⁻⁵ m or more.

11. The semiconductor laser element according to claim 1, wherein
the stacked structure includes, in a stacked manner,
the first compound semiconductor layer having a first surface and a second surface opposed to the first surface,
the active layer facing the second surface of the first compound semiconductor layer, and
the second compound semiconductor layer having a first surface facing the active layer and a second surface opposed to the first surface,
the stacked structure is provided with a first edge surface that outputs a portion of laser light generated in the active layer and reflects a remainder, and a second edge surface that is opposed to the first edge surface and reflects the laser light generated in the active layer,
the first edge surface is provided with the first light reflective layer, and
the second edge surface is provided with the second light reflective layer.
